(19) United States
(12) Patent Application Publication
(10) Pub. No.: US 2025/0287626 A1
(43) Pub. Date: Sep. 11, 2025

(54) SEMICONDUCTOR DEVICE WITH DRAIN ELECTRICAL CONTACT FORMING JUNCTIONS HAVING DIFFERENT ENERGY BARRIER HEIGHTS TO DRAIN LAYER

(71) Applicant: TEXAS INSTRUMENTS INCORPORATED, Dallas, TX (US)

(72) Inventors: Ujwal Radhakrishna, San Jose, CA (US); Zhikai Tang, Sunnyvale, CA (US); Jungwoo Joh, Allen, TX (US)

(21) Appl. No.: 18/597,910

(22) Filed: Mar. 6, 2024

(51) Int. Cl. H01L 29/66; H01L 29/20; H01L 29/47; H01L 29/778; H01L 29/872

(52) U.S. Cl. CPC H10D 30/015; H10D 8/051; H10D 8/60; H10D 30/475; H10D 30/6738; H10D 30/675; H10D 62/85; H10D 62/8503; H10D 64/64

(57) ABSTRACT

A semiconductor device, such as a GaN-based high electron mobility transistor (HEMT), includes a hybrid drain contact structure over a channel layer and a barrier layer. The hybrid drain contact structure includes a first drain contact electrically coupled to the channel layer, a semiconductor layer over the barrier layer and including a first semiconductor portion and a second semiconductor portion, and a second drain contact on the semiconductor layer and electrically coupled to the first drain contact. The second drain contact includes a first metal portion and a second metal portion. The first metal portion and the first semiconductor portion form a first junction having a first energy barrier height. The second metal portion and the second semiconductor portion form a second junction having a second energy barrier height lower than the first energy barrier height.

### BACKGROUND

A high electron mobility transistor (HEMT) may include a heterojunction formed using different semiconductor materials, where a channel may be formed near the heterojunction and between a source region and a drain region, and the channel may be turned on or off by applying an appropriate voltage level on a gate structure. Gallium nitride (GaN)-based HEMT devices generally have high breakdown field, high electron mobility, low resistance, high current, faster-switching speed, high thermal conductivity, and excellent reverse-recovery performance, and thus may be suitable for applications where a low-loss and high-efficiency performance is desired, such as power electronics, radio frequency (RF) circuits, etc.

### SUMMARY

This Summary is provided to introduce examples of disclosed concepts in a simplified form, which are further described below in the Detailed Description including the drawings provided.

According to certain aspects, a semiconductor device may include a substrate having a channel layer and a barrier layer over the channel layer, a source contact electrically coupled to the channel layer, a gate structure over the barrier layer, and a drain contact structure. The drain contact structure includes a first drain contact electrically coupled to the channel layer, a semiconductor layer over the barrier layer and including a first semiconductor portion and a second semiconductor portion, and a second drain contact on the semiconductor layer and electrically coupled to the first drain contact. The second drain contact includes a first metal portion and a second metal portion, where the first metal portion and the first semiconductor portion form a first junction having a first energy barrier height, and the second metal portion and the second semiconductor portion form a second junction having a second energy barrier height lower than the first energy barrier height.

According to certain aspects, a method may include forming a patterned semiconductor layer over a barrier layer that is over a channel layer formed on a semiconductor substrate. The patterned semiconductor layer includes a plurality of regions, where each of the plurality of regions includes a first semiconductor portion and a second semiconductor portion. The method also includes forming first metal contacts on regions of the channel layer and first semiconductor portions of the plurality of regions of the patterned semiconductor layer, where the first semiconductor portions and the first metal contacts on the first semiconductor portions form first junctions. The method further includes depositing second metal contacts on second semiconductor portions of the plurality of regions of the patterned semiconductor layer, where the second semiconductor portions and the second metal contacts on the second semiconductor portions form second junctions having energy barrier heights greater than energy barrier heights of the first junctions.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1 is a cross-sectional view of an example of an enhancement mode high electron mobility transistor (HEMT) with an overlaid circuit model of the HEMT.

FIG. 2 is a cross-sectional view of another example of an enhancement mode HEMT with an overlaid circuit model of the HEMT.

FIG. 3A includes top-down views of an example of an HEMT including a hybrid drain contact structure.

FIG. 3B includes top-down views of another example of an HEMT including a hybrid drain contact structure.

FIG. 3C is a cross-sectional view of an example of a cross-section of the HEMT of FIG. 3A or 3B.

FIG. 3D is a cross-sectional view of another example of a cross-section of the HEMT of FIG. 3A or 3B.

FIG. 3E is a cross-sectional view of an example of a hybrid drain contact structure including a Schottky contact, with an overlaid circuit model of the hybrid drain contact structure.

FIG. 4 includes a graph illustrating reduction of the dynamic on-state resistance (dRon) of an HEMT using a hybrid drain contact.

FIG. 5A is a cross-sectional view of an example of an HEMT including a hybrid drain contact structure according to certain embodiments.

FIG. 5B illustrates examples of a hybrid drain contact structure.

FIG. 5C is a cross-sectional view of an example of a hybrid drain contact structure, with an overlaid circuit model of the hybrid drain contact structure.

FIG. 6A illustrates an example of an enhancement mode HEMT including a hybrid drain contact structure having a Schottky contact and an ohmic contact.

FIG. 6B illustrates an example of a depletion mode HEMT including a hybrid drain contact structure having a Schottky contact and an ohmic contact.

FIG. 7A illustrates an example of an enhancement mode HEMT including a hybrid drain contact structure having Schottky contacts of different barrier heights.

FIG. 7B illustrates an example of a depletion mode HEMT including a hybrid drain contact structure having Schottky contacts of different barrier heights.

FIG. 8A illustrates an example of an enhancement mode HEMT including a hybrid drain contact structure having Schottky contacts of different barrier heights and an ohmic contact.

FIG. 8B illustrates an example of a depletion mode HEMT including a hybrid drain contact structure having Schottky contacts of different barrier heights and an ohmic contact.

FIGS. 9A, 9B, and 9C illustrate an example of a drain region of an HEMT including a hybrid drain contact structure.

FIGS. 9D and 9E illustrate another example of a drain region of an HEMT including a hybrid drain contact structure.

FIGS. 10A, 10B, and 10C illustrate another example of a drain region of an HEMT including a hybrid drain contact structure.

FIGS. 10D and 10E illustrate yet another example of a drain region of an HEMT including a hybrid drain contact structure.

FIGS. 11A, 11B, 11C, 11D, 11E, 11F, 11G, and 11H illustrate examples of hybrid drain contact structures of HEMTs including a continuous semiconductor layer.

FIG. 12A illustrates an example of an enhancement mode HEMT including a hybrid drain contact structure.

FIG. 12B illustrates an example of an enhancement mode HEMT including a hybrid drain contact structure.

FIG. 12C illustrates another example of an enhancement mode HEMT including a hybrid drain contact structure.

FIGS. 13A, 13B, 13C, and 13D illustrate an example of a process of fabricating an HEMT including a hybrid drain contact structure.

FIG. 14 includes a flowchart illustrating an example of a process of fabricating an HEMT including a hybrid drain contact structure.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to a semiconductor device including a drain contact structure that includes junctions with different energy barrier heights. In some examples described herein, the semiconductor device includes a high electron mobility transistor (HEMT), such as a gallium nitride (GaN)-based enhancement mode or depletion mode HEMT. The junctions with the different energy barrier heights may be used to improve hole injection during switching at high drain voltage, mitigate current collapse, and reduce dynamic and static on-state resistance. Other benefits and advantages may also be achieved, such as simplifying layout, improving breakdown performance, and the like.

A GaN-based HEMT may include a heterojunction formed by a channel layer (e.g., a GaN layer) and a barrier layer (e.g., an aluminum gallium nitride (AlGaN) layer). A conductive channel can be formed by high-density two-dimensional electron gas (2DEG) at the heterojunction. For example, the 2DEG can have a sheet charge density greater than about 10¹³ cm⁻², and thus can have a very low on-state resistance. GaN-based HEMTs are attractive for high frequency and high power applications due to, for example, high breakdown field, high electron mobility, low static resistance, and high thermal conductivity of GaN-based HEMTs. However, GaN-based transistors may suffer from current collapse, which is an increase in the dynamic on-state drain-to-source resistance (RDSON) during high-voltage switching operations. Current collapse may result in, for example, power loss, temperature increase, and reliability issues.

Several factors may contribute to the current collapse. For example, when a lateral HEMT device is in the off-state with a high drain bias, the large negative gate-to-drain bias and thus high electric field can lead to electron injection and trapping at regions such as the heterojunction interface and barrier layer surface, while the large positive drain-to-substrate voltage may cause electrons to be injected from the substrate and trapped in the buffer stack between the channel layer and the substrate. In addition, when the HEMT device operates in high voltages (e.g., a few hundred volts), a hard switching can generate hot electrons in the channel, which may be injected and trapped, for example, in the dielectric, at the surface, in the GaN channel, and/or in the buffer. The trapped negative charges may at least partially deplete carriers (e.g., electrons) in the channel, causing a reduction in the channel carrier density and thus an increase in the channel resistance and a reduction in the current between the drain and the source (I_{DS}). Electron trapping at the interface and border regions beneath the gate electrode may also cause a positive shift in the threshold voltage. When the HEMT device is switched on, it may take a considerable amount of time to release the electrons from surface states and buffer traps so that the drain-to-source resistance may decrease.

A hybrid drain contact may be used to mitigate the electron trapping and current collapse effects. For example, a hybrid drain contact structure may include, in addition to the drain contact structure that forms an ohmic contact with the channel layer, a p-type drain contact structure that includes a p-doped semiconductor layer (e.g., a p-doped GaN (p-GaN) layer) positioned below a drain contact (e.g., a metal layer). When the voltage level applied to the drain contact is high and thus the voltage drop in the channel layer is high, a diode formed by the p-doped semiconductor layer and the underlying channel layer may be turned on to inject holes into the barrier layer, the channel layer, and/or the buffer layer, to neutralize the trapped electrons at the off-state and during the switching. In order to avoid depleting the 2DEG channel in the drain region by the p-doped semiconductor layer, the barrier layer (e.g., an AlGaN layer) under the p-doped semiconductor layer of the p-type drain contact structure may be thicker than the barrier layer under the p-doped semiconductor layer at the gate of an example of an enhancement mode HEMT (e-HEMT) that may be off without a positive gate voltage, and/or the p-doped semiconductor layer of the p-type drain contact structure may be thinner than the p-doped semiconductor layer at the gate of the enhancement mode HEMT. Therefore, fabricating normally-off GaN-based transistors (e.g., enhancement mode HEMTs, or e-HEMTs) with p-type drain contact structures may include growing the barrier layer or the p-GaN layer twice (or selective etching) to attain different barrier layer and/or p-doped semiconductor layer thicknesses at the gate and the drain. The additional processing steps may add significant costs and reduce yield/throughput.

In some enhancement mode GaN-based HEMTs, multiple p-type drain contact structures may be used to inject holes to neutralize the trapped electrons, thereby mitigating the current collapses. The barrier layer under the p-GaN layer of the p-type drain contact structures may have the same thickness as the barrier layer under the p-GaN layer at the gate of the enhancement mode HEMT, such that one epitaxial growth process may be used to grow the barrier layer to reduce the manufacturing cost. The p-GaN layer of the p-type drain contact structures and the p-GaN layer of the gate structure may also be fabricated using the same processes and may have the same thickness. Each of the multiple p-type drain contact structures may be physically separated from the remaining p-type drain contact structures, such that the 2DEG channel may be depleted mostly/only at certain regions at the drain, whereas other regions of the 2DEG channel at the drain are not depleted and thus may allow current to pass through. In this way, the current collapse may be reduced due to the hole injection by the multiple p-type drain contact structures, and the fabrication cost may also be reduced.

However, using the multiple separate p-type drain contact structures in GaN-based HEMTs may effectively reduce the channel width and increase the static R_{DS}. In addition, the p-type drain contact structures may include Schottky junctions formed by the metal contact and the underlying p-GaN layer. A Schottky junction may reduce the leakage current during operations of the e-HEMT because the Schottky junction may be reverse biased when a positive voltage is applied to the gate or drain metal contact. However, the Schottky junction may result in a back-to-back diode configuration, which in turn may result in a floating, quasi-neutral node in the p-GaN layer. The back-to-back diodes may form a voltage divider, which may reduce the effective drive voltage, increase drain-to-source on-state resistance, and reduce drain current (Id). The reduction in the effective drive voltage at the drain may result in a decrease in the hole injection capability of the p-type drain contact structure, and thus the p-type drain contact structure may be less effective in mitigating the current collapse. In switching events, the floating, quasi-neutral node may be biased based on past switching events due to its floating nature, and thus may have a memory effect. This biasing that depends on past switching events may result in non-deterministic behavior of the HEMT and may adversely affect the drain current of the HEMT. In addition, due to the reduced hole injection capability, the dynamic on-state resistance (dRₒₙ) of the HEMT during the switching (e.g., immediately after turning on the HEMT) may be higher, and the switching time may be longer before the on-state resistance of the HEMT settles to a static on-state resistance.

Examples of a hybrid drain contact structure that can address at least some of the issues above are disclosed herein. According to some examples, a hybrid drain contact structure includes both an ohmic contact coupled to the channel layer and a p-type drain contact structure. The p-type drain contact structure includes two or more junctions with different energy barrier heights formed by one or more metal materials and a p-type semiconductor layer (e.g., a p-GaN layer) over the barrier layer. In one example, the p-type drain contact structure includes a first metal portion and a second metal portion. The first metal portion forms a first junction with a first portion of the p-type semiconductor layer, and the second metal portion forms a second junction with a second portion of the p-type semiconductor layer. The energy barrier height of the first junction is different from the energy barrier height of the second junction. For example, the first junction may be a high-barrier Schottky (HBS) junction and the second junction may be a low-barrier junction such as a low-barrier Schottky (LBS) junction having a lower barrier height than the HBS junction, or an ohmic junction. In some examples, a LBS junction has a barrier height lower than 1.7 eV, and an HBS junction has a barrier height higher than 1.7 eV.

The ohmic junction and/or low-barrier junction may provide a Kelvin connection to the p-type semiconductor layer to remove the floating, quasi-neutral node and reduce the voltage drop between the drain electrical contact and the floating, quasi-neutral node. Reducing the voltage drop may improve the hole injection efficiency of the p-type drain contact structure for mitigating current collapse and reducing dynamic on-state resistance dRon. Due to the improved hole injection efficiency of the p-type drain contact structure, the p-type drain contact structure can be smaller to reduce the depleted region of the channel layer under the p-type drain contact structure (and the reduced channel width penalty), thereby reducing the static on-state resistance RDSON. As such, the channel length would not need to be reduced in order to reduce the static on-state resistance RDSON, and thus the breakdown voltage of the device may not be reduced. The smaller p-type drain contact structures may also simplify the layout. In addition, the voltage drop at the drain can be the same under DC conditions and in switching events. Therefore, the dynamic on-state resistance may be closer to the static on-state resistance.

In some examples of the p-type drain contact structure disclosed herein, the two or more junctions having different energy barrier heights may be implemented using a p-type semiconductor layer having a uniform composition and two or more different metal materials with different metal work functions. In some examples of the p-type drain contact structure, the two or more junctions having different energy barrier heights may be implemented using a same metal material and a same base semiconductor material (e.g., p-GaN) with different constituents (e.g., Al or In), different doping densities, and/or different levels of dopant activation in two or more different regions.

The hybrid drain contact structures disclosed herein may be used in enhancement mode HEMTs and depletion mode HEMTs. In some examples, an HEMT may include multiple p-type drain contact structures formed on separate regions of the p-type semiconductor layer. In some examples, the second metal portions of the multiple p-type drain contact structures and the drain contact metal that form the ohmic contact with the channel layer may include the same metal material, and may be parts of a continuous metal layer. In some examples, an HEMT disclosed herein may include one p-type drain contact structure that includes a continuous p-type semiconductor region, a continuous first metal portion, and a continuous second metal portion, where the barrier layer under the gate structure may have a lower thickness than the barrier layer under the p-type drain contact structure, and/or the p-type semiconductor layer in the gate structure may have a higher thickness than the p-type semiconductor layer in the p-type drain contact structure, in order to achieve a low on-state resistance. In such examples, the layout may be less complex, but additional fabrication processes (e.g., epitaxial growth or etching) may be needed.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to communicate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to communicate various aspects or concepts concerning those drain contact structures.

Various examples are described in the context of an HEMT. Some examples may be implemented in enhancement mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may focus on group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce 2DEG at the heterojunction interface.

GaN-based HEMTs include heterostructures that induce two-dimensional electron gas (2DEG) at the interface between two GaN-based materials with different bandgaps. In one example, the heterostructure may be formed by a GaN layer and an AlₓGa₍₁₋ₓ₎N layer, where x is the concentration of aluminum. The GaN layer has a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer (having the narrower bandgap) near the interface of the heterostructure to form a conductive channel in the GaN layer (which is referred to as the channel layer). Compared to silicon-based transistors, GaN-based transistors devices generally have high breakdown field, high electron mobility, low resistance, high current, faster-switching speed, high thermal conductivity, and excellent reverse-recovery performance, and thus may be suitable for applications where a low-loss and high-efficiency performance may be desired, such as power electronics.

A GaN-based transistor may include a gate structure positioned between a source structure and a drain structure. The drain structure may include a metal contact that is coupled to the channel layer and forms an ohmic contact with the channel layer. The source structure may include a metal contact that is coupled to the channel layer and forms an ohmic contact with the channel layer. Depending on the architecture of the gate structure, a GaN-based transistor may be an enhancement mode high electron mobility transistor (e-HEMT) or a depletion mode high electron mobility transistors (d-HEMT). For example, the gate structure of an e-HEMT may include a p-GaN layer formed over the barrier layer and a gate electrical contact (a metal electrode) formed on the p-GaN layer, which together form a p-GaN gate structure. The p-GaN layer may be doped using, for example, magnesium (Mg), which is an acceptor that makes the GaN layer p-type or p-doped. This p-GaN layer depletes electrons in the 2DEG channel under the p-GaN gate structure, such that the path between the source and gate may be disabled when no gate drive voltage is applied to the gate electrical contact. When a positive voltage above the gate threshold voltage is applied to the gate electrical contact, the gate structure may attract electrons to replete the 2DEG under the gate structure, thereby turning on the e-HEMT. In contrast, the gate structure of a d-HEMT may include an insulator layer (e.g., a dielectric layer) over the barrier layer and a gate electrical contact (e.g., a metal electrode) on the insulator layer. When no voltage signal is applied to the gate electrical contact, the 2DEG under the gate structure may not be depleted such that the path in the channel layer between the drain structure and the source structure may be enabled even without a positive gate voltage. A d-HEMT can be turned off by applying a negative threshold voltage to the gate electrical contact to deplete electrons from the 2DEG under the gate structure. In some applications such as switch-mode power applications, e-HEMTs, rather than d-HEMTs, may be used in order to, for example, decrease leakage current, reduce power loss, simplify the driving circuit, and/or improve device stability.

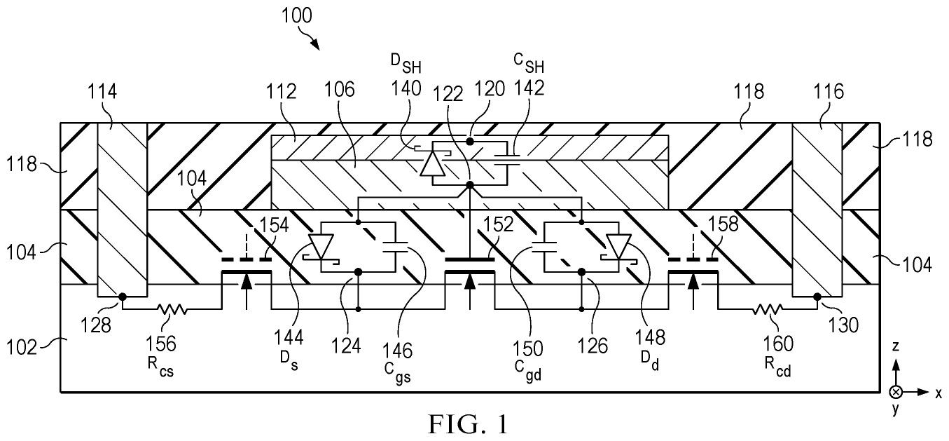

FIG. 1 is a cross-sectional view of an example of an enhancement mode HEMT 100 with an overlaid circuit model of HEMT 100. In the illustrated example, HEMT 100 includes a channel layer 102, a barrier layer 104 over channel layer 102, and a gate semiconductor layer 106 over barrier layer 104. Channel layer 102 and barrier layer 104 have different energy bandgaps. For example, channel layer 102 may include undoped GaN, and barrier layer 104 may include undoped AlGaN, which has a wider bandgap than GaN. The configuration of barrier layer 104 over channel layer 102 can induce a two-dimensional electron gas in channel layer 102 near the interface between channel layer 102 and barrier layer 104. A gate electrical contact 112 on gate semiconductor layer 106 forms a gate structure with gate semiconductor layer 106. Gate semiconductor layer 106 may be a p-doped semiconductor layer (e.g., a p-GaN layer) and can deplete electrons in the 2DEG under gate semiconductor layer 106. Gate electrical contact 112 and gate semiconductor layer 106 may form a junction having an energy barrier height that depends on the energy band structures of the materials of gate electrical contact 112 and gate semiconductor layer 106. In the illustrated example, gate electrical contact 112 and gate semiconductor layer 106 form a Schottky junction. A source electrical contact 114 and a drain electrical contact 116 are electrically coupled to channel layer 102 on opposing sides of gate semiconductor layer 106. A dielectric layer 118 is deposited on barrier layer 104, gate semiconductor layer 106, and gate electrical contact 112 to encapsulate and isolate the conductive materials. Source electrical contact 114 and drain electrical contact 116 pass through dielectric layer 118 and barrier layer 104 to contact channel layer 102.

FIG. 1 also shows a circuit model of HEMT 100. In the circuit model, a gate contact node 120 is in or on gate electrical contact 112, and a gate semiconductor layer node 122 is in gate semiconductor layer 106. A source-side channel node 124 and a drain-side channel node 126 are at an interface between channel layer 102 and barrier layer 104. A source contact node 128 is at the interface between source electrical contact 114 and channel layer 102, while a drain contact node 130 is at the interface between drain electrical contact 116 and channel layer 102.

At the gate structure, a Schottky diode (D_{SH}) 140 and a Schottky capacitor (C_{SH}) 142 are formed by gate electrical contact 112 and gate semiconductor layer 106, and are electrically coupled between gate contact node 120 and gate semiconductor layer node 122. The cathode terminal of Schottky diode 140 is electrically coupled to the gate contact node 120, and the anode terminal of Schottky diode 140 is electrically coupled to the gate semiconductor layer node 122. Similarly, a first terminal of Schottky capacitor 142 is electrically coupled to gate contact node 120, and a second terminal of Schottky capacitor 142 is electrically coupled to gate semiconductor layer node 122.

At the source side of a region under the gate structure, a p-type, intrinsic, n-type (p-i-n) source-side diode (Dₛ) 144 and a gate-to-source capacitor (C_{gs}) 146 are formed by gate semiconductor layer 106, barrier layer 104, and channel layer 102. Source-side diode 144 and gate-to-source capacitor 146 are electrically coupled between gate semiconductor layer node 122 and source-side channel node 124. The anode terminal of source-side diode 144 is electrically coupled to gate semiconductor layer node 122, and the cathode terminal of source-side diode 144 is electrically coupled to source-side channel node 124. A first terminal of gate-to-source capacitor 146 is electrically coupled to gate semiconductor layer node 122, and a second terminal of gate-to-source capacitor 146 is electrically coupled to source-side channel node 124.

At the drain side of the region under the gate structure, a p-i-n drain-side diode (D_{d}) 148 and a gate-to-drain capacitor (C_{gd}) 150 are formed by gate semiconductor layer 106, barrier layer 104, and channel layer 102. Drain-side diode 148 and gate-to-drain capacitor 150 are electrically coupled between gate semiconductor layer node 122 and drain-side channel node 126. The anode terminal of drain-side diode 148 is electrically coupled to gate semiconductor layer node 122, and the cathode terminal of drain-side diode 148 is electrically coupled to drain-side channel node 126. A first terminal of gate-to-drain capacitor 150 is electrically coupled to gate semiconductor layer node 122, and a second terminal of gate-to-drain capacitor 150 is electrically coupled to drain-side channel node 126.

The circuit model of HEMT 100 includes a field effect transistor (FET) 152 having a gate terminal electrically coupled to gate semiconductor layer node 122. The source terminal of FET 152 is electrically coupled to source-side channel node 124, and the drain terminal of FET 152 is electrically coupled to drain-side channel node 126. The circuit model of HEMT 100 also includes a FET 154, where the channel of FET 154 and a channel-to-source resistor (R_{cs}) 156 are serially connected between source-side channel node 124 and source contact node 128. The circuit model of HEMT 100 further includes a FET 158, where the channel of FET 158 and a channel-to-drain resistor (R_{cd}) 160 are serially connected between drain-side channel node 126 and drain contact node 130.

Having the Schottky junction between gate electrical contact 112 and gate semiconductor layer 106 (shown by Schottky diode 140 and Schottky capacitor 142 coupled between gate contact node 120 and gate semiconductor layer node 122) may result in low gate leakage current during operations of HEMT 100. When a positive voltage is applied to gate electrical contact 112 (e.g., gate contact node 120), the positive voltage may reverse bias the Schottky junction, which can result in a low gate leakage current. However, as illustrated by the circuit model, HEMT 100 with the gate structure having a Schottky junction between gate electrical contact 112 and gate semiconductor layer 106 includes a back-to-back diode configuration at gate semiconductor layer node 122, where the anode terminals of Schottky diode 140, source-side diode 144, and drain-side diode 148 are electrically coupled to a same node (gate semiconductor layer node 122). Such a back-to-back diode configuration may result in a voltage divider and a floating, quasi-neutral node (e.g., gate semiconductor layer node 122) in gate semiconductor layer 106 under some circumstances.

For example, under direct current (DC) conditions, the floating, quasi-neutral node in gate semiconductor layer 106 is in a voltage divider formed by Schottky diode 140 and source-side diode 144 or drain-side diode 148. The voltage divider may divide the voltage level applied to gate electrical contact 112, such that the effective voltage level applied to gate semiconductor layer 106 is lower than the voltage level applied to gate electrical contact 112. As a result, the drain current (I_{d}) may be lower, and the drain-to-source on-state resistance (R_{DSON}) may be higher in HEMT 100 with Schottky diode 140 than in an HEMT without Schottky diode 140.

In switching events, the floating, quasi-neutral node in gate semiconductor layer 106 may be biased by past switching events due to its floating nature. This biasing may result in non-deterministic behavior of HEMT 100 and may adversely affect the drain current of HEMT 100. Furthermore, when HEMT 100 is switched on, Schottky capacitor 142 may form a low impedance path initially, which may quickly pull the voltage level of gate semiconductor layer node 122 up to the voltage applied to gate contact node 120. However, following the initial switching, the voltage level of gate semiconductor layer node 122 may settle to a voltage level proportional to the voltage level applied on gate electrical contact 112 due to voltage dividing by the voltage divider. This voltage change at gate semiconductor layer node 122 may result in a drain current that has an initial peak and subsequently decreases and settles. Therefore, HEMT 100 may experience a dynamic gate overdrive voltage (V_{GT}).

In some examples, to address these effects, an HEMT may include a gate electrical contact that includes a first metal portion and a second metal portion. The first metal portion forms a first junction with a first semiconductor portion of the gate semiconductor layer (e.g., gate semiconductor layer 106), whereas the second metal portion forms a second junction with a second semiconductor portion of the gate semiconductor layer. An energy barrier height of the first junction is greater than the energy barrier height of the second junction. For example, the first junction may be a high-barrier Schottky junction, and the second junction may be a low-barrier junction such as a low-barrier Schottky (LBS) junction or ohmic junction.

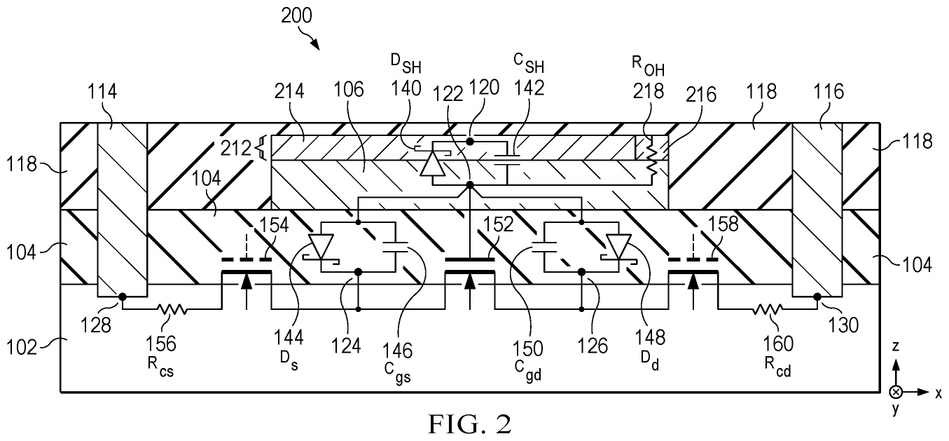

FIG. 2 is a cross-sectional view of another example of an enhancement mode HEMT 200 with an overlaid circuit model of HEMT 200. In the illustrated example, HEMT 200 includes most components of HEMT 100, and has a gate electrical contact 212 that is different from gate electrical contact 112 of HEMT 100. Gate electrical contact 212 includes a first metal portion 214 and a second metal portion 216 that are electrically shorted and have the same voltage level. First metal portion 214 and a portion of gate semiconductor layer 106 form a first junction, such as a Schottky junction described above. Second metal portion 216 and another portion of the gate semiconductor layer 106 form a second junction. In the example shown in FIG. 2, the second junction is an ohmic junction formed between second metal portion 216 and gate semiconductor layer 106. In another example, the second junction may be a Schottky junction having an energy barrier height lower than the energy barrier height of the first junction.

As shown in FIG. 2, the circuit model of HEMT 200 includes an ohmic resistor (R_{OH}) 218 electrically coupled between gate contact node 120 and gate semiconductor layer node 122. Ohmic resistor 218 is formed by the junction between second metal portion 216 and the second semiconductor portion of gate semiconductor layer 106. The ohmic junction or another low-barrier junction may provide an electrical path through which gate semiconductor layer node 122 (e.g., gate semiconductor layer 106) may be biased by the voltage applied to gate electrical contact 212, and thus may reduce the voltage drop between gate electrical contact 212 and gate semiconductor layer node 122. In addition, the small (e.g., close to zero) voltage drop can be the same under DC conditions and in switching events. Accordingly, the effective gate drive voltage can be increased (under DC conditions) and stabilized (in switching events), and thus the drain current (Id) can also be increased. In addition, because gate semiconductor layer 106 can be driven to a voltage level that more accurately tracks the voltage level at gate electrical contact 112 by bypassing Schottky capacitor 142, the drain current may be more stable in switching events, rather than having an initial peak and subsequently decreasing as described above with respect to FIG. 1. The surface areas of the first junction and the second junction may be scaled to obtain a target gate leakage while obtaining the stabilized gate overdrive voltage (V_{GT}) and increased drain current (I_{d}). For example, by having a surface area of the second junction relatively small compared to the surface area of the first junction, gate leakage may remain low, and a path to bias gate semiconductor layer 106 may still be provided to achieve stabilized gate overdrive voltage (V_{GT}) and increased drain current (I_{d}).

GaN-based HEMTs described above are attractive for high frequency and high power applications due to, for example, high breakdown voltage, high electron mobility, low static resistance, and high thermal conductivity of GaN-based HEMTs. However, GaN-based HEMTs may suffer from current collapse, which is an undesirable phenomenon of an increase in the dynamic on-state drain-to-source resistance (dRon) that occurs during high-voltage switching operations, for example, when the GaN-based HEMT is turned on and off and a high voltage level is applied to the drain of the transistor. Current collapse may result in, for example, power loss, temperature increase, and reliability issues.

Current collapse may be caused by electron and/or hole trapping, and can appear as a transient and recoverable reduction in the drain current (and increase in the effective resistance) during high-voltage switching operations. Several factors may contribute to current collapse, including electrons trapped at the surface of the barrier layer and/or in the buffer layer in the off state with a high drain bias, and hot electrons trapped during high voltage switching. For example, for an HEMT including an AlGaN barrier layer and a GaN channel layer, when the HEMT is in the off state and has the following voltage states: a high drain voltage (e.g., a few hundred volts such as about 600V or higher), a gate voltage below the threshold, and a grounded source voltage, high-energy electrons from the 2DEG may be injected towards the top of the AlGaN barrier layer and trapped by the surface states (resulting in a negatively charged surface) due to the high electric field caused by large negative gate-to-drain bias. The large positive drain-to-substrate voltage may cause electrons to be injected from the substrate and trapped in the buffer stack between the channel layer and the substrate. Furthermore, in the off state, the high drain voltage induces a high electric field, which may ionize holes in the heterostructure between the gate and the drain contact structures or underneath the drain contact structure. These ionized holes may be pulled towards the gate and/or source contact structures in the off state due to the electric field caused by the biasing, which may leave fixed negative charges in the heterostructure. When the HEMT operates with high drain voltages (e.g., a few hundred volts), a hard switching can generate hot electrons in the channel due to the high electric field, and the hot electrons may be injected and trapped, for example, in the dielectric, at the surface of the barrier layer, in the channel layer, and/or in the buffer layer. The trapped negative charges and the fixed negative charges in the heterostructure may at least partially deplete carriers (e.g., electrons) in the 2DEG channel, causing a reduction in the channel carrier density and thus an increase in the resistance.

When the HEMT is switched on (e.g., when the gate voltage is above the threshold voltage in an e-HEMT), the dynamic on-state drain-to-source resistance may be high initially as compared to a static on-state drain-to-source resistance, due to the lower channel carrier density caused by carrier depletion by the negative charges. The trapped electrons and fixed negative charges may be slowly detrapped or neutralized by holes injected from the drain, and the remaining negative charges may continue to deplete the 2DEG, leading to a slow reduction of the drain-to-source resistance.

In some examples, a hybrid drain contact may be used to mitigate the electron trapping and current collapse effects. For example, a hybrid drain contact structure may include, in addition to the drain contact structure that forms an ohmic contact with the channel layer, a p-type drain contact structure that includes a p-doped semiconductor layer (e.g., a p-GaN layer) positioned below a drain electrical contact (e.g., a metal layer). Therefore, the hybrid drain contact structure includes both the drain contact structure and the p-type drain contact structure that are electrically coupled and driven by the same drain voltage. The hybrid drain contact structure may be used to inject holes to neutralize the trapped electrons at the off state and during the switching, due to the high voltage applied to the drain contact, thereby reducing the current collapse effect.

However, in an enhancement mode HEMT with the p-type drain contact structure, in order to avoid depleting the 2DEG channel in the drain region by the p-doped semiconductor layer (e.g., a p-GaN layer), the barrier layer (e.g., an AlGaN layer) under the p-doped semiconductor layer of the p-type drain contact structure may need to be thicker than the barrier layer under the p-doped semiconductor layer at the gate of the enhancement mode HEMT, and/or the p-doped semiconductor layer of the p-type drain contact structure may need to be thinner than the p-doped semiconductor layer at the gate of the enhancement mode HEMT. The different thicknesses are needed for normally-off operation because the barrier layer below the p-type gate contact structure may need to be thin enough to ensure that the threshold voltage (Vt) is greater than zero (positive), while the barrier layer below the p-type drain contact structure needs to be thick to prevent the p-type drain contact structure from depleting the electrons from the 2DEG channel below it and enable current flow during the on state. In this way, in the off state, the 2DEG is only depleted at the gate of the e-HEMT with the p-type drain contact structure. Having a thicker p-doped semiconductor layer at the p-type gate contact structure and a thinner p-doped semiconductor layer at the p-type drain contact structure may achieve similar results. Therefore, fabricating normally-off GaN-based transistors (e.g., e-HEMTs) with p-type drain contact structures may include growing the barrier layer or the p-doped semiconductor layer twice (or selective etching) to attain different barrier layer thicknesses and/or different thicknesses of the p-doped semiconductor layer at the gate and the drain. The additional processing steps (e.g., epitaxial growth) may increase manufacturing costs and reduce both yield and throughput.

In some enhancement mode GaN-based HEMTs, multiple p-type drain contact structures may be used to inject holes to neutralize the trapped electrons, thereby mitigating the current collapses. The barrier layer under the p-GaN layer of the p-type drain contact structures may have the same thickness as the barrier layer under the p-GaN layer at the gate of the enhancement mode HEMT, such that one epitaxial growth process may be used to grow the barrier layer to reduce the manufacturing cost. The p-GaN layer of the p-type drain contact structures and the p-GaN layer of the gate structure may also be fabricated using the same processes and may have the same thickness. Each of the multiple p-type drain contact structures may be physically separate from the remaining p-type drain contact structures, such that the 2DEG channel may only be depleted at isolated regions at the drain, whereas other regions of the 2DEG channel at the drain are not depleted and thus may allow current to pass through. In this way, the current collapse may be reduced due to the hole injection by the multiple p-type drain contact structures, and the fabrication cost may also be reduced.

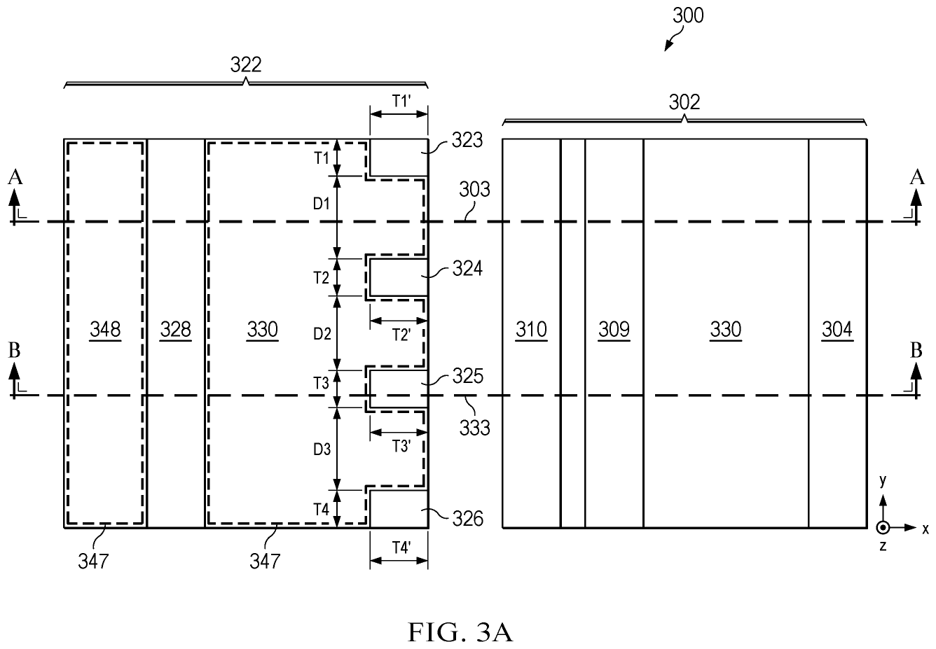

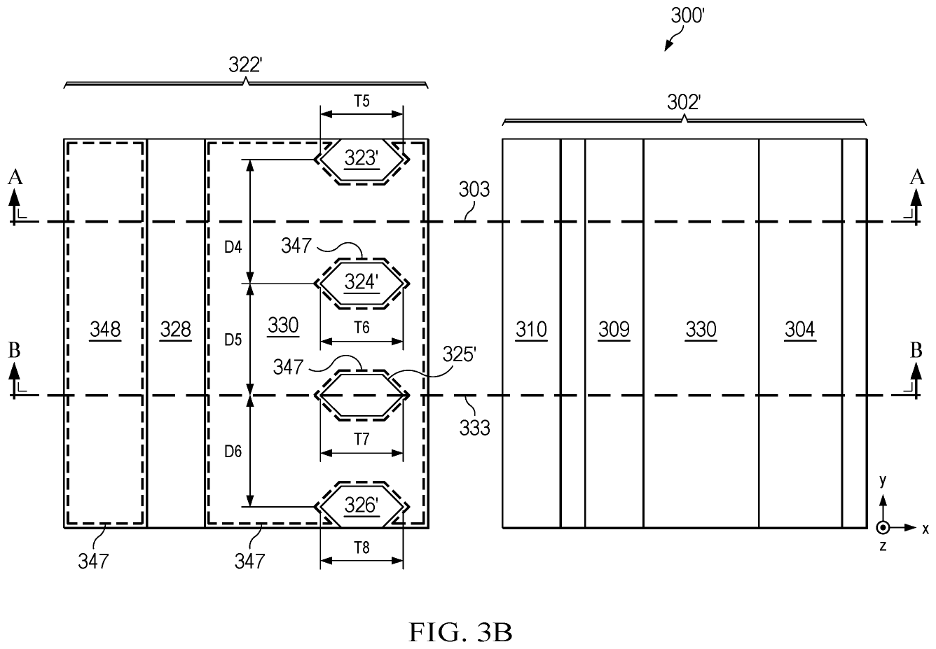

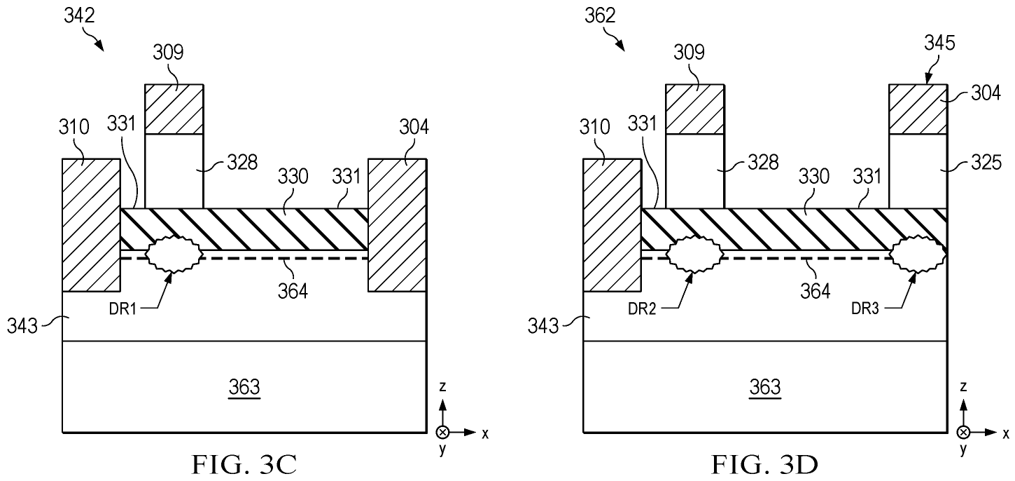

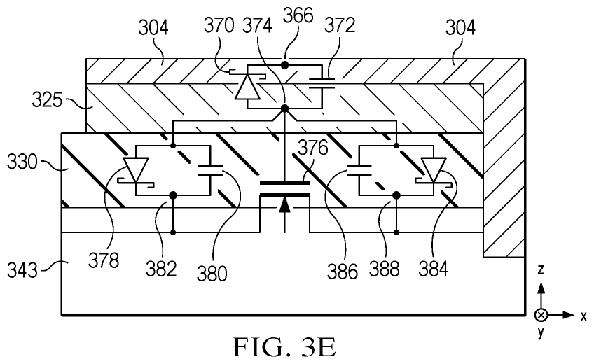

FIG. 3A includes top-down views of an example of an HEMT 300 including a hybrid drain contact structure. In the illustrated example, HEMT 300 is an enhancement mode GaN-based transistor that includes multiple p-type drain contact structures, where each p-type drain contact structure of the multiple p-type drain contact structures includes a p-doped semiconductor layer (e.g., a p-GaN block) and a drain contact structure (e.g., a metal contact). The top-down views include a top-down view 302 of HEMT 300 that includes some contact structures (e.g., metal contact layers) at the drain, gate, and source of HEMT 300, and a top-down view 322 of HEMT 300 that does not include some contact structures at the drain, gate, and source of HEMT 300. Top-down view 302 depicts a source contact structure 310, a gate contact structure 309, a drain contact structure 304, and a barrier layer 330. Top-down view 322 depicts the layers of HEMT 300 underneath the contact structures depicted in the top-down view 302, including a channel layer 348, a p-GaN gate structure 328 that enables HEMT 300 to operate in an enhancement mode, barrier layer 330, and an array of p-GaN blocks 323, 324, 325, and 326. The array of p-GaN blocks 323, 324, 325, and 326 on barrier layer 330 and p-GaN gate structure 328 may be fabricated by epitaxial growth of a p-GaN layer on barrier layer 330 and patterning the p-GaN layer by selective etching. In one example, barrier layer 330 includes an AlGaN layer, and channel layer 348 includes a GaN layer, where the AlGaN layer and the GaN layer form a heterostructure that induces 2DEG in the GaN layer at the interface between the AlGaN layer and the GaN layer.

In HEMT 300, source contact structure 310 may be formed on and in contact with a source region of channel layer 348, to form an ohmic source contact. Gate contact structure 309 is positioned on p-GaN gate structure 328 to form the gate structure of the enhancement mode HEMT. Drain contact structure 304 may be formed on and in contact with a drain region of channel layer 348 to form an ohmic drain contact with the channel layer. Drain contact structure 304 may also be formed on and in contact with the array of p-GaN blocks 323, 324, 325, and 326, to form multiple p-type drain contact structures for mitigating current collapse. The ohmic drain contact and the multiple p-type drain contact structures form a hybrid drain contact structure. In the illustrated example, the array of p-GaN blocks 323, 324, 325, and 326 are underneath drain contact structure 304. In some other examples, the array of p-GaN blocks 323, 324, 325, and 326 may be positioned on a side of drain contact structure 304 in the x direction (the channel length direction of HEMT 300). In the illustrated example, each p-GaN block of the array of p-GaN blocks 323, 324, 325, and 326 has a rectangular shape in the top-down view. In other examples, each p-GaN block of the array of p-GaN blocks 323, 324, 325, and 326 may have another regular, irregular, or arbitrary shape.

As shown in top-down view 322, p-GaN blocks 323, 324, 325, and 326 have widths T1, T2, T3, and T4, respectively, along the channel width direction (e.g., y direction). In the illustrated example, p-GaN blocks 323, 324, 325, and 326 have the same widths. In other examples, widths T1, T2, T3, and T4 may be unequal. Top-down view 322 also shows that p-GaN blocks 323, 324, 325, and 326 have lengths T1′, T2′, T3′, and T4′, respectively, in the channel length direction (e.g., the x direction). In the example illustrated in FIG. 3A, p-GaN blocks 323, 324, 325, and 326 have equal lengths. In other examples, lengths T1′, T2′, T3′, and T4′ may be unequal. In the illustrated example, the length of drain contact structure 304 may be similar to the lengths of p-GaN blocks 323, 324, 325, and 326 in the channel length direction. In other examples, the length of drain contact structure 304 may be different from (e.g., shorter or longer than) the lengths of p-GaN blocks 323, 324, 325, and 326 in the channel length direction.

As also shown in top-down view 322 of FIG. 3A, regions 347 of HEMT 300 do not have p-GaN gate structure 328 or the array of p-GaN blocks 323, 324, 325, and 326 over barrier layer 330. Therefore, the 2DEG in regions 347 is not depleted, and there are conductive paths in the channel layer between the gate and the drain of HEMT 300 even when HEMT 300 is in the off state. For example, the conductive path of the channel layer between p-GaN blocks 323 and 324 may have a width D1, the conductive path of the channel layer between p-GaN blocks 324 and 325 may have a width D2, and the conductive path of the channel layer between p-GaN blocks 325 and 326 may have a width D3. D1, D2, and D3 may be the same or may be different. As such, barrier layer 330 under p-GaN gate structure 328 and the array of p-GaN blocks 323, 324, 325, and 326 can have the same thickness, without turning off the 2DEG channel between the gate and the drain of HEMT 300 even when HEMT 300 is in the off state. In this way, each of barrier layer 330 and the p-GaN layer above barrier layer 330 can be grown in one epitaxial growth process.

FIG. 3B includes top-down views of another example of an HEMT 300′ including a hybrid drain contact structure. HEMT 300′ may be similar to HEMT 300, but may include p-GaN blocks having shapes different from the shapes of p-GaN blocks 323, 324, 325, and 326 of HEMT 300. As HEMT 300, HEMT 300′ is an enhancement mode GaN-based transistor that includes multiple p-type drain contact structures, where each p-type drain contact structure of the multiple p-type drain contact structures includes a p-doped semiconductor layer (e.g., a p-GaN block) and a drain contact structure (e.g., a metal contact). The top-down views include a top-down view 302′ of HEMT 300′ that shows some contact structures (e.g., metal contact layers) at the drain, gate, and source of HEMT 300′, and a top-down view 322′ of HEMT 300′ that does not include some contact structures at the drain, gate, and source of HEMT 300′. Top-down view 302′ depicts source contact structure 310, gate contact structure 309, drain contact structure 304, and barrier layer 330. Top-down view 322′ depicts the layers of HEMT 300′ underneath the contact structures depicted in top-down view 302′, including channel layer 348, p-GaN gate structure 328 that enables HEMT 300′ to function in a normally-off mode, barrier layer 330, and an array of p-GaN blocks 323′, 324′, 325′, and 326′. The array of p-GaN blocks 323′, 324′, 325′, and 326′ on barrier layer 330 and p-GaN gate structure 328 may be formed, for example, by epitaxial growth of a p-GaN layer over barrier layer 330 and patterning the p-GaN layer by selective etching, or by selective area growth.

In HEMT 300′, source contact structure 310 may be formed on and in contact with a source region of channel layer 348, to form an ohmic source contact. Gate contact structure 309 is positioned on p-GaN gate structure 328 to form the gate structure of the enhancement mode HEMT. Drain contact structure 304 may be formed on and in contact with a drain region of channel layer 348 to form an ohmic drain contact with the channel layer. Drain contact structure 304 may also be formed on and in contact with the array of p-GaN blocks 323′, 324′, 325′, and 326′, to form multiple p-type drain contact structures for mitigating current collapse. The ohmic drain contact and the multiple p-type drain contact structures form a hybrid drain contact structure.

In the illustrated example, the array of p-GaN blocks 323′, 324′, 325′, and 326′ are underneath drain contact structure 304, where each p-GaN block of the array of p-GaN blocks 323′, 324′, 325′, and 326′ has a hexagonal shape in the top-down view. In other examples, edges of each p-GaN block of the array of p-GaN blocks 323′, 324′, 325′, and 326′ may be straight lines or may include curves (e.g., a parabolic curve), and each p-GaN block may have a regular, irregular, or arbitrary shape. In the illustrated example, each p-GaN block is tapered in a direction towards p-GaN gate structure 328. The tapering may be linear or nonlinear (e.g., parabolic). As shown in top-down view 322′, p-GaN blocks 323′, 324′, 325′, and 326′ have lengths T5, T6, T7, and T8, respectively, in the channel length direction (e.g., the x direction). In the example illustrated in FIG. 3B, p-GaN blocks 323′, 324′, 325′, and 326′ have equal lengths. In other examples, lengths T5, T6, T7, and T8 may be unequal. In the illustrated example, the length of drain contact structure 304 may be similar to the lengths of p-GaN blocks 323′, 324′, 325′, and 326′ in the channel length direction. In other examples, the length of drain contact structure 304 may be different from the lengths of p-GaN blocks 323, 324, 325, and 326 in the channel length direction.

As also shown in top-down view 322′ of FIG. 3A, regions 347 of HEMT 300′ do not have p-GaN gate structure 328 or the array of p-GaN blocks 323′, 324′, 325′, and 326′ over barrier layer 330. Therefore, the 2DEG in regions 347 is not depleted, and there are conductive paths in the channel layer between the gate and the drain of HEMT 300′ even when HEMT 300′ is in the off state. For example, the distance between the centers of p-GaN blocks 323′ and 324′ is D4, which may be much larger than the width of p-GaN block 323′ or 324′ in the channel width direction (e.g., y direction). The distance between the centers of p-GaN blocks 324′ and 325′ is D5, which may be much larger than the width of p-GaN block 324′ or 325′ in the channel width direction. The distance between the centers of p-GaN blocks 325′ and 326′ is D6, which may be much larger than the width of p-GaN block 324′ or 325′ in the channel width direction. As such, barrier layer 330 under p-GaN gate structure 328 and the array of p-GaN blocks 323′, 324′, 325′, and 326′ can have the same thickness, without turning off the 2DEG channel between the gate and the drain of HEMT 300′ even when HEMT 300′ in the off state. In this way, each of barrier layer 330 and the p-GAN layer above barrier layer 330 can be grown in one epitaxial growth process. In addition, the linear or nonlinear tapering of p-GaN blocks 323′, 324′, 325′, and 326′, and thus the linear or nonlinear tapering of 2DEG channels between the p-GaN blocks near the drain, may facilitate the movement of the carriers in the 2DEG channel, such that the channel resistance of HEMT 300′ may be lower than the channel resistance of HEMT 300 having the rectangular-shaped p-GaN blocks.

FIG. 3C is a cross-sectional view 342 of an example of a cross-section of the HEMT of FIG. 3A or 3B along a line 303. Cross-sectional view 342 shows drain contact structure 304 that is in ohmic contact with a channel layer 343 of HEMT 300 or 300′. In the illustrated example, the HEMT includes a substrate 363, channel layer 343 grown on substrate 363, and barrier layer 330 grown on channel layer 343. Substrate 363 may include, for example, silicon, silicon carbide, sapphire, gallium nitride, or other suitable substrate material or substrate consisting of multiple materials. In some examples, the substrate material (e.g., silicon) may have a large lattice structure mismatch with GaN, and substrate 363 may include one or more seed layers or buffer layers (e.g., aluminum nitride, not shown in FIG. 3C) deposited on it to facilitate high quality epitaxial growth of the GaN-based material layers (e.g., with low defect density and appropriate thicknesses).

Channel layer 343 may include, for example, GaN, which may be doped or undoped. Barrier layer 330 may include, for example, AlₓGa₍₁₋ₓ₎N. In some examples, the thickness of barrier layer 330 may be in the range of a few nanometers (e.g., about 1 nm) to tens of microns (e.g., about 20 microns). In some examples, the thickness of barrier layer 330 can be in the range of a few nanometers (e.g., about 1 nm) to hundreds of nanometers (e.g., about 1000 nm). In some examples, the AlₓGa₍₁₋ₓ₎N material in barrier layer 330 may include other elements, such as indium (In). For example, barrier layer 330 may have a composition Al_{(X)}In_{(Y)}Ga_{(1-X-Y)}N, where X and Y are the concentrations of Aluminum and Indium, respectively, and may be selected to achieve the desired energy band structure and lattice constant. In some examples, barrier layer 330 may have a uniform composition, such as a uniform composition of Al_{0.3}Ga_{0.7}N. In other examples, barrier layer 330 may have a graded composition of Aluminum, Gallium, and Indium, in different regions of a same layer or in different sublayers. Due to the different energy band structures of the materials of channel layer 343 and barrier layer 330, channel layer 343 and barrier layer 330 form a heterostructure that induces 2DEG 364 in channel layer 343 near the interface between channel layer 343 and barrier layer 330.

To form the gate structure of an e-HEMT, a p-doped semiconductor layer (e.g., p-GaN layer) may be grown on a top side 331 of barrier layer 330 and patterned by selective etching (e.g., using an etch mask) to form p-GaN gate structure 328, and then gate contact structure 309 may be deposited on p-GaN gate structure 328. The thicknesses of p-GaN gate structure 328 and barrier layer 330 under p-GaN gate structure 328 may be selected such that 2DEG 364 under p-GaN gate structure 328 may be depleted in depleted region DR1, such that the HEMT may be off without a positive gate voltage. In one example, gate contact structure 309 and p-GaN gate structure 328 may form a Schottky junction as described above with respect to, for example, FIG. 1.

Barrier layer 330 may be etched to expose regions of channel layer 343, and drain contact structure 304 and source contact structure 310 may be deposited on the exposed regions of channel layer 343 to form ohmic drain and source contacts with channel layer 343. The ohmic contact is a low resistance junction that provides a low-resistance conduction between channel layer 343 and either source contact structure 310 or drain contact structure 304. In some examples, source contact structure 310 and drain contact structure 304 may be fabricated such that they extend into barrier layer 330 and couple to channel layer 343 through quantum tunneling, rather than ohmic contact. As illustrated, in the cross-section shown in cross-sectional view 342, 2DEG 364 is not deleted near the drain region. As shown in FIGS. 3A and 3B, in HEMTs 300 and 300′, there are multiple regions between the p-GaN blocks at the drain region where 2DEG 364 is not deleted in the off state and can provide a low-resistance current path.

FIG. 3D is a cross-sectional view 362 of another cross-section of the HEMT of FIG. 3A or 3B along a line 333. Cross-sectional view 362 shows drain contact structure 304 on a p-GaN block 325 (or p-GaN block 325′). As described above, in some examples, p-GaN block 325 may be fabricated using the same processes for fabricating p-GaN gate structure 328, and thus may have the same material and thickness as p-GaN gate structure 328. The region of barrier layer 330 under p-GaN block 325 and the region of barrier layer 330 under p-GaN gate structure 328 may also be fabricated using the same processes and may have the same thickness. As such, 2DEG 364 under p-GaN gate structure 328 may be depleted in depleted region DR2, and 2DEG 364 under p-GaN block 325 may also be depleted in depleted region DR3. Other p-type drain contact structures formed by other p-GaN blocks (e.g., p-GaN blocks 323, 324, and 326) may have similar configurations. As the p-GaN gate structure described above with respect to FIG. 1, drain contact structure 304 and the p-GaN blocks (e.g., p-GaN blocks 323, 324, 325, and 326) may form Schottky junctions to inject holes for neutralizing trapped electrons. Because each of the multiple p-type drain contact structures is physically separate from the remaining p-type drain contact structures, 2DEG 364 may only be depleted at isolated regions at the drain, whereas other regions of 2DEG 364 at the drain are not depleted and thus may provide a low-resistance current path. In this way, the current collapse may be reduced, and the fabrication cost may also be reduced.

Since 2DEG 364 under the p-GaN blocks at the drain region may be depleted by the p-GaN blocks in the static on state, the effective channel width of the HEMT may be reduced and thus the static on-state resistance of HEMT 300 or 300′ may be higher than the static on-state resistance of an HEMT without the p-GaN blocks at the drain region. Therefore, it may be desirable to reduce the sizes (e.g., widths) of the p-GaN blocks to reduce the static on-state resistance of HEMT 300 or 300′. On the other hand, increasing the sizes of the p-GaN block may improve the hole injection efficiency and reduce the dynamic on-state resistance of the HEMT. Therefore, the sizes (e.g., widths) of the p-GaN blocks may need to be selected to balance the reduction of the dynamic on-state resistance and the increase of the static on-state resistance.

In addition, as described above with respect to FIG. 1, the Schottky junction in the HEMT may result in a back-to-back diode configuration, which in turn may result in a floating, quasi-neutral node in the p-GaN layer. The back-to-back diodes may form a voltage divider, which may reduce the effective drive voltage, reduce drain current (I_{d}), and increase drain-to-source on-state resistance (R_{DSON}). The reduction in the effective drain drive voltage may result in a decrease in the hole injection capability of the p-type drain contact structure, and thus the p-type drain contact structure may be less effective in mitigating the current collapse. In switching events, the floating, quasi-neutral node may be biased based on past switching events due to its floating nature, and thus may have a memory effect. This biasing that depends on past switching events may result in a non-deterministic behavior of the HEMT and may adversely affect the drain current of the HEMT. In addition, due to the reduced hole injection capability, the dynamic R_{DSON} may be higher and the switching time may be longer.

FIG. 3E is a cross-sectional view of an example of a hybrid drain contact structure including a Schottky contact, with an overlaid circuit model of the hybrid drain contact structure. The hybrid drain contact structure includes a portion of drain contact structure 304 that forms an ohmic contact with channel layer 343, and a portion of drain contact structure 304 that forms a Schottky contact with p-GaN block 325. As illustrated, p-GaN block 325 is formed on barrier layer 330, which is grown on channel layer 343. In the circuit model, a drain contact node 366 is in drain contact structure 304, and a p-GaN drain node 374 is in p-GaN block 325. One or more channel nodes, such as a first channel node 382 and a second channel node 388, are at an interface between channel layer 343 and barrier layer 330.

A Schottky diode 370 and a Schottky capacitor 372 are formed by drain contact structure 304 and p-GaN block 325, and are electrically coupled between drain contact node 366 and p-GaN drain node 374. The cathode terminal of Schottky diode 370 is electrically coupled to drain contact node 366, and the anode terminal of Schottky diode 370 is electrically coupled to the p-GaN drain node 374. Similarly, a first terminal of Schottky capacitor 372 is electrically coupled to drain contact node 366, and a second terminal of Schottky capacitor 372 is electrically coupled to p-GaN drain node 374.

A first side diode 378 (e.g., a p-i-n diode) and a first side capacitor 380 are formed by p-GaN block 325, barrier layer 330, and channel layer 343. First side diode 378 and first side capacitor 380 are electrically coupled between p-GaN drain node 374 and first channel node 382. The anode terminal of first side diode 378 is electrically coupled to p-GaN drain node 374, and the cathode terminal of first side diode 378 is electrically coupled to first channel node 382. A first terminal of first side capacitor 380 is electrically coupled to p-GaN drain node 374, and a second terminal of first side capacitor 380 is electrically coupled to first channel node 382.

In examples where p-GaN block 325 is separate from the portion of drain contact structure 304 that forms the ohmic contact with channel layer 343, a second side diode 384 (e.g., a p-i-n diode) and a second side capacitor 386 may be formed by p-GaN block 325, barrier layer 330, and channel layer 343. Second side diode 384 and second side capacitor 386 are electrically coupled between p-GaN drain node 374 and second channel node 388. The anode terminal of second side diode 384 is electrically coupled to p-GaN drain node 374, and the cathode terminal of second side diode 384 is electrically coupled to second channel node 388. A first terminal of second side capacitor 386 is electrically coupled to p-GaN drain node 374, and a second terminal of second side capacitor 386 is electrically coupled to second channel node 388. The circuit model of the hybrid drain contact structure also includes a field effect transistor (FET) 376 having a gate terminal electrically coupled to p-GaN drain node 374. The source terminal of FET 376 is electrically coupled to first channel node 382, and the drain terminal of FET 376 is electrically coupled to second channel node 388.

As illustrated by the circuit model, the hybrid drain contact structure with the Schottky junction between drain contact structure 304 and p-GaN block 325 includes a back-to-back diode configuration at p-GaN drain node 374, where the anode terminals of Schottky diode 370, first side diode 378, and second side diode 384 are electrically coupled to a same node (e.g., p-GaN drain node 374). Such a back-to-back diode configuration may result in a voltage divider and a floating, quasi-neutral node (e.g., p-GaN drain node 374) in p-GaN block 325 under some circumstances. In switching events, the floating, quasi-neutral node in p-GaN block 325 may be biased by past switching events due to its floating nature. This biasing may result in a non-deterministic behavior of the HEMT and may adversely affect the drain current of the HEMT. The floating, quasi-neutral node in p-GaN block 325 is in a voltage divider formed by Schottky diode 370 and first side diode 378 (and/or second side diode 384). The voltage divider may divide the voltage level applied to drain contact structure 304, such that the effective voltage level applied to p-GaN block 325 is lower than the voltage level applied to drain contact structure 304, and thus the voltage applied across the first side diode 378 (and/or second side diode 384) is reduced. As a result, the drive strength and the hole injection efficiency of the hybrid drain contact structure may be reduced, and the dynamic on-state resistance of the HEMT may still be high.

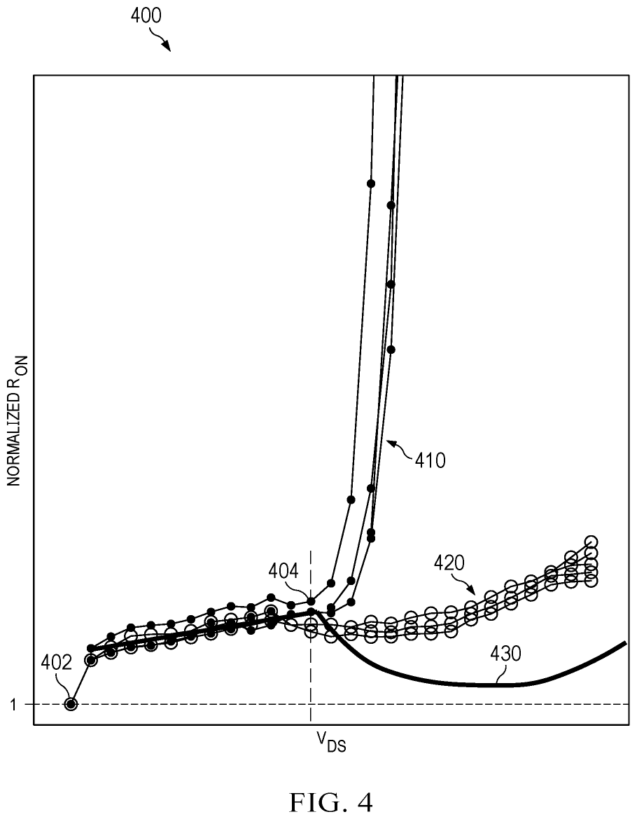

FIG. 4 includes a graph 400 illustrating reduction of the dynamic on-state resistance (dRon) of an HEMT using a hybrid drain contact. In graph 400, the horizontal axis represents the drive voltage (e.g., VDD) applied to the drain or the voltage difference VDs between the drain and source of the HEMT before the HEMT is switched on, and the vertical axis represents normalized dynamic on-state resistance of the HEMT. The normalized dynamic on-state resistance is the ratio between the dynamic on-state resistance and the static on-state resistance. Plot 410 show normalized dynamic on-state resistance of HEMTs without hybrid drain contacts, such as HEMT 100 or 200 described above with respect to FIGS. 1 and 2. Plots 420 show normalized dynamic on-state resistance of HEMTs having hybrid drain contacts, such as HEMT 300 or 300′ described above with respect to FIGS. 3A and 3B.

When V_{DS} is low, for example, when the drive voltage applied to the drain is low, the dynamic on-state resistance of an HEMT without hybrid drain contacts (e.g., HEMT 100 or 200) may be close to the static on-state resistance of the HEMT because the electron trapping and current collapse generally occur when the drive voltage applied to the drain (and thus VDs) is high as described above. Therefore, the normalized dynamic on-state resistance may be close to 1 at low drive voltage as shown by, for example, a data point 402 in FIG. 4. As the drive voltage applied to the drain (and thus V_{DS}) before a switching increases, more and more electrons may be trapped before and during the switching to deplete the 2DEG channel, and thus the current collapse may become more and more severe and the normalized dynamic on-state resistance may become larger. When the drive voltage applied to the drain (and thus V_{DS}) before the switching is sufficiently high (e.g., higher than the V_{DS} at a data point 404), the 2DEG between the drain and the gate of the HEMT may be depleted such that the 2DEG channel is switched off, and thus the normalized dynamic on-state resistance may become very large.

When a hybrid drain contact in, for example, FIGS. 3A and 3B, is used in an HEMT (e.g., HEMT 300 or 300′), if the drive voltage applied to the drain (and thus V_{DS}) before switching is low, the electron trapping and current collapse may increase as the drive voltage applied to the drain increases, but if the voltage difference between the p-type drain contact structure and the channel layer under the p-type drain contact structure is not large enough to turn on the diodes, the p-type drain contact structure may inject very few holes, or does not inject holes at all, to neutralize the trapped negative charges. Therefore, the normalized dynamic on-state resistance may increase as the drive voltage applied to the drain increases. When the drive voltage applied to the drain (and thus V_{DS}) before a switching is sufficiently high (e.g., higher than the VDs at a data point 404), the voltage difference between the drain contact structure (e.g., drain contact structure 304) and the channel layer under the p-GaN block can be sufficiently high to turn on the diodes (e.g., the p-i-n diode) to inject holes to neutralize the trapped negative charges. As a result, the normalized dynamic on-state resistance may reduce as shown by curves 420, rather than becoming very large as shown by curves 410. But the normalized dynamic on-state resistance may increase as the drain drive voltage continues to increase as shown by curves 420.

As shown in FIG. 4, using a hybrid drain contact structure in FIGS. 3A and 3B, the current collapse may be reduced but the normalized dynamic on-state resistance may still be significantly higher than 1 at high drain drive voltages. The high normalized dynamic on-state resistance may be at least partially caused by the back-to-back diode configuration of the hybrid drain contact structure with the Schottky contact. As described above, the back-to-back diode configuration may function as a voltage divider that effectively reduces the voltage level at the p-GaN block, and thus the efficiency of hole injection from the p-GaN block to the barrier layer and channel layer may be reduced.

According to certain examples, a drain contact structure disclosed herein includes a hybrid drain contact structure that includes both an ohmic contact coupled to the channel layer and a p-type drain contact structure that includes two or more junctions with different energy barrier heights formed by one or more metal materials and a p-type semiconductor layer (e.g., a p-GaN layer) over the barrier layer. In one example, the p-type drain contact structure includes a first metal portion and a second metal portion. The first metal portion forms a first junction with a first portion of the p-type semiconductor layer, and the second metal portion forms a second junction with a second portion of the p-type semiconductor layer. The energy barrier height of the first junction is different from the energy barrier height of the second junction. For example, the first junction may be a high-barrier Schottky (HBS) junction, and the second junction may be a low-barrier junction such as a low-barrier Schottky (LBS) junction or an ohmic junction. In some examples, the HBS junction has a barrier height greater than 1.7 eV, and the LBS junction has a barrier height lower than 1.7 eV.

The ohmic junction and/or low-barrier junction may provide a Kelvin connection to the p-type semiconductor layer to remove the floating, quasi-neutral node and reduce the voltage drop between the drain electrical contact and the floating, quasi-neutral node. Reducing the voltage drop may improve the hole injection efficiency of the p-type drain contact structure for mitigating current collapse and reducing dynamic on-state resistance (dRon). Due to the improved hole injection efficiency of the p-type drain contact structure, the p-type drain contact structure can be smaller to reduce the depleted region of the channel layer under the p-type drain contact structure (and the reduced channel width penalty), thereby reducing the static on-state resistance R_{DSON}. As such, the channel length does not need to be reduced in order to reduce the static on-state resistance R_{DSON}. The smaller p-type drain contact structures may also simplify the layout. In addition, the voltage drop at the drain can be the same under DC conditions and in switching events. Therefore, the dynamic on-state resistance may be closer to the static on-state resistance, as shown by a plot 430 in FIG. 4.

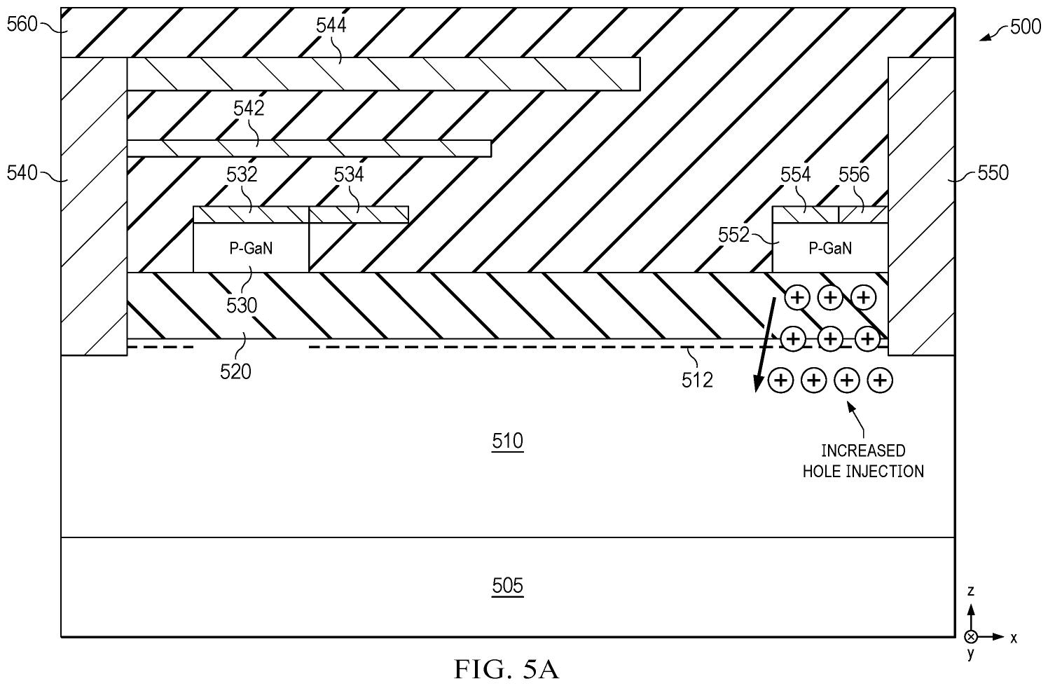

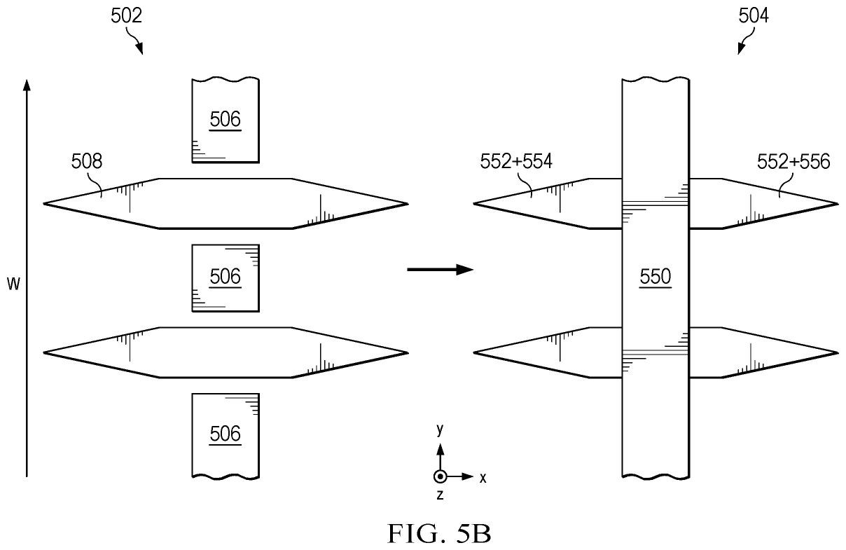

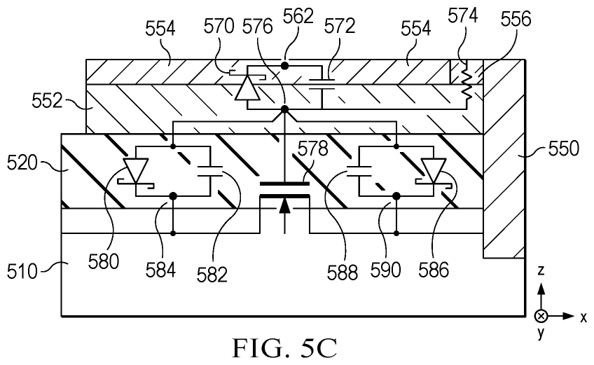

FIG. 5A is a cross-sectional view of an example of an HEMT 500 including a hybrid drain contact structure according to certain examples. In the illustrated example, HEMT 500 includes a substrate 505, a channel layer 510 (e.g., including a GaN layer) grown on substrate 505, a barrier layer 520 (e.g., including an AlGaN layer) over channel layer 510, and drain, source, and gate structures. The drain, source, and gate structures are isolated by the dielectric material of a dielectric layer 560. The gate structure is between the drain structure and the source structure, and may be closer to the source structure. In some examples, HEMT 500 shown in FIG. 5A may be a half pitch of an HEMT device that includes HEMT 500 and a mirrored version of HEMT 500 that shares the drain structure with HEMT 500.

Substrate 505 may be a bulk semiconductor substrate, a semiconductor-on-insulator (SOI) substrate, or any other suitable substrate. In one example, substrate 505 may include a bulk silicon wafer, and may include one or more transition layers or buffer layers of suitable materials for accommodating the lattice mismatch between substrate 505 and channel layer 510 (e.g., to reduce or minimize lattice defect generation and/or propagation in channel layer 510). For example, the transition layers or buffer layers may have a gradient concentration of one or more elements in a surface normal direction (e.g., z direction) of substrate 505 to gradually change the lattice constant.

Channel layer 510 and barrier layer 520 may be epitaxially grown on substrate 505 to form a heterostructure that may induce a 2DEG 512 near the interface between channel layer 510 and barrier layer 520 due to the different energy band structures of channel layer 510 and barrier layer 520. 2DEG 512 may conduct current in a two-dimensional plane (e.g., an x-y plane). In some examples, channel layer 510 may be a portion of substrate 505. In the illustrated example, channel layer 510 includes a GaN layer. In some examples, the material of channel layer 510 includes an unintentionally doped material, such as a material doped by diffusion of dopants from another layer, or includes an intrinsic material. In the illustrated example, barrier layer 520 includes an AlGaN layer. Other materials may also be used for channel layer 510 and barrier layer 520. For example, channel layer 510 may include indium aluminum gallium nitride (InᵢAlⱼGa₁₋ᵢ₋ⱼN) (where 0≤i≤1, 0≤j≤1, and 0≤i+j≤1), and barrier layer 520 may include indium aluminum gallium nitride (InₖAlₗGa₁₋ₖ₋ₗN) (where 0≤k≤1, 0≤l≤1, and 0≤k+l≤1).

The gate structure of HEMT 500 includes a gate semiconductor layer 530 over an upper surface of barrier layer 520. In some examples, gate semiconductor layer 530 includes a p-doped semiconductor layer. For example, gate semiconductor layer 530 may include a GaN layer, or more generally, an InₘAlₙGa₁₋ₘ₋ₙN layer (where 0≤m<1, 0≤n<1, and 0≤m+n≤1). The p-type dopant with which gate semiconductor layer 530 is doped may include magnesium (Mg), carbon (C), zinc (Zn), and the like, or a combination thereof. In examples where gate semiconductor layer 530 includes GaN doped with a p-type dopant, gate semiconductor layer 530 may be referred to as a p-GaN layer. Further, in examples where gate semiconductor layer 530 includes GaN doped with magnesium, gate semiconductor layer 530 may be referred to as a magnesium doped gallium nitride (GaN:Mg) layer. In some examples, a concentration of the dopant that is electrically activated in gate semiconductor layer 530 may be equal to or greater than about 1×10¹⁷ cm⁻³. In some examples, the concentration may be equal to or greater than about 1×10¹⁸ cm⁻³. Other materials, dopants, and/or concentrations may be used in other examples. Gate semiconductor layer 530 may be formed by epitaxial growth and selective etching using an etch mask, or may be formed by selective area growth using a growth mask. The etch mask or growth mask may define the shape and size of gate semiconductor layer 530. The doping density and thickness of p-doped gate semiconductor layer 530 and the thickness of barrier layer 520 under gate semiconductor layer 530 may be selected such that the p-doped gate semiconductor layer 530 may deplete 2DEG 512 under gate semiconductor layer 530, such that HEMT 500 is off without a positive gate voltage and may be turned on by applying a positive voltage to the gate structure.

A gate electrical contact 532 is formed on gate semiconductor layer 530 to transmit a gate voltage to gate semiconductor layer 530. Gate electrical contact 532 may be electrically connected to a gate drive circuit though electrical interconnects such as conductive traces and/or vias (now shown). In the illustrated example, gate electrical contact 532 may laterally extend beyond gate semiconductor layer 530 to form a gate field plate 534. Gate field plate 534 may be used in high voltage and low voltage GaN power devices to, for example, reduce current collapse and dynamic on-state resistance, and increase the breakdown voltage. Gate electrical contact 532 may include one or more metal and/or metal alloy materials having high electrical conductivity. Depending on the metal work function of gate electrical contact 532 and the energy band structure of gate semiconductor layer 530, the metal-to-semiconductor contact between gate electrical contact 532 and gate semiconductor layer 530 may be, for example, an ohmic contact or a Schottky contact having a high or low barrier height. As described above, a Schottky contact between gate electrical contact 532 and gate semiconductor layer 530 may reduce gate leakage.

At the source region of HEMT 500, a source electrical contact 540 extends through barrier layer 520 and contacts a source region of channel layer 510. Source electrical contact 540 may include a metal or metal alloy and may form a low-barrier metal-to-semiconductor contact (e.g., an ohmic contact) with channel layer 510. One or more source field plates 542 and 544 may be formed in a dielectric layer 560 and may be coupled to source electrical contact 540. The source field plates may be used to reduce current collapse and dynamic on-state resistance and/or increase the breakdown voltage of HEMT 500.

At the drain region of HEMT 500, a drain electrical contact 550 extends through dielectric layer 560 and barrier layer 520 and contacts a drain region of channel layer 510. Drain electrical contact 550 may include a metal or metal alloy and may form a low-barrier metal-to-semiconductor contact (e.g., an ohmic contact) with channel layer 510. In addition to drain electrical contact 550, the drain structure of HEMT 500 also includes a p-type drain contact structure that includes a drain semiconductor layer 552 over the upper surface of barrier layer 520. Drain semiconductor layer 552 may be separate from drain electrical contact 550, or may contact drain electrical contact 550. In some examples, drain semiconductor layer 552 includes a p-doped semiconductor layer, such as a p-GaN layer. In some examples, drain semiconductor layer 552 and gate semiconductor layer 530 may be fabricated using the same processes. For example, a p-doped semiconductor layer may be epitaxially grown over barrier layer 520 and then selectively etched using an etch mask that defines the shapes and sizes of gate semiconductor layer 530 and drain semiconductor layer 552. As such, gate semiconductor layer 530 and drain semiconductor layer 552 may include the same material and have the same thickness.

In some examples, an additional epitaxial growth process may be performed to further grow gate semiconductor layer 530 such that gate semiconductor layer 530 is thicker than drain semiconductor layer 552. In some examples, barrier layer 520 under gate semiconductor layer 530 may be etched before the epitaxial growth of the p-doped semiconductor layer, such that barrier layer 520 under gate semiconductor layer 530 may be thinner than barrier layer 520 under drain semiconductor layer 552, while gate semiconductor layer 530 may be thicker than drain semiconductor layer 552. In this way, 2DEG 512 under gate semiconductor layer 530 may be completely depleted by the p-doped gate semiconductor layer 530 to turn off HEMT 500, while 2DEG 512 under drain semiconductor layer 552 may be partially depleted and thus can still conduct current.

In the illustrated example, a drain metal contact is formed on drain semiconductor layer 552. The drain metal contact may be electrically connected to drain electrical contact 550 and/or may be connected to a drain drive circuit though electrical interconnects. The drain metal contact includes a first metal portion 554 and a second metal portion 556. Second metal portion 556 is electrically connected to drain electrical contact 550 and may, in some examples, have the same material as drain electrical contact 550. First metal portion 554 is on a first semiconductor region of drain semiconductor layer 552. Second metal portion 556 is on a second semiconductor region of drain semiconductor layer 552. In some examples, first metal portion 554 may be much larger than second metal portion 556. First metal portion 554 and the first semiconductor region of drain semiconductor layer 552 form a first junction that has a higher barrier height, such as a Schottky junction. The first junction with the higher barrier height may reduce leakage current of the p-type drain contact structure during operation of HEMT 500. Second metal portion 556 and the second semiconductor region of drain semiconductor layer 552 form a second junction that has a lower barrier height, such as an ohmic contact or a low-barrier Schottky junction.

An energy barrier height of a junction between a metal and a semiconductor material can be a function of the materials of the metal and semiconductor material and any doping of the semiconductor material. For example, the energy barrier height of a metal-to-semiconductor junction can be determined by the metal work function of the metal and the energy band structure of the semiconductor material. In some examples, to achieve the different energy barrier heights, first metal portion 554 and second metal portion 556 may include different metal or metal alloy materials. In some examples, first metal portion 554 of the drain metal contact has a work function that is greater than a work function of second metal portion 556 of the drain metal contact. For example, the work function of first metal portion 554 of the drain metal contact is equal to or greater than about 4.6 electron volt (eV), whereas the work function of second metal portion 556 of the drain metal contact is less than about 4.6 eV. In some examples, the energy barrier height of the first junction is equal to or greater than about 1.7 eV, and the energy barrier height of the second junction is less than about 1.7 eV. In some examples, the first junction may be a high-barrier Schottky junction, and the second junction may be an ohmic junction (e.g., having an energy barrier height of about 0 eV) or may be a low-barrier Schottky junction. Within the drain metal contact, first metal portion 554 may form an ohmic junction with second metal portion 556, which may be contiguous with drain electrical contact 550 or may be electrically connected to drain electrical contact 550 by an electrical interconnect such as a trace or wire.

In the illustrated example, the semiconductor material and doping condition of the first semiconductor region of drain semiconductor layer 552 are the same as those of the second semiconductor region of drain semiconductor layer 552. For example, drain semiconductor layer 552 may be a magnesium doped gallium nitride (GaN:Mg) layer with magnesium (Mg) doped at an activated concentration about 2×10¹⁸ cm⁻³. First metal portion 554 may include, for example, titanium (Ti), titanium tungsten (TiW), titanium nitride (TiN), nickel (Ni), platinum (Pt), tantalum nitride (TaN), copper (Cu), tungsten (W), or an alloy thereof. Second metal portion 556 may include, for example, gold (Au), aluminum (Al), an alloy, or a combination thereof. In some examples, the alloy may include titanium tungsten aluminum (TiWAl) or titanium aluminum nitride (TiAlN), each with an increased percentage of aluminum. In some examples, first metal portion 554 and second metal portion 556 include different metal materials, where the metal materials can include any of the metal materials described above, such as titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), titanium aluminum nitride (TiAlN), or a combination thereof.

In some other examples, to achieve the different energy barrier heights, first metal portion 554 and second metal portion 556 can include the same metal or metal alloy material, or different metal materials having similar metal work functions, but the first semiconductor region and the second semiconductor region of drain semiconductor layer 552 may have different compositions, such as different p-type dopants, different doping densities, different activation levels of the dopant, or a combination thereof. Therefore, the first semiconductor region and the second semiconductor region of drain semiconductor layer 552 may have different energy band structures, and thus may form junctions with different energy barrier heights with a same metal material. The metal material can include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), titanium aluminum nitride (TiAlN), or a combination thereof. In some examples, first metal portion 554 and second metal portion 556 can be processed with different process conditions (e.g., different anneal conditions, different deposition/etch conditions, etc.) to create junctions of different barrier heights.

Dielectric layer 560 includes one or more dielectric materials that isolate and protect the gate structure, drain structure, and source structure. Dielectric layer 560 may include multiple dielectric layers of a same dielectric material or different dielectric materials deposited in one or more deposition processes. For example, dielectric layer 560 may include an oxide-based material or a nitride-based material, such as silicon oxide (e.g., a phosphosilicate glass (PSG)), aluminum oxide, silicon nitride, and the like. In some examples, dielectric layer 560 may further include one or more etch stop layers, such as silicon nitride (SiN) and the like, for controlling the etch depth of etching processes (e.g., for patterning a dielectric or metal layer).

In some examples, the electrical contacts or other metal electrical interconnects described above may each include one or more metal barrier layers and/or one or more adhesion layers (e.g., titanium nitride (TiN), tantalum nitride (TaN), and the like, or a combination thereof) between the metal material (e.g., aluminum (Al), copper (Cu), tungsten (W), the like, or a combination thereof) and dielectric layer 560. The one or more metal barrier layers may prevent the diffusion of metal atoms into dielectric layer 560. The one or more adhesion layers may be used to improve the adhesion of the metal material to the dielectric material of dielectric layer 560 to reduce or avoid defects and reliability issues such as interfacial delamination.

As described above and shown in FIG. 5A, the p-type drain contact structure including a first junction formed by a p-doped semiconductor layer and a metal contact can be used to inject holes to the barrier layer, the channel layer, and the buffer layer to neutralize the trapped electrons at the off-state and during the switching, thereby reducing the dynamic on-state resistance and current collapse. When the first junction includes a Schottky junction with a high barrier height (e.g., >1.7 eV), the leak current of the p-type drain contact structure may be low, but the hole injection efficiency of the p-type drain contact structure may also be low due to, for example, the dividing of the drain voltage by the back-to-back diodes and thus the reduction of the voltage level applied to the p-type semiconductor layer. Therefore, the normalized dynamic on-state resistance (dRon) may still be significantly higher than 1 at high drain drive voltages. Adding the second junction with a lower energy barrier height, such as an ohmic junction, to the p-type drain contact structure can provide a Kelvin connection to the p-type semiconductor layer of the p-type drain contact structure to avoid the voltage dividing caused by the first junction that has a higher barrier height, thereby increasing the voltage level at the p-type semiconductor layer and thus the hole injection efficiency of the p-type drain contact structure. Due to the improved hole injection efficiency, the size of drain semiconductor layer 552 can be reduced and can still achieve the same hole injection and current collapse mitigation results. As such, the depleted region of the channel layer under the p-type drain contact structure can be reduced. Therefore, the channel width of the HEMT may be higher, and thus the static on-state resistance can be lower and the channel length does not need to be reduced to reduce the static R_{DS}. When the channel length and thus the gate-drain spacing are longer, the breakdown voltage of the device can be higher.

FIG. 5B illustrates differences between an example of a hybrid drain contact structure including Schottky junctions and an example of a hybrid drain contact structure including two or more junctions with different barrier heights according to certain examples. The left diagram in FIG. 5B is a top view of a hybrid drain contact structure 502 that includes a plurality of ohmic drain contact structures 506 and a plurality of p-type drain contact structures 508 as described above with respect to, for example, FIG. 3B. Ohmic drain contact structures 506 may be in direct contact with the channel layer as described above with respect to drain contact structure 304. Each p-type drain contact structure 508 may include a p-GaN block and a metal layer that form a metal-to-semiconductor junction such as a Schottky junction, as described above with respect to, for example, FIGS. 3A-3E. In the illustrated example, the p-GaN block of each p-type drain contact structure 508 has a hexagonal shape and tapers in a direction towards a gate structure. In other examples, the p-GaN block can have any other suitable regular, irregular, or arbitrary shapes. As described above, hybrid drain contact structure 502 shown in FIG. 3B may be the common drain contact structure of an HEMT that includes two symmetrical half pitches sharing the common drain contact structure.

The right diagram in FIG. 5B is a top view of an example of a hybrid drain contact structure 504 that includes a plurality of drain electrical contacts 550 and a plurality of p-type drain contact structures. Hybrid drain contact structure 504 may be an example of the hybrid drain contact structure shown in FIG. 5A. As shown in FIGS. 5A and 5B, each p-type drain contact structure may include drain semiconductor layer 552, and first metal portion 554 and second metal portion 556 formed on drain semiconductor layer 552. As described above, first metal portion 554 and drain semiconductor layer 552 may form a first junction having a high barrier height (e.g., a Schottky junction), while second metal portion 556 and drain semiconductor layer 552 may form a second junction having a low barrier height, such as an ohmic contact or a low-barrier Schottky junction. In the illustrated example, drain semiconductor layer 552 has a hexagonal shape and tapers in a direction towards the gate structure. First metal portion 554 on drain semiconductor layer 552 may have a shape matching the shape of drain semiconductor layer 552, and may also taper in a direction towards the gate structure. Second metal portions 556 and drain electrical contacts 550 may interleave and may be contiguous to form a continuous ohmic contact. Second metal portions 556 and drain electrical contacts 550 may have the same length or different lengths in the x direction. In some examples, second metal portions 556 and drain electrical contacts 550 may include a same metal material. Hybrid drain contact structure 504 shown in FIG. 5B may be the common drain contact structure of an HEMT that includes two symmetrical half pitches sharing the common drain contact structure.

FIG. 5C is a cross-sectional view of an example of a hybrid drain contact structure including a Schottky contact and a low-barrier (e.g., ohmic) contact as shown in FIG. 5A, with an overlaid circuit model of the hybrid drain contact structure according to certain examples. The hybrid drain contact structure and the corresponding circuit model shown in FIG. 5C may be similar to those of the hybrid drain contact structure of FIG. 3E, but may include a low-barrier junction in addition to the higher barrier height junction (e.g., Schottky junction). As illustrated, the hybrid drain contact structure includes drain electrical contact 550 that forms an ohmic contact with channel layer 510, first metal portion 554 that forms a Schottky contact with a first region of drain semiconductor layer 552, and second metal portion 556 that forms a lower barrier height junction with a second region of drain semiconductor layer 552.

In the circuit model, a drain contact node 562 is in first metal portion 554, and a p-type drain node 576 is in drain semiconductor layer 552. One or more channel nodes, such as a first channel node 584 and a second channel node 590, are at an interface between channel layer 510 and barrier layer 520. A Schottky diode 570 and a Schottky capacitor 572 are formed by first metal portion 554 and drain semiconductor layer 552, and are electrically coupled between drain contact node 562 and p-type drain node 576. The cathode terminal of Schottky diode 570 is electrically coupled to drain contact node 562, and the anode terminal of Schottky diode 570 is electrically coupled to the p-type drain node 576. Similarly, a first terminal of Schottky capacitor 572 is electrically coupled to drain contact node 562, and a second terminal of Schottky capacitor 572 is electrically coupled to p-type drain node 576.

A first side diode 580 (e.g., a p-i-n diode) and a first side capacitor 582 are formed by drain semiconductor layer 552, barrier layer 520, and channel layer 510. First side diode 580 and first side capacitor 582 are electrically coupled between p-type drain node 576 and first channel node 584. The anode terminal of first side diode 580 is electrically coupled to p-type drain node 576, and the cathode terminal of first side diode 580 is electrically coupled to first channel node 584. A first terminal of first side capacitor 582 is electrically coupled to p-type drain node 576, and a second terminal of first side capacitor 582 is electrically coupled to first channel node 584.

In examples where drain semiconductor layer 552 is separate from drain electrical contact 550 that forms the ohmic contact with channel layer 510, a second side diode 586 (e.g., a p-i-n diode) and a second side capacitor 588 may be formed by drain semiconductor layer 552, barrier layer 520, and channel layer 510. Second side diode 586 and second side capacitor 588 may be electrically coupled between p-type drain node 576 and second channel node 590. The anode terminal of second side diode 586 may be electrically coupled to p-type drain node 576, and the cathode terminal of second side diode 586 may be electrically coupled to second channel node 590. A first terminal of second side capacitor 588 may be electrically coupled to p-type drain node 576, and a second terminal of second side capacitor 588 may be electrically coupled to second channel node 590.

The circuit model of the hybrid drain contact structure may also include a field effect transistor (FET) 578 having a gate terminal electrically coupled to p-type drain node 576. The source terminal of FET 578 may be electrically coupled to first channel node 584, and the drain terminal of FET 578 may be electrically coupled to second channel node 590.

As illustrated by the circuit model, the hybrid drain contact structure with a Schottky junction between first metal portion 554 and drain semiconductor layer 552 includes a back-to-back diode configuration at p-type drain node 576, where the anode terminals of Schottky diode 570 and first side diode 580 (and second side diode 586) are electrically coupled to a same node (e.g., p-type drain node 576). Such a back-to-back diode configuration may otherwise result in a voltage divider and a floating, quasi-neutral node (e.g., p-type drain node 576) in drain semiconductor layer 552 under some circumstances. For example, the floating, quasi-neutral node in drain semiconductor layer 552 may be in a voltage divider formed by Schottky diode 570 and first side diode 580 (and/or second side diode 586). The voltage divider may divide the voltage level applied to first metal portion 554, such that the effective voltage level applied to drain semiconductor layer 552 is lower than the voltage level applied to first metal portion 554, and thus the voltage applied across the first side diode 580 (and/or second side diode 586) is reduced. As a result, the drive strength and the hole injection efficiency of the hybrid drain contact structure may be low.

As shown in FIG. 5C, the circuit model of the hybrid drain contact structure described in FIG. 5A includes an ohmic resistor 574 electrically coupled between second metal portion 556 and drain semiconductor layer 552 to model the ohmic junction between second metal portion 556 and drain semiconductor layer 552. Ohmic resistor 574 may provide a Kelvin connection to p-type drain node 576 (e.g., drain semiconductor layer 552), to reduce the voltage drop (e.g., to about 0 V) between second metal portion 556 and p-type drain node 576, and remove the floating, quasi-neutral node. Reducing the voltage drop may effectively increase the voltage level at drain semiconductor layer 552, thereby improving the hole injection efficiency of the p-type drain contact structure for mitigating current collapse and reducing dynamic on-state resistance. For example, as described above, when a positive voltage level is applied to drain electrical contact 550 and the source is at a low voltage level, the voltage level in the channel layer may gradually decrease from the drain region to the gate and source regions. When the voltage level applied to drain electrical contact 550 is sufficiently high, a voltage difference between the voltage level applied to drain electrical contact 550 (and thus the voltage level at drain semiconductor layer 552 due to the very small voltage drop on ohmic resistor 574) and the voltage level at the region of the channel layer below the p-type drain contact structure, which is the effective voltage level applied across first side diode 580 (or second side diode 586), may be sufficiently high to turn on first side diode 580 (and second side diode 586) to inject holes to barrier layer 520 and channel layer 510.

Due to the improved hole injection efficiency of the p-type drain contact structure, the p-type drain contact structure can be smaller to reduce the depleted region of the channel layer under the p-type drain contact structure, thereby reducing the static on-state resistance. As such, the channel length does not need to be reduced to reduce the static on-state resistance, and thus the breakdown voltage of the HEMT can be high. The smaller p-type drain contact structures may also simplify the layout. In addition, the voltage drop can be the same under DC conditions and in switching events. Therefore, the dynamic on-state resistance may be closer to the static on-state resistance, as shown by a curve 430 in FIG. 4. In addition, Schottky capacitor 572 may be bypassed by ohmic resistor 574, and thus the drain current may be more stable in switching events.

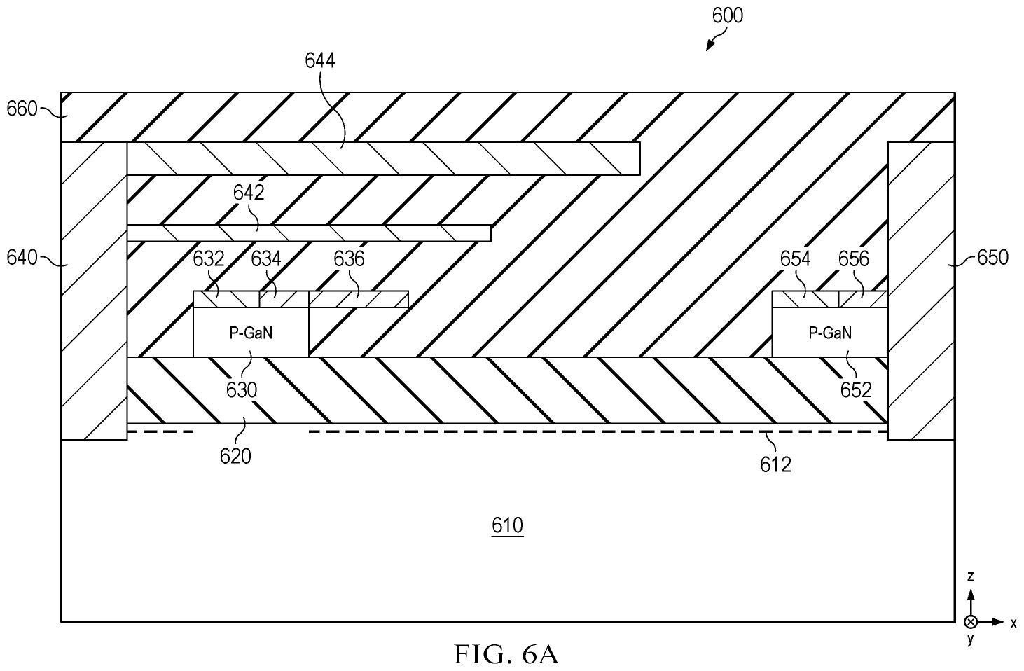

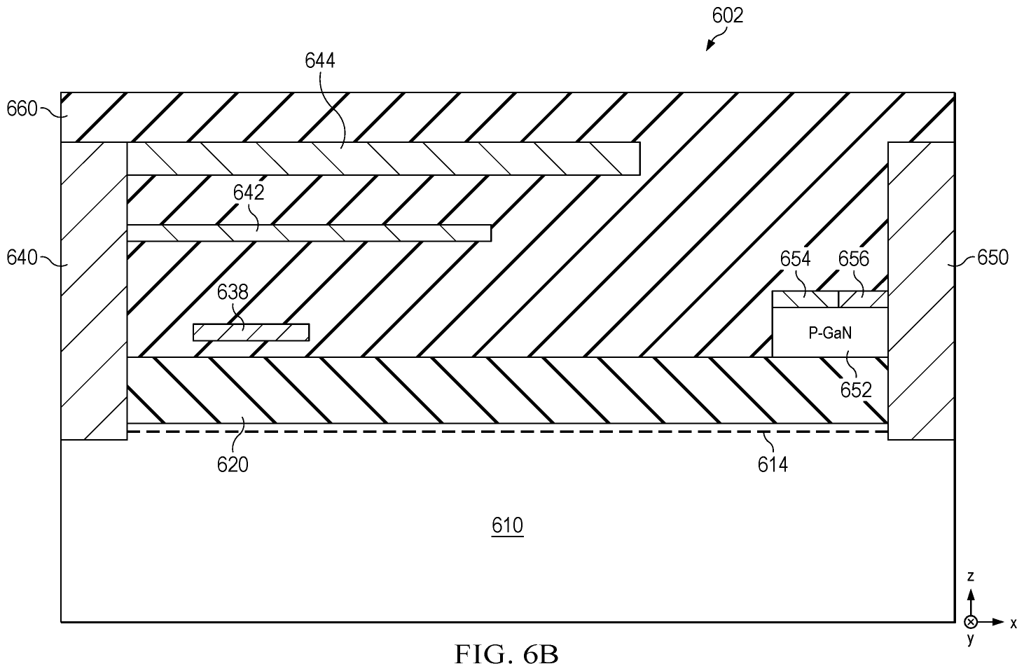

FIG. 6A illustrates an example of an enhancement mode HEMT 600 including a hybrid drain contact structure having a Schottky contact and an ohmic contact according to certain examples. HEMT 600 may be an example of HEMT 500. In the illustrated example, HEMT 600 includes a substrate (not shown), a channel layer 610 (e.g., including a GaN layer), a barrier layer 620 (e.g., including an AlGaN) layer, and drain, source, and gate structures. The drain, source, and gate structures are isolated and protected by the dielectric material of a dielectric layer 660. The gate structure is between the drain structure and the source structure, and may be closer to the source structure. In some examples, HEMT 600 shown in FIG. 6A may be a half pitch of an HEMT device that includes HEMT 600 and a mirrored version of HEMT 600 that shares the drain structure with HEMT 600.

The substrate of HEMT 600 may be similar to substrate 505 described above, and thus is not described in detail with respect to FIG. 6A. Channel layer 610 and barrier layer 620 may be epitaxially grown on or in the substrate to form a heterostructure that may induce a 2DEG 612 near the interface between channel layer 610 and barrier layer 620 due to the different energy band structures of channel layer 610 and barrier layer 620. Channel layer 610, barrier layer 620, and 2DEG 612 may be similar to channel layer 510, barrier layer 520, and 2DEG 512, respectively. In the illustrated example, channel layer 610 includes a GaN layer, and barrier layer 620 includes an AlGaN layer. Other materials may also be used for channel layer 610 and barrier layer 620 as described above with respect to FIG. 5A.

The gate structure of HEMT 600 includes a gate semiconductor layer 630 over an upper surface of barrier layer 620. Gate semiconductor layer 630 may be similar to gate semiconductor layer 530 and includes a p-doped semiconductor layer, such as a gallium nitride layer doped with magnesium (Mg), carbon (C), zinc (Zn), and the like, or a combination thereof, as described above with respect to FIG. 5A. Gate semiconductor layer 630 may be formed by epitaxial growth and selective etching using an etch mask, or may be formed by selective area growth using a growth mask. The etch mask or growth mask may define the shape and size of gate semiconductor layer 630. The doping density and thickness of p-doped gate semiconductor layer 630 and the thickness of barrier layer 620 under gate semiconductor layer 630 may be selected such that the p-doped gate semiconductor layer 630 may deplete 2DEG 612 under gate semiconductor layer 630, such that HEMT 600 is off without a positive gate voltage and may be turned on by applying a positive voltage to the gate structure.

A first gate electrical contact 632 is deposited on a first semiconductor portion of gate semiconductor layer 630 to function as a gate electrode for applying a gate voltage to gate semiconductor layer 630. First gate electrical contact 632 may be electrically connected to a gate drive circuit (now shown). First gate electrical contact 632 and the first semiconductor portion of gate semiconductor layer 630 may form a Schottky contact, which may reduce gate leakage. A second gate electrical contact 634 is deposited on a second semiconductor portion of gate semiconductor layer 630. Second gate electrical contact 634 and the second semiconductor portion of gate semiconductor layer 630 may form an ohmic contact, which may reduce the voltage drop between the first and second gate electrical contacts 632 and 634 and gate semiconductor layer 630 under DC conditions and in switching events, thereby reducing the effective gate overdrive voltage (V_{GT}). In the illustrated example, the gate structure also includes a gate field plate 636. Gate field plate 636 may be used in high voltage and low voltage GaN power devices to, for example, reduce current collapse and dynamic on-state resistance, and increase the breakdown voltage of HEMT 600. First gate electrical contact 632, second gate electrical contact 634, and gate field plate 636 may include one or more metal and/or metal alloy materials having high electrical conductivity.

At the source region of HEMT 600, a source electrical contact 640 extends through barrier layer 620 and contacts a source region of channel layer 610. Source electrical contact 640 may include a metal or metal alloy and may form a low-barrier metal-to-semiconductor contact (e.g., an ohmic contact) with channel layer 610. One or more source field plates 642 and 644 may be formed in dielectric layer 660 and may be coupled to source electrical contact 640. As described above, the field plates may be used to reduce current collapse and dynamic on-state resistance and/or increase the breakdown voltage of HEMT 600.

At the drain region of HEMT 600, a drain electrical contact 650 extends through dielectric layer 660 and barrier layer 620, and contacts a drain region of channel layer 610. Drain electrical contact 650 may include a metal or metal alloy, and may form a low-barrier metal-to-semiconductor contact (e.g., an ohmic contact) with channel layer 610. In addition to drain electrical contact 650, the drain structure of HEMT 600 also includes a p-type drain contact structure that includes a drain semiconductor layer 652 over the upper surface of barrier layer 620. Drain semiconductor layer 652 may be separate from drain electrical contact 650, or may contact drain electrical contact 650. In some examples, drain semiconductor layer 652 includes a p-doped semiconductor layer, such as a p-GaN layer. In the illustrated example, drain semiconductor layer 652 and gate semiconductor layer 630 may be fabricated using the same processes. For example, a p-doped semiconductor layer may be epitaxially grown on barrier layer 620 and then selectively etched using an etch mask that defines the shapes and sizes of gate semiconductor layer 630 and drain semiconductor layer 652. As such, gate semiconductor layer 630 and drain semiconductor layer 652 may include the same material and have the same thickness.

In the illustrated example, a drain metal contact is deposited on drain semiconductor layer 652. The drain metal contact may be electrically connected to drain electrical contact 650 and/or may be connected to a drain drive circuit. The drain metal contact includes a first metal portion 654 and a second metal portion 656. Second metal portion 656 is electrically connected to drain electrical contact 650 and may, in some examples, contact drain electrical contact 650 and/or have the same material as drain electrical contact 650. First metal portion 654 is on a first semiconductor region of drain semiconductor layer 652. Second metal portion 656 is on a second semiconductor region of drain semiconductor layer 652. In some examples, first metal portion 654 may be larger than second metal portion 656. First metal portion 654 and the first semiconductor region of drain semiconductor layer 652 may form a first junction that has a higher barrier height, such as a Schottky junction. The first junction with the higher barrier height may reduce the leakage current of the p-type drain contact structure and provide some current collapse mitigation capability. Second metal portion 656 and the second semiconductor region of drain semiconductor layer 652 may form a second junction that has a lower barrier height, such as an ohmic contact or a low-barrier Schottky junction, to improve the hole injection efficiency of the -type drain contact structure. First metal portion 654 and second metal portion 656 may include different metal or metal alloy materials that have different work functions. First metal portion 654 may include, for example, titanium (Ti), titanium tungsten (TiW), titanium nitride (TiN), nickel (Ni), platinum (Pt), tantalum nitride (TaN), copper (Cu), tungsten (W), or an alloy thereof. Second metal portion 656 may include, for example, gold (Au), aluminum (Al), or an alloy thereof. In some examples, the alloy may include titanium tungsten aluminum (TiWAl) or titanium aluminum nitride (TiAlN). In some examples, first metal portion 654 and second metal portion 656 may include any of the metal materials described above, such as titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), titanium aluminum nitride (TiAlN), or a combination thereof.

Dielectric layer 660 includes dielectric materials that isolate and protect the gate structure, drain structure, and source structure. Dielectric layer 660 may include multiple dielectric layers of a same dielectric material or different dielectric materials deposited in one or more deposition processes. For example, dielectric layer 660 may include an oxide-based material or a nitride-based material, such as silicon oxide (e.g., a phosphosilicate glass (PSG)), aluminum oxide, silicon nitride, and the like. In some examples, dielectric layer 660 may further include one or more etch stop layers, such as silicon nitride (SiN) and the like, for controlling the etch depth of etching processes (e.g., for patterning a dielectric or metal layer). In some examples, the electrical contacts or other metal electrical interconnects described above may each include one or more metal barrier layers and/or one or more adhesion layers (e.g., titanium nitride (TiN), tantalum nitride (TaN), and the like, or a combination thereof) between the metal material (e.g., aluminum (Al), copper (Cu), tungsten (W), the like, or a combination thereof) and dielectric layer 660.

As described above, the p-type drain contact structure including a first junction formed by a p-type semiconductor layer and a metal contact may be used to inject holes to the barrier layer, the channel layer, and the buffer layer to neutralize the trapped electrons at the off-state and during the switching, thereby reducing the dynamic on-state resistance and current collapse. When the first junction includes a Schottky junction with a high barrier height (e.g., >1.7 eV), the leak current of the p-type drain contact structure may be reduced, but the hole injection efficiency of the p-type drain contact structure may be low due to, for example, the dividing of the drain voltage by the back-to-back diodes and thus the reduction of the voltage level applied to the p-type semiconductor layer. Therefore, the normalized dynamic on-state resistance (dRon) may still be significantly higher than 1 at high drain drive voltages as described above with respect to FIGS. 4-5C. Adding the second junction with a lower energy barrier height, such as an ohmic junction, to the p-type drain contact structure can provide a Kelvin connection to the p-type semiconductor layer of the p-type drain contact structure to avoid the voltage dividing caused by the first junction that has a higher barrier height (e.g., the Schottky junction), thereby increasing the voltage level at the p-type semiconductor layer and thus the hole injection efficiency of the p-type drain contact structure. Due to the improved hole injection efficiency, the size of drain semiconductor layer 652 can be reduced and can still achieve the same hole injection and current collapse mitigation results. As such, the depleted region of the channel layer under the p-type drain contact structure can be reduced. Therefore, the channel width of the HEMT may be higher, and thus the static on-state resistance can be lower and the channel length does not need to be reduced to reduce the static on-state resistance. When the channel length and thus the gate-drain spacing are longer, the breakdown voltage of the device can be higher.

The hybrid drain structures described with respect to FIGS. 5A and 6A may also be used in other enhancement mode transistor devices that are not p-GaN based enhancement mode HEMTs. For example, the hybrid drain structures disclosed herein may also be used in gate-injection transistor (GIT) enhancement mode devices, etched gate-barrier based enhancement mode devices, fluorine-implanted enhancement mode devices, or enhancement mode devices implemented using other techniques.

FIG. 6B illustrates an example of a depletion mode HEMT 602 including a hybrid drain contact structure having a Schottky contact and an ohmic contact according to certain examples. As HEMT 600, HEMT 602 includes a substrate (not shown), channel layer 610 (e.g., including a GaN layer), barrier layer 620 (e.g., including an AlGaN) layer, and drain, source, and gate structures. Channel layer 610 and barrier layer 620 may be epitaxially grown on or in the substrate to form a heterostructure that may induce a 2DEG 614 near the interface between channel layer 610 and barrier layer 620 due to the different energy band structures of channel layer 610 and barrier layer 620. The drain, source, and gate structures are isolated and protected by the dielectric material of dielectric layer 660. The gate structure is between the drain structure and the source structure, and may be closer to the source structure. HEMT 602 has a gate structure different from the gate structure of HEMT 600, and is an enhancement mode HEMT because of the gate structure that does not include a p-doped semiconductor layer to deplete the 2DEG channel under the gate. The source structure and the drain structure of HEMT 602 may be similar to the source structure and the drain structure of HEMT 602, respectively. In some examples, HEMT 602 shown in FIG. 6B may be a half pitch of an HEMT device that includes HEMT 602 and a mirrored version of HEMT 602 that shares the drain structure with HEMT 602.

As illustrated, the gate structure of HEMT 602 includes a gate metal layer 638 separated from barrier layer 620 by a dielectric layer. When no negative voltage signal is applied to gate metal layer 638, 2DEG 614 is not depleted and can conduct current between the drain and source, and HEMT 602 is turned on. When a negative voltage level is applied to gate metal layer 638, electrons in the region of 2DEG 614 under gate metal layer 638 may be depleted to turn off HEMT 602.

At the source region of HEMT 602, a source electrical contact 640 extends through barrier layer 620 and contacts a source region of channel layer 610. Source electrical contact 640 may include a metal or metal alloy and may form a low-barrier metal-to-semiconductor contact (e.g., an ohmic contact) with channel layer 610. One or more source field plates 642 and 644 may be formed in dielectric layer 660 and may be coupled to source electrical contact 640. As described above, the field plates may reduce current collapse and dynamic on-state resistance and/or increase the breakdown voltage of HEMT 602.

The drain structure of HEMT 602 includes drain electrical contact 650 that extends through dielectric layer 660 and barrier layer 620 and contacts the drain region of channel layer 610. In addition to drain electrical contact 650, the drain structure of HEMT 602 also includes a p-type drain contact structure that includes drain semiconductor layer 652 (e.g., a p-doped GaN layer) over the upper surface of barrier layer 620. Drain semiconductor layer 652 may be separate from drain electrical contact 650, or may contact drain electrical contact 650. Drain semiconductor layer 652 may be fabricated by, for example, epitaxially growing a p-doped semiconductor layer over barrier layer 620 and selectively etching the p-doped semiconductor layer using an etch mask that defines the shape and size of drain semiconductor layer 652. A drain metal contact is deposited on drain semiconductor layer 652. The drain metal contact may be electrically connected to drain electrical contact 650 and/or may be connected to a drain drive circuit. The drain metal contact includes first metal portion 654 and second metal portion 656. Second metal portion 656 is electrically connected to drain electrical contact 650 and may, in some examples, have the same material as drain electrical contact 650. First metal portion 654 is on a first semiconductor region of drain semiconductor layer 652. Second metal portion 656 is on a second semiconductor region of drain semiconductor layer 652. First metal portion 654 and the first semiconductor region of drain semiconductor layer 652 forms a first junction that has a higher barrier height, such as a Schottky junction. The first junction with the higher barrier height may reduce the leakage current of the p-type drain contact structure, and may have a limited capability for current collapse mitigation. Second metal portion 656 and the second semiconductor region of drain semiconductor layer 652 may form a second junction that has a lower barrier height, such as an ohmic contact or a low-barrier Schottky junction. First metal portion 654 and second metal portion 656 may include different metal or metal alloy materials that have different work functions as describe above.

The p-type drain contact structure including a first junction formed by a p-type semiconductor layer and a metal contact may be used to inject holes to the barrier layer, the channel layer, and/or the buffer layer to neutralize the trapped electrons at the off-state and during the switching, thereby reducing the dynamic on-state resistance and current collapse at high drain voltages. When the first junction includes a Schottky junction with a high barrier height (e.g., >1.7 eV), the hole injection efficiency of the p-type drain contact structure may be low due to, for example, the dividing of the drain voltage by the back-to-back diodes and thus the reduction of the voltage level applied to the p-type semiconductor layer as described above. Adding the second junction with a lower energy barrier height, such as an ohmic junction, to the p-type drain contact structure can provide a Kelvin connection to the p-type semiconductor layer of the p-type drain contact structure to avoid the voltage dividing caused by the first junction (e.g., the Schottky diode), thereby increasing the voltage level at the p-type semiconductor layer and thus the hole injection efficiency of the p-type drain contact structure. Due to the improved hole injection efficiency, the dynamic on-state resistance may be reduced, and the size of drain semiconductor layer 652 can be reduced and can still achieve the same hole injection and current collapse mitigation results. As such, the depleted region of the channel layer under the p-type drain contact structure can be reduced. Therefore, the channel width of the HEMT may be higher, and thus the static on-state resistance can be lower and the channel length does not need to be reduced to reduce the static on-state resistance. When the channel length and thus the gate-drain spacing are longer, the breakdown voltage of the device can be higher.

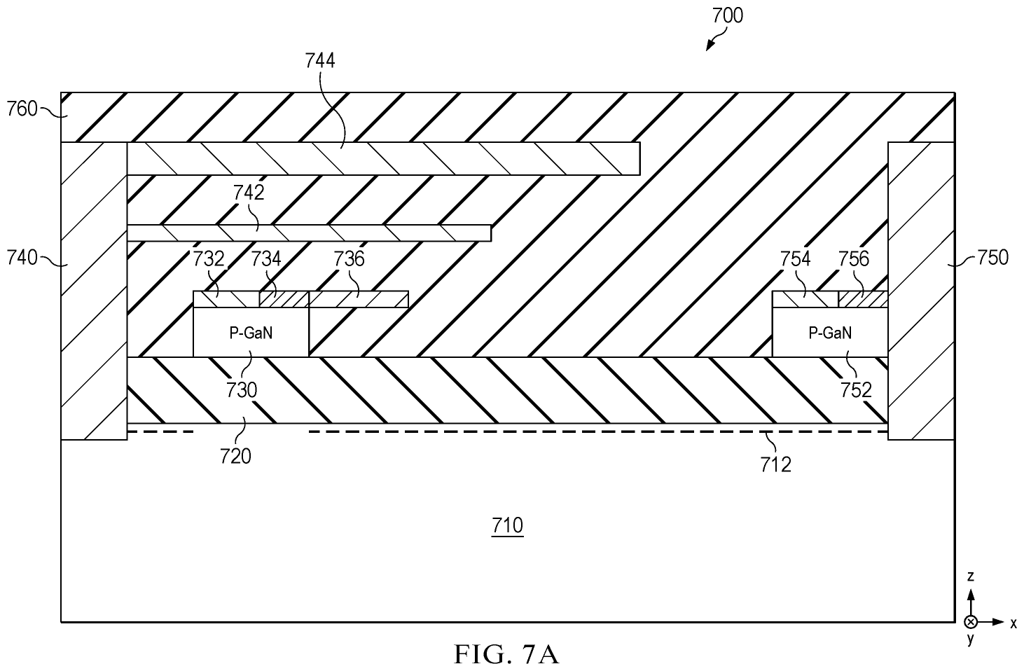

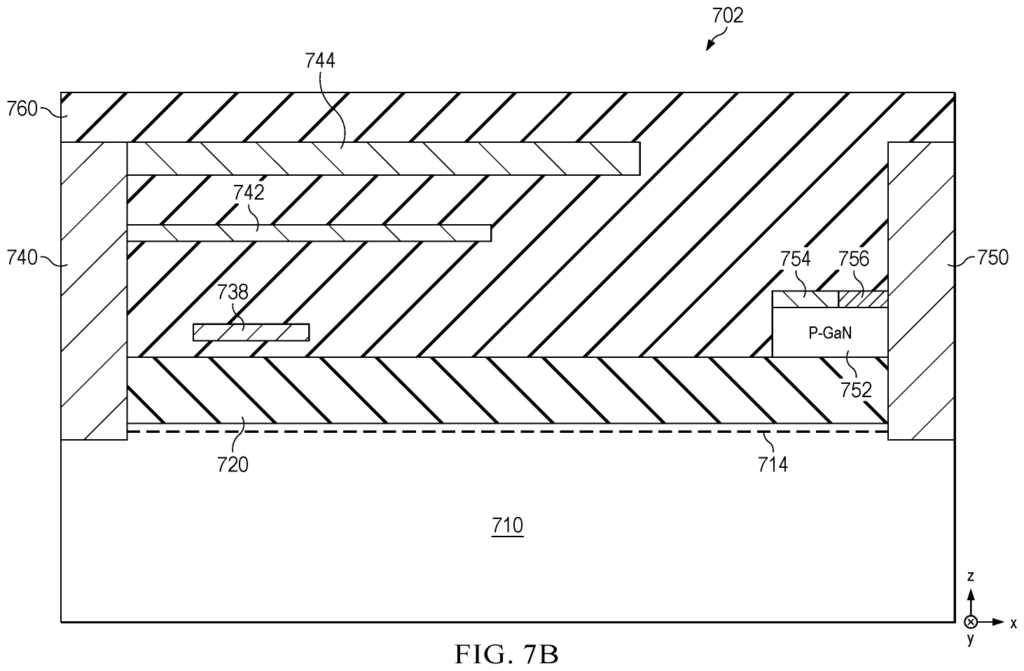

FIG. 7A illustrates an example of an enhancement mode HEMT 700 including a hybrid drain contact structure having a Schottky contact and a low-barrier Schottky (LBS) contact according to certain examples. HEMT 700 may be similar to HEMT 500 and HEMT 600. In the illustrated example, HEMT 700 includes a substrate (not shown), a channel layer 710 (e.g., including a GaN layer), a barrier layer 720 (e.g., including an AlGaN) layer, and drain, source, and gate structures. The drain, source, and gate structures are isolated and protected by the dielectric material of a dielectric layer 760. The gate structure is between the drain structure and the source structure, and may be closer to the source structure. In some examples, HEMT 700 shown in FIG. 7A may be a half pitch of an HEMT device that includes HEMT 700 and a mirrored version of HEMT 700 that shares the drain structure with HEMT 700.

The substrate of HEMT 700 may be similar to substrate 505 described above, and thus is not described in detail with respect to FIG. 7A. Channel layer 710 and barrier layer 720 may be epitaxially grown on or in the substrate to form a heterostructure that may induce a 2DEG 712 near the interface between channel layer 710 and barrier layer 720 due to the different energy band structures of channel layer 710 and barrier layer 720. Channel layer 710, barrier layer 720, and 2DEG 712 may be similar to channel layer 510, barrier layer 520, and 2DEG 512, respectively. In the illustrated example, channel layer 710 includes a gallium nitride (GaN) layer, and barrier layer 720 includes an aluminum gallium nitride (AlGaN) layer. Other materials may also be used for channel layer 710 and barrier layer 720 as described above with respect to FIG. 5A.

The gate structure of HEMT 700 includes a gate semiconductor layer 730 over an upper surface of barrier layer 720. Gate semiconductor layer 730 may be similar to gate semiconductor layer 530 and includes a p-doped semiconductor layer, such as a GaN layer doped with magnesium (Mg), carbon (C), zinc (Zn), and the like, or a combination thereof, as described above with respect to FIG. 5A. Gate semiconductor layer 730 may be formed by epitaxial growth and selective etching using an etch mask, or may be formed by selective area growth using a growth mask. The doping density and thickness of p-doped gate semiconductor layer 730 and the thickness of barrier layer 720 under gate semiconductor layer 730 may be selected such that the p-doped gate semiconductor layer 730 may deplete 2DEG 712 under gate semiconductor layer 730, such that HEMT 700 is off without a positive gate voltage and may be turned on by applying a positive voltage to the gate structure.

A first gate electrical contact 732 is deposited on a first semiconductor portion of gate semiconductor layer 730 to function as a gate electrode for applying a gate voltage to gate semiconductor layer 730. First gate electrical contact 732 and the first semiconductor portion of gate semiconductor layer 730 may form a Schottky contact, which may reduce gate leakage. A second gate electrical contact 734 is deposited on a second semiconductor portion of gate semiconductor layer 730. Second gate electrical contact 734 and the second semiconductor portion of gate semiconductor layer 730 may form a low-barrier Schottky contact, which may reduce the voltage drop between the first and second gate electrical contacts 732 and 734 and gate semiconductor layer 730 under DC conditions and in switching events, thereby reducing the effective gate overdrive voltage (V_{GT}). In the illustrated example, the gate structure also includes a gate field plate 736. Gate field plate 736 may be used to, for example, reduce current collapse and dynamic on-state resistance, and increase the breakdown voltage of HEMT 700. First gate electrical contact 732, second gate electrical contact 734, and gate field plate 736 may include one or more metal and/or metal alloy materials having high electrical conductivity.

At the source region of HEMT 700, a source electrical contact 740 extends through barrier layer 720 and contacts a source region of channel layer 710. Source electrical contact 740 may include a metal or metal alloy and may form a low-barrier metal-to-semiconductor contact (e.g., an ohmic contact) with channel layer 710. One or more source field plates 742 and 744 may be formed in dielectric layer 760 and may be coupled to source electrical contact 740. As described above, the field plates may be used to, for example, reduce current collapse and dynamic on-state resistance, and/or increase the breakdown voltage of HEMT 700.

At the drain region of HEMT 700, a drain electrical contact 750 extends through dielectric layer 760 and barrier layer 720 and contacts a drain region of channel layer 710. Drain electrical contact 750 may include a metal or metal alloy and may form a low-barrier metal-to-semiconductor contact (e.g., an ohmic contact) with channel layer 710. In addition to drain electrical contact 750, the drain structure of HEMT 700 also includes a p-type drain contact structure that includes a drain semiconductor layer 752 (e.g., a p-GaN layer) over the upper surface of barrier layer 720. Drain semiconductor layer 752 may be separate from drain electrical contact 750, or may contact drain electrical contact 750. In some examples, drain semiconductor layer 752 includes a p-doped semiconductor layer, such as a p-doped GaN layer. In the illustrated example, drain semiconductor layer 752 and gate semiconductor layer 730 may be fabricated using the same processes. For example, a p-doped semiconductor layer may be epitaxially grown on barrier layer 720 and then selectively etched using an etch mask that defines the shapes and sizes of gate semiconductor layer 730 and drain semiconductor layer 752. As such, gate semiconductor layer 730 and drain semiconductor layer 752 may include the same material and have the same thickness.

A drain metal contact is deposited on drain semiconductor layer 752. The drain metal contact may be electrically connected to drain electrical contact 750. The drain metal contact includes a first metal portion 754 and a second metal portion 756. Second metal portion 756 is electrically connected to drain electrical contact 750 and may, in some examples, have the same material as drain electrical contact 750 and contact drain electrical contact 750. First metal portion 754 is on a first semiconductor region of drain semiconductor layer 752. Second metal portion 756 is on a second semiconductor region of drain semiconductor layer 752. In some examples, first metal portion 754 may be larger than second metal portion 756. First metal portion 754 and the first semiconductor region of drain semiconductor layer 752 may form a first junction that has a higher barrier height, such as a Schottky junction. The first junction with the higher barrier height may reduce the leakage current of the p-type drain contact structure and may have a limited capability for hole injection and current collapse mitigation. Second metal portion 756 and the second semiconductor region of drain semiconductor layer 752 may form a second junction that has a lower barrier height, such as a low-barrier Schottky junction. First metal portion 754 and second metal portion 756 may include different metal or metal alloy materials that have different work functions, and may include materials described above with respect to FIG. 5A.

Dielectric layer 760 includes dielectric materials that isolate and protect the gate structure, drain structure, and source structure. Dielectric layer 760 may include multiple dielectric layers of a same dielectric material or different dielectric materials deposited in one or more deposition processes. For example, dielectric layer 760 may include an oxide-based material or a nitride-based material, such as silicon oxide (e.g., a phosphosilicate glass (PSG)), aluminum oxide, silicon nitride, and the like. In some examples, dielectric layer 760 may further include one or more etch stop layers, such as silicon nitride (SiN) and the like, for controlling the etch depth of etching processes (e.g., for patterning a dielectric or metal layer). In some examples, the electrical contacts or other metal electrical interconnects described above may each include one or more metal barrier layers and/or one or more adhesion layers (e.g., titanium nitride (TiN), tantalum nitride (TaN), and the like, or a combination thereof) between the metal material (e.g., aluminum (Al), copper (Cu), tungsten (W), the like, or a combination thereof) and dielectric layer 760.

As described above, the p-type drain contact structure including a first junction formed by a p-type semiconductor layer and a metal contact may be used to inject holes to the barrier layer, the channel layer, and the buffer layer to neutralize the trapped electrons at the off-state and during the switching, thereby reducing the dynamic on-state resistance and current collapse. Adding the second junction with a lower energy barrier height, such as a low-barrier Schottky junction, to the p-type drain contact structure can provide a Kelvin connection to the p-type semiconductor layer of the p-type drain contact structure to avoid the voltage dividing caused by the first junction that has a higher barrier height, thereby increasing the voltage level at the p-type semiconductor layer and thus the hole injection efficiency of the p-type drain contact structure.

FIG. 7B illustrates an example of a depletion mode HEMT 702 including a hybrid drain contact structure having a Schottky contact and a low-barrier Schottky contact according to certain examples. HEMT 702 may be similar to HEMT 602 or 700 described above. As HEMT 700, HEMT 702 includes a substrate (not shown), channel layer 710 (e.g., including a GaN layer), barrier layer 720 (e.g., including an AlGaN) layer, and drain, source, and gate structures. Channel layer 710 and barrier layer 720 may be epitaxially grown on or in the substrate to form a heterostructure that may induce a 2DEG 714 near the interface between channel layer 710 and barrier layer 720 due to the different energy band structures of channel layer 710 and barrier layer 720. The drain, source, and gate structures are isolated by the dielectric material of dielectric layer 760. The gate structure is between the drain structure and the source structure, and may be closer to the source structure. HEMT 702 has a gate structure different from the gate structure of HEMT 700, and is an enhancement mode HEMT because of the different gate structure that does not include a p-doped semiconductor layer to deplete the 2DEG channel under the gate. The source structure and the drain structure of HEMT 702 may be similar to the source structure and the drain structure of HEMT 700, respectively. In some examples, HEMT 702 shown in FIG. 7B may be a half pitch of an HEMT device that includes HEMT 702 and a mirrored version of HEMT 702 that shares the drain structure with HEMT 702.

As illustrated, the gate structure of HEMT 702 includes a gate metal layer 738 separated from barrier layer 720 by a dielectric layer. When no negative voltage signal is applied to gate metal layer 738, 2DEG 714 is not depleted and can conduct current between the drain and source, and HEMT 702 is turned on. When a negative voltage level is applied to gate metal layer 738, electrons in the region of 2DEG 714 under gate metal layer 738 may be depleted to turn off HEMT 702.

At the source region of HEMT 702, a source electrical contact 740 extends through barrier layer 720 and contacts a source region of channel layer 710. Source electrical contact 740 may include a metal or metal alloy and may form a low-barrier metal-to-semiconductor contact (e.g., an ohmic contact) with channel layer 710. One or more source field plates 742 and 744 may be formed in dielectric layer 760 and may be coupled to source electrical contact 740. The field plates may be used to reduce current collapse and dynamic on-state resistance and/or increase the breakdown voltage of HEMT 702.

The drain structure of HEMT 702 includes drain electrical contact 750 that extends through dielectric layer 760 and barrier layer 720 and contacts the drain region of channel layer 710. In addition to drain electrical contact 750, the drain structure of HEMT 702 also includes a p-type drain contact structure that includes drain semiconductor layer 752 (e.g., a p-doped GaN layer) over the upper surface of barrier layer 720. Drain semiconductor layer 752 may be separate from drain electrical contact 750, or may contact drain electrical contact 750. Drain semiconductor layer 752 may be fabricated by, for example, epitaxially growing a p-doped semiconductor layer over barrier layer 720 and selectively etching the p-doped semiconductor layer using an etch mask that defines the shape and size of drain semiconductor layer 752. A drain metal contact is deposited on drain semiconductor layer 752. The drain metal contact may be electrically connected to drain electrical contact 750 and a drain drive circuit. The drain metal contact includes first metal portion 754 and second metal portion 756. Second metal portion 756 is electrically connected to drain electrical contact 750 and may, in some examples, have the same material as drain electrical contact 750. First metal portion 754 is on a first semiconductor region of drain semiconductor layer 752. Second metal portion 756 is on a second semiconductor region of drain semiconductor layer 752.

First metal portion 754 and the first semiconductor region of drain semiconductor layer 752 forms a first junction that has a higher barrier height, such as a Schottky junction. The first junction with the higher barrier height may reduce the leakage current of the p-type drain contact structure and may have some hole injection and current collapse mitigation capability as described above. Second metal portion 756 and the second semiconductor region of drain semiconductor layer 752 may form a second junction that has a lower barrier height, such as an ohmic contact or a low-barrier Schottky junction. First metal portion 754 and second metal portion 756 may include different metal or metal alloy materials that have different work functions as describe above. The p-type drain contact structure including the first junction formed by a p-doped semiconductor layer and a metal contact may be used to inject holes to the barrier layer, the channel layer, and/or the buffer layer at high drain voltages to neutralize the trapped electrons at the off-state and during the switching, thereby reducing the dynamic on-state resistance and current collapse at high drain voltages. Adding the second junction with a lower energy barrier height, such as an ohmic junction, to the p-type drain contact structure can provide a Kelvin connection to the p-type semiconductor layer of the p-type drain contact structure to avoid the voltage dividing caused by the first junction that has a higher barrier height, thereby increasing the voltage level at the p-type semiconductor layer and thus the hole injection efficiency of the p-type drain contact structure.

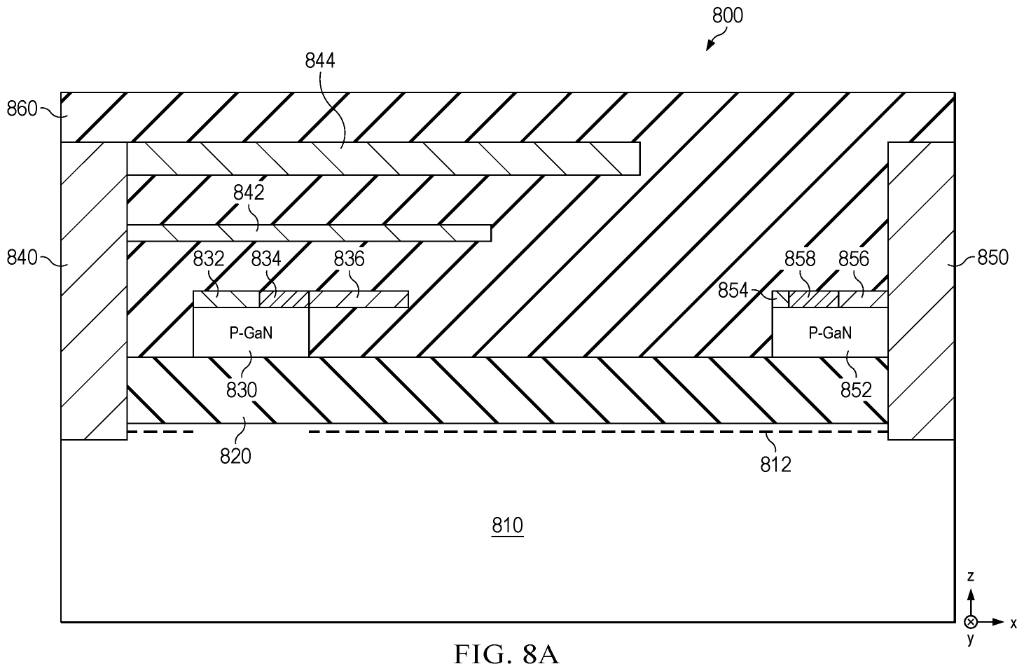

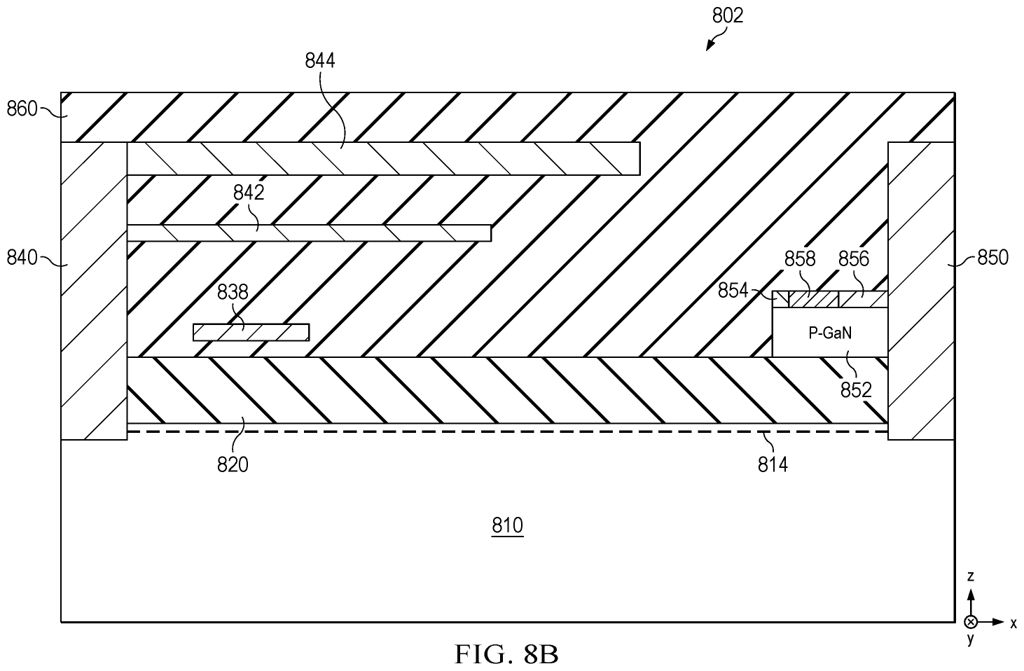

FIG. 8A illustrates an example of an enhancement mode HEMT 800 including a hybrid drain contact structure having a Schottky contact, a low-barrier Schottky contact, and an ohmic contact according to certain examples. HEMT 800 may be similar to HEMTs 500, 600, and 700 described above. HEMT 800 includes a substrate (not shown), a channel layer 810 (e.g., including a GaN layer), a barrier layer 820 (e.g., including an AlGaN layer), and drain, source, and gate structures. The drain, source, and gate structures are isolated and protected by the dielectric material of a dielectric layer 860. The gate structure is between the drain structure and the source structure, and may be closer to the source structure. In some examples, HEMT 800 shown in FIG. 8A may be a half pitch of an HEMT device that includes HEMT 800 and a mirrored version of HEMT 800 that shares the drain structure with HEMT 800.

The substrate of HEMT 800 may be similar to substrate 505 described above, and thus is not described in detail with respect to FIG. 8A. Channel layer 810 and barrier layer 820 may be epitaxially grown on or in the substrate to form a heterostructure that may induce a 2DEG 812 near the interface between channel layer 810 and barrier layer 820 due to the different energy band structures of channel layer 810 and barrier layer 820. Channel layer 810, barrier layer 820, and 2DEG 812 may be similar to channel layer 510, barrier layer 520, and 2DEG 512, respectively. In the illustrated example, channel layer 810 includes a gallium nitride (GaN) layer, and barrier layer 820 includes an aluminum gallium nitride (AlGaN) layer. Other materials may also be used for channel layer 810 and barrier layer 820 as described above with respect to FIG. 5A.

The gate structure of HEMT 800 includes a gate semiconductor layer 830 over an upper surface of barrier layer 820. Gate semiconductor layer 830 may be similar to gate semiconductor layer 530 and includes a p-doped semiconductor layer, such as a gallium nitride (GaN) layer doped with magnesium (Mg), carbon (C), zinc (Zn), and the like, or a combination thereof, as described above with respect to FIG. 5A. Gate semiconductor layer 830 may be formed by epitaxial growth and selective etching using an etch mask, or may be formed by selective area growth using a growth mask. The doping density and thickness of p-doped gate semiconductor layer 830 and the thickness of barrier layer 820 under gate semiconductor layer 830 may be selected such that the p-doped gate semiconductor layer 830 may deplete 2DEG 812 under gate semiconductor layer 830, such that HEMT 800 is off without a positive gate voltage and may be turned on by applying a positive voltage to the gate structure.

A first gate electrical contact 832 is deposited on a first semiconductor portion of gate semiconductor layer 830 to function as a gate electrode for applying a gate voltage to gate semiconductor layer 830. First gate electrical contact 832 and the first semiconductor portion of gate semiconductor layer 830 may form a Schottky contact, which may reduce gate leakage and provide some hole injection and current collapse mitigation capability at high drain voltages. A second gate electrical contact 834 is deposited on a second semiconductor portion of gate semiconductor layer 830. Second gate electrical contact 834 and the second semiconductor portion of gate semiconductor layer 830 may form a low-barrier Schottky contact, which may reduce the voltage drop between the first and second gate electrical contacts 832 and 834 and gate semiconductor layer 830 under DC conditions and in switching events, thereby reducing the effective gate overdrive voltage (V_{GT}). In the illustrated example, the gate structure also includes a gate field plate 836. Gate field plate 836 may be used to, for example, reduce current collapse and dynamic on-state resistance, and increase the breakdown voltage of HEMT 800. First gate electrical contact 832, second gate electrical contact 834, and gate field plate 836 may include one or more metal and/or metal alloy materials having high electrical conductivity.

At the source region of HEMT 800, a source electrical contact 840 extends through barrier layer 820 and contacts a source region of channel layer 810. Source electrical contact 840 may include a metal or metal alloy and may form a low-barrier metal-to-semiconductor contact (e.g., an ohmic contact) with channel layer 810. One or more source field plates 842 and 844 may be formed in dielectric layer 860 and may be coupled to source electrical contact 840. As described above, the field plates may reduce current collapse and dynamic on-state resistance and/or increase the breakdown voltage of HEMT 800.

At the drain region of HEMT 800, a drain electrical contact 850 extends through dielectric layer 860 and barrier layer 820 and contacts a drain region of channel layer 810. Drain electrical contact 850 may include a metal or metal alloy and may form a low-barrier metal-to-semiconductor contact (e.g., an ohmic contact) with channel layer 810. In addition to drain electrical contact 850, the drain structure of HEMT 800 also includes a p-type drain contact structure that includes a drain semiconductor layer 852 (e.g., a p-doped GaN layer) over the upper surface of barrier layer 820. Drain semiconductor layer 852 may be separate from drain electrical contact 850, or may contact drain electrical contact 850. In the illustrated example, drain semiconductor layer 852 and gate semiconductor layer 830 may be fabricated using the same processes as described with respect to, for example, FIGS. 5A, 6A, and 7A.

A drain metal contact is deposited on drain semiconductor layer 852. The drain metal contact may be electrically connected to drain electrical contact 850. The drain metal contact includes a first metal portion 854, a second metal portion 856, and a third metal portion 858. Second metal portion 856 is electrically connected to drain electrical contact 850 and may, in some examples, have the same material as drain electrical contact 850 and contact drain electrical contact 850. First metal portion 854 is on a first semiconductor region of drain semiconductor layer 852. Second metal portion 856 is on a second semiconductor region of drain semiconductor layer 852. Third metal portion 858 is on a third semiconductor region of drain semiconductor layer 852. First metal portion 854 and the first semiconductor region of drain semiconductor layer 852 may form a first junction that has a higher barrier height, such as a Schottky junction. The first junction with the higher barrier height may reduce the leakage current of the p-type drain contact structure, and may be used to inject holes to the barrier layer, the channel layer, and the buffer layer to neutralize the trapped electrons at the off-state and during the switching, thereby reducing the dynamic on-state resistance and current collapse. Second metal portion 856 and the second semiconductor region of drain semiconductor layer 852 may form a second junction that has a lower barrier height, such as an ohmic junction. Third metal portion 858 and the third semiconductor region of drain semiconductor layer 852 may form a third junction that has a barrier height between the first junction and the second junction, such as a low-barrier Schottky junction. The second junction and the third junction can provide a low-resistance connection to the p-type semiconductor layer of the p-type drain contact structure to avoid the voltage dividing caused by the first junction, thereby increasing the voltage level at the p-GaN layer and thus the hole injection efficiency of the p-type drain contact structure. First metal portion 854, second metal portion 856, and third metal portion 858 may include different metal or metal alloy materials that have different work functions to achieve desired barrier heights, and may include materials described above with respect to FIG. 5A.

FIG. 8B illustrates an example of a depletion mode HEMT including a hybrid drain contact structure having a Schottky contact, a low-barrier Schottky contact, and an ohmic contact according to certain examples. HEMT 802 may be similar to HEMT 602 or 702 described above. As HEMT 800, HEMT 802 includes a substrate (not shown), channel layer 810 (e.g., including a GaN layer), barrier layer 820 (e.g., including an AlGaN layer), and drain, source, and gate structures. Channel layer 810 and barrier layer 820 may be epitaxially grown on or in the substrate to form a heterostructure that may induce a 2DEG 814 near the interface between channel layer 810 and barrier layer 820 due to the different energy band structures of channel layer 810 and barrier layer 820. The drain, source, and gate structures are isolated by the dielectric material of dielectric layer 860. The gate structure is between the drain structure and the source structure, and may be closer to the source structure. HEMT 802 has a gate structure different from the gate structure of HEMT 800, and is an enhancement mode HEMT because of the different gate structure that does not include a p-doped semiconductor layer to deplete the 2DEG channel under the gate. The source structure and the drain structure of HEMT 802 may be similar to the source structure and the drain structure of HEMT 800, respectively. In some examples, HEMT 802 shown in FIG. 8B may be a half pitch of an HEMT device that includes HEMT 802 and a mirrored version of HEMT 802 that shares the drain structure with HEMT 802.

As illustrated, the gate structure of HEMT 802 includes a gate metal layer 838 separated from barrier layer 820 by a dielectric layer. When no negative voltage signal is applied to gate metal layer 838, 2DEG 814 is not depleted and can conduct current between the drain and source, and HEMT 802 is turned on. When a negative voltage level is applied to gate metal layer 838, electrons in the region of 2DEG 814 under gate metal layer 838 may be depleted to turn off HEMT 802.

At the source region of HEMT 802, a source electrical contact 840 extends through barrier layer 820 and contacts a source region of channel layer 810. Source electrical contact 840 may include a metal or metal alloy and may form a low-barrier metal-to-semiconductor contact (e.g., an ohmic contact) with channel layer 810. One or more source field plates 842 and 844 may be formed in dielectric layer 860 and may be coupled to source electrical contact 840. As described above, the field plates may be used to reduce current collapse and dynamic on-state resistance and/or increase the breakdown voltage of HEMT 802.

The drain structure of HEMT 802 includes drain electrical contact 850 that extends through dielectric layer 860 and barrier layer 820 and contacts the drain region of channel layer 810. In addition to drain electrical contact 850, the drain structure of HEMT 802 also includes a p-type drain contact structure that includes drain semiconductor layer 852 (e.g., a p-doped GaN layer) over the upper surface of barrier layer 820. Drain semiconductor layer 852 may be separate from drain electrical contact 850, or may contact drain electrical contact 850. Drain semiconductor layer 852 may be fabricated by, for example, epitaxially growing a p-doped semiconductor layer over barrier layer 820 and selectively etching the p-doped semiconductor layer using an etch mask that defines the shape and size of drain semiconductor layer 852. A drain metal contact is deposited on drain semiconductor layer 852. The drain metal contact may be electrically connected to drain electrical contact 850 and/or a drain drive circuit.

The drain metal contact may be electrically connected to drain electrical contact 850. The drain metal contact includes first metal portion 854, second metal portion 856, and third metal portion 858. Second metal portion 856 is electrically connected to drain electrical contact 850 and may, in some examples, have the same material as drain electrical contact 850 and contact drain electrical contact 850. First metal portion 854 is on a first semiconductor region of drain semiconductor layer 852. Second metal portion 856 is on a second semiconductor region of drain semiconductor layer 852. Third metal portion 858 is on a third semiconductor region of drain semiconductor layer 852. First metal portion 854 and the first semiconductor region of drain semiconductor layer 852 may form a first junction that has a higher barrier height, such as a Schottky junction. The first junction with the higher barrier height may reduce the leakage current of the p-type drain contact structure, and may be used to inject holes to the barrier layer, the channel layer, and the buffer layer to neutralize the trapped electrons at the off-state and during the switching, thereby reducing the dynamic on-state resistance and current collapse. Second metal portion 856 and the second semiconductor region of drain semiconductor layer 852 may form a second junction that has a lower barrier height, such as an ohmic junction. Third metal portion 858 and the third semiconductor region of drain semiconductor layer 852 may form a third junction that has a barrier height between the first junction and the second junction, such as a low-barrier Schottky junction. The second junction and the third junction can provide a low-resistance connection to the p-GaN layer of the p-type drain contact structure to avoid the voltage dividing caused by the first junction, thereby increasing the voltage level at the p-GaN layer and thus the hole injection efficiency of the p-type drain contact structure. First metal portion 854, second metal portion 856, and third metal portion 858 may include different metal or metal alloy materials that have different work functions to achieve desired barrier heights, and may include materials described above with respect to FIG. 5A.

FIGS. 6A-8B illustrate examples of a hybrid drain contact structure that includes at least a high barrier junction and a lower barrier junction, and optionally one or more high or low barrier junctions. The arrangements of the junctions shown in FIGS. 6A-8B are for illustration purposes only. In other examples, the two or more metal-to-semiconductor junctions having different energy barrier heights may be arranged differently. In addition, the hybrid gate contact structures in enhancement mode HEMTs may also include two or more metal-to-semiconductor junctions having different energy barrier heights, where the hybrid gate contact structure and the hybrid drain contact structure may have the same or different numbers of metal-to-semiconductor junctions, the same or different metal-to-semiconductor junctions, and the same or different arrangements of the two or more metal-to-semiconductor junctions.

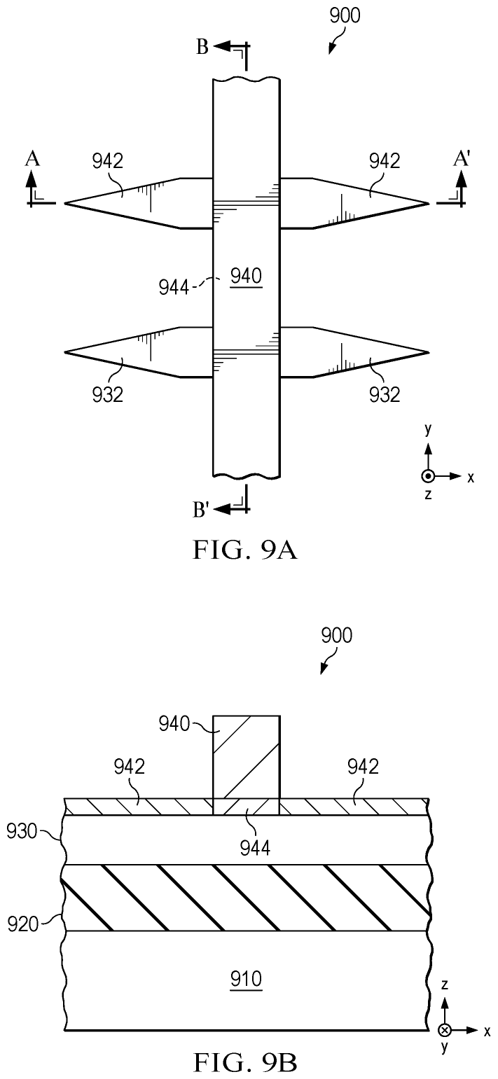

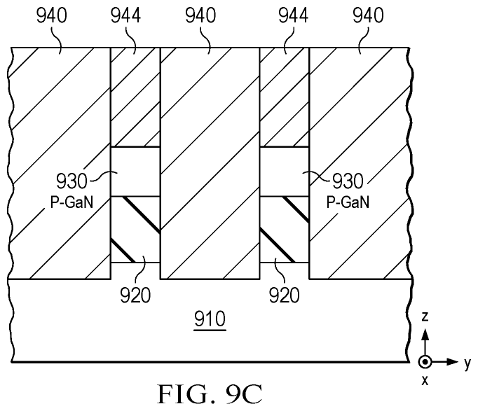

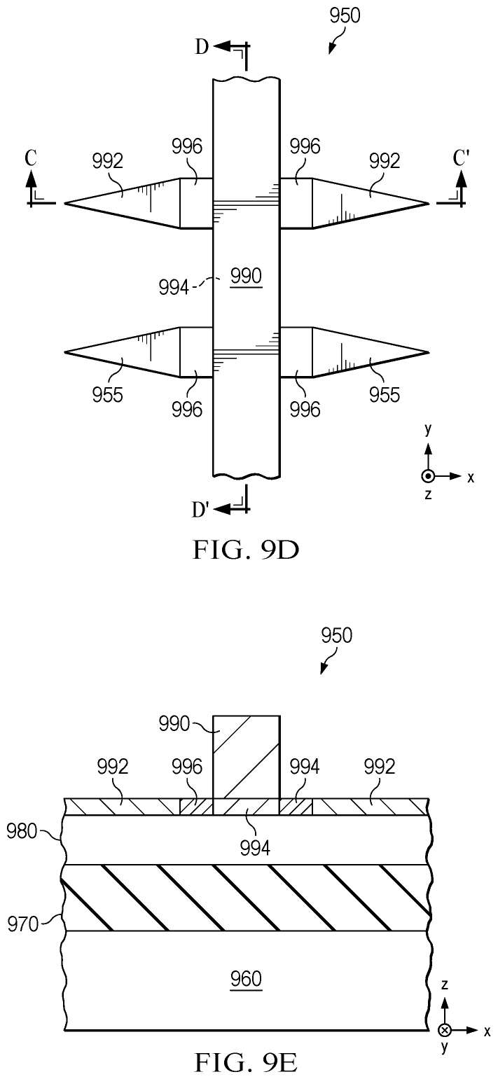

FIGS. 9A-9C illustrate an example of a drain region 900 of an HEMT including a hybrid drain contact structure according to certain examples. FIG. 9A is a top view of the hybrid drain contact structure at drain region 900, FIG. 9B is a cross-sectional view of drain region 900 along a line AA′, and FIG. 9C is a cross-sectional view of drain region 900 along a line BB′. The HEMT may be an enhancement mode HEMT or a depletion mode HEMT, and may be an example of HEMT 500, 600, or 602. In some examples, the hybrid drain contact structure shown in FIGS. 9A-9C may be a common hybrid drain contact structure shared by two half-pitches of an HEMT device.

As shown in FIGS. 9A and 9B, the hybrid drain contact structure may include a plurality of drain contact structures 932 formed on a semiconductor substrate. The semiconductor substrate may include a channel layer 910 (e.g., including GaN) and a barrier layer 920 (e.g., including AlGaN) grown on a growth substrate that may include one or more buffer layers. Each of the plurality of drain contact structures 932 includes a semiconductor block (e.g., a p-GaN block) of a semiconductor layer 930 over barrier layer 920, and a first metal portion 942 and a second metal portion 944 on semiconductor layer 930. As described above, semiconductor layer 930 may deplete the 2DEG channel underneath. In the illustrated example, each semiconductor block has a hexagonal shape and tapers in a direction towards the gate structure of the HEMT. In other examples, each semiconductor block can have any other suitable regular, irregular, or arbitrary shapes, and can taper linearly or nonlinearly. As described above, the semiconductor blocks with the tapered shape may facilitate the movement of carriers in regions of the 2DEG channel between drain contact structures 932 and reduce the channel width reduction, thereby reducing the on-state resistance of the HEMT. First metal portion 942 and second metal portion 944 may include metal or metal alloy materials described above. First metal portion 942 and a first semiconductor portion of semiconductor layer 930 form a first junction (e.g., a Schottky junction) having a first energy barrier height. Second metal portion 944 and a second semiconductor portion of semiconductor layer 930 form a second junction (e.g., an ohmic junction) having a second energy barrier height lower than the first energy barrier height. In some examples, each drain contact structure 932 may also include a drain electrical contact 940 that contacts channel layer 910 to form an ohmic contact with channel layer 910. In some examples, drain electrical contacts 940 may not be part of drain contact structures 932 and may be between drain contact structures 932. In some examples, drain electrical contacts 940 and second metal portions 944 of the plurality of drain contact structures 932 may include the same metal material and may be deposited in a same deposition process. As shown in FIGS. 9A and 9C, second metal portions 944 of the plurality of drain contact structures 932 and drain electrical contacts 940 may be contiguous (adjacent and touching) and may be parts of a continuous metal contact structure.

FIGS. 9D-9E illustrate an example of a drain region 950 of an HEMT including a hybrid drain contact structure according to certain examples. FIG. 9D is a top view of the hybrid drain contact structure at drain region 950, and FIG. 9E is a cross-sectional view of drain region 950 along a line CC′. A cross-sectional view of drain region 950 along a line DD′ may be similar to the cross-sectional view shown in FIG. 9C. The HEMT may be an enhancement mode HEMT or a depletion mode HEMT, and may be an example of HEMT 800 or 802. In some examples, the hybrid drain contact structure shown in FIGS. 9D-9E may be a common hybrid drain contact structure shared by two half-pitches of an HEMT device.

As shown in FIGS. 9D and 9E, the hybrid drain contact structure may include a plurality of drain contact structures 955 formed on a semiconductor substrate. The semiconductor substrate may include a channel layer 960 (e.g., including GaN) and a barrier layer 970 (e.g., including AlGaN) grown on a growth substrate that may include one or more buffer layers. Each of the plurality of drain contact structures 955 includes a semiconductor block (e.g., a p-GaN block) of a semiconductor layer 980 over barrier layer 970, and a first metal portion 992, a second metal portion 994, and a third metal portion 996 on the semiconductor block. As described above, semiconductor layer 980 may deplete the 2DEG channel underneath. In the illustrated example, each semiconductor block has a hexagonal shape and tapers in a direction towards the gate structure of the HEMT. The semiconductor blocks with the tapered shape may facilitate the movement of carriers in regions of the 2DEG channel between drain contact structures 955 and reduce the channel width reduction, thereby reducing the on-state resistance of the HEMT. First metal portion 992, second metal portion 994, and third metal portion 996 may include metal or metal alloy materials described above. First metal portion 992 and a first semiconductor portion of the semiconductor block form a first junction (e.g., a Schottky junction) having a first energy barrier height. Second metal portion 994 and a second semiconductor portion of the semiconductor block form a second junction (e.g., an ohmic junction) having a second energy barrier height lower than the first energy barrier height. Third metal portion 996 and a third semiconductor portion of the semiconductor block form a third junction (e.g., a low-barrier Schottky junction) having a third energy barrier height between the first energy barrier height and the second energy barrier height. In some examples, each drain contact structure 955 may also include a drain electrical contact 990 that contacts channel layer 960 to form an ohmic contact with channel layer 960. In some examples, drain electrical contacts 990 may not be part of drain contact structures 955 and may be between drain contact structures 955. In some examples, drain electrical contacts 990 and second metal portions 994 of the plurality of drain contact structures 955 may include the same metal material and may be deposited in a same deposition process. As shown in FIG. 9D (and FIG. 9C), second metal portions 994 of the plurality of drain contact structures 955 and drain electrical contacts 990 may be contiguous (adjacent and touching) and may be parts of a continuous metal contact structure.

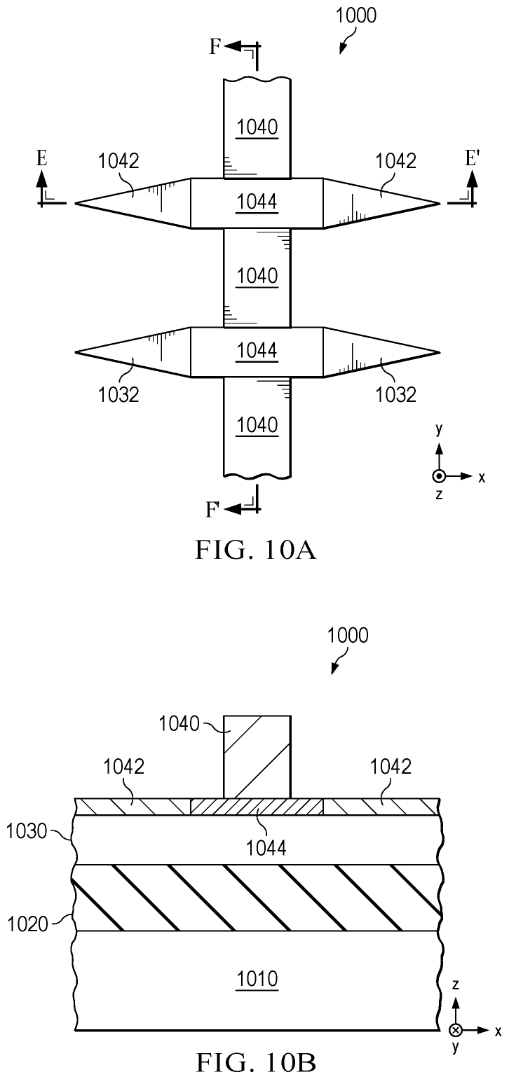

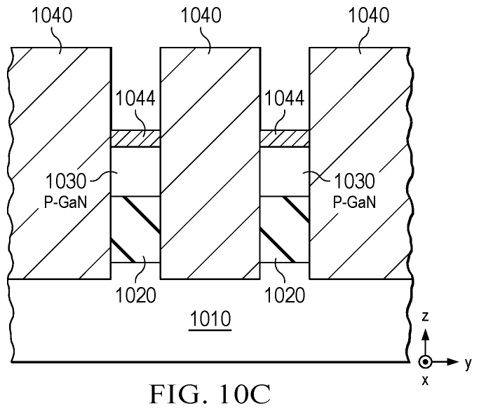

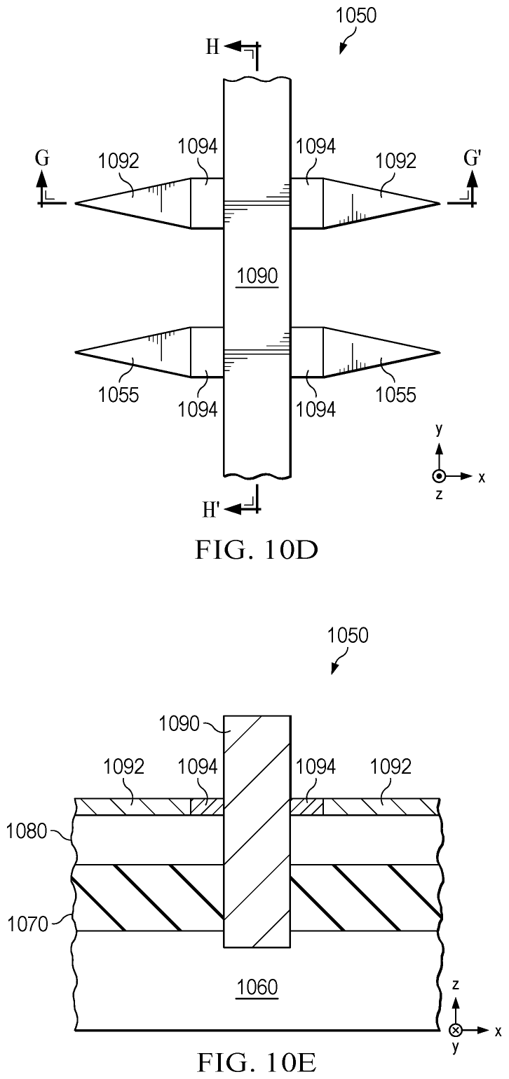

FIGS. 10A-10C illustrate an example of a drain region 1000 of an HEMT including a hybrid drain contact structure according to certain examples. FIG. 10A is a top view of the hybrid drain contact structure at drain region 1000, FIG. 10B is a cross-sectional view of drain region 1000 of the HEMT along a line EE′, and FIG. 10C is a cross-sectional view of drain region 1000 of the HEMT along a line FF′. The HEMT may be an enhancement mode HEMT or a depletion mode HEMT, and may be an example of HEMT 700 or 702. In some examples, the hybrid drain contact structure shown in FIGS. 10A-10C may be a common hybrid drain contact structure shared by two half-pitches of an HEMT device.

As shown in FIGS. 10A and 10B, the hybrid drain contact structure may include a plurality of drain contact structures 1032 formed on a semiconductor substrate. The semiconductor substrate may include a channel layer 1010 (e.g., including GaN) and a barrier layer 1020 (e.g., including AlGaN) grown on a growth substrate that may include one or more buffer layers. Each of the plurality of drain contact structures 1032 includes a semiconductor block (e.g., a p-GaN block) of a semiconductor layer 1030 over barrier layer 1020, and a first metal portion 1042 and a second metal portion 1044 on semiconductor layer 1030. As described above, semiconductor layer 1030 may deplete the 2DEG channel underneath. In the illustrated example, each semiconductor block has a hexagonal shape and tapers in a direction towards the gate structure of the HEMT. As described above, the semiconductor blocks with the tapered shape may facilitate the movement of carriers in regions of the 2DEG channel between drain contact structures 1032, thereby reducing the channel width reduction caused by the semiconductor blocks and reducing the on-state resistance of the HEMT. First metal portion 1042 and second metal portion 1044 may include metal or metal alloy materials described above. First metal portion 1042 and a first semiconductor portion of each semiconductor block form a first junction (e.g., a Schottky junction) having a first energy barrier height. Second metal portion 1044 and a second semiconductor portion of the semiconductor block form a second junction (e.g., a low-barrier Schottky junction) having a second energy barrier height lower than the first energy barrier height. In some examples, each drain contact structure 1032 may also include a drain electrical contact 1040 that contacts channel layer 1010 to form an ohmic contact with channel layer 1010. In some examples, drain electrical contacts 1040 may not be part of drain contact structures 1032 and may be between drain contact structures 1032. Drain electrical contacts 1040 and second metal portions 1044 of the plurality of drain contact structures 1032 may be contiguous (adjacent and touching) and may be parts of a continuous metal contact structure.

FIGS. 10D-10E illustrate an example of a drain region 1050 of an HEMT including a hybrid drain contact structure according to certain examples. FIG. 10D is a top view of the hybrid drain contact structure at drain region 1050, and FIG. 10E is a cross-sectional view of drain region 1050 along a line GG′. The HEMT may be an enhancement mode HEMT or a depletion mode HEMT, and may be an example of HEMT 700 or 702. In some examples, the hybrid drain contact structure shown in FIGS. 10D-10E may be a common hybrid drain contact structure shared by two half-pitches of an HEMT device.

As shown in FIGS. 10D and 10E, the hybrid drain contact structure may include a plurality of drain contact structures 1055 formed on a semiconductor substrate. The semiconductor substrate may include a channel layer 1060 (e.g., including GaN) and a barrier layer 1070 (e.g., including AlGaN) grown on a growth substrate that may include one or more buffer layers. Each of the plurality of drain contact structures 1055 includes a semiconductor block (e.g., a p-GaN block) of a semiconductor layer 1080 over barrier layer 1070, and a first metal portion 1092 and a second metal portion 1094 on the semiconductor block. As described above, semiconductor layer 1080 may deplete the 2DEG channel underneath. In the illustrated example, each semiconductor block has a hexagonal shape and tapers in a direction towards the gate structure of the HEMT. The semiconductor blocks with the tapered shape may facilitate the movement of carriers in regions of the 2DEG channel between drain contact structures 1055, thereby reducing the channel width reduction caused by the semiconductor blocks and reducing the on-state resistance of the HEMT. First metal portion 1092 and second metal portion 1094 may include metal or metal alloy materials described above. First metal portion 1092 and a first semiconductor portion of each semiconductor block form a first junction (e.g., a Schottky junction) having a first energy barrier height. Second metal portion 1094 and a second semiconductor portion of the semiconductor block form a second junction (e.g., an LBS junction) having a second energy barrier height lower than the first energy barrier height.

The hybrid drain contact structure also include a drain electrical contact 1090 that contacts channel layer 1060 to form an ohmic contact with channel layer 1060. In some examples, drain electrical contact 1090 may be a continuous metal contact structure, and may be formed by, for example, selectively etching semiconductor layer 1080 and barrier layer 1070 and depositing the metal material of drain electrical contact 1090 in the etched regions.

In some of the examples described above, the hybrid drain contact structure may include a plurality of drain contact structures formed using semiconductor blocks that are separate from each other. The layout of the hybrid drain contact structure may be complex, and the individual semiconductor blocks may need to be fabricated by epitaxial growth and etching using masks that may need to have a complex layout. In addition, in order to reduce the channel width reduction caused by the depletion of the 2DEG by the semiconductor blocks, each semiconductor block may need to be small, and the total area of the semiconductor blocks may need to be small. As result, the total area of the hybrid drain contact structure may be small, and thus the hole injection capability of the hybrid drain contact structure may not be as high as desired.

In some examples, in order to simplify the layout and increase the area of the hybrid drain contact structure, the hybrid drain contact structure of an HEMT may include a continuous drain electrical contact, and a p-type drain contact structure that includes a continuous p-type semiconductor region, a continuous first metal portion, and a second metal portion on the p-type semiconductor region. The drain electrical contact may contact the channel layer to form an ohmic contact with the channel layer. In some examples, the second metal portion and the drain electrical contact may be contiguous or may be parts of a same metal layer. In examples where the HEMT is an enhancement mode HEMT, the barrier layer under the hybrid drain contact structure may have a higher thickness than the barrier layer under the gate structure of the enhancement mode HEMT, and/or the p-GaN layer in the gate structure may have a higher thickness than the p-GaN layer in the hybrid drain contact structure, such that the 2DEG under the gate structure may be depleted, but the 2DEG under the hybrid drain contact structure may not be depleted and thus the on-state resistance can be low.

The different thicknesses of the barrier layer may be achieved by, for example, uniformly growing a first sublayer of the barrier layer followed by selective area growth of a second sublayer of the barrier layer at the drain region. In another example, a barrier layer with a uniform thickness may be grown first and then selectively etched at the gate region to reduce the thickness of the barrier layer at the gate region. After the etching, a p-GaN layer may be grown on the partially etched barrier layer. The p-GaN layer may have a flat top surface such that the p-GaN layer at the gate region may be thicker (due to the lower thickness of the underlying barrier layer) than the p-GaN layer at the drain region. As such, at the gate region, the barrier layer may be thinner and the p-GaN layer may be thicker, such that the 2DEG at the gate region may be depleted, whereas the barrier layer may be thicker and the p-GaN layer may be thinner at the drain region, such that the 2DEG at the drain region may not be depleted. In some examples, additionally or alternatively, the sublayers of the barrier layer may have different compositions (e.g., different percentages of aluminum) in order to deplete the 2DEG at the gate region but not deplete the 2DEG at the drain region.

In some examples, the barrier layer may have a uniform thickness, but the p-GaN layer may have a higher thickness at the gate region than at the drain region. The different thicknesses of the p-GaN layer may be achieved by, for example, uniformly growing a first sublayer of the p-GaN layer followed by selective area growth of a second sublayer of the p-GaN layer at the gate region. In another example, a p-GaN layer with a uniform thickness may be grown first and then selectively etched at the drain region to reduce the thickness of the p-GaN layer at the drain region.

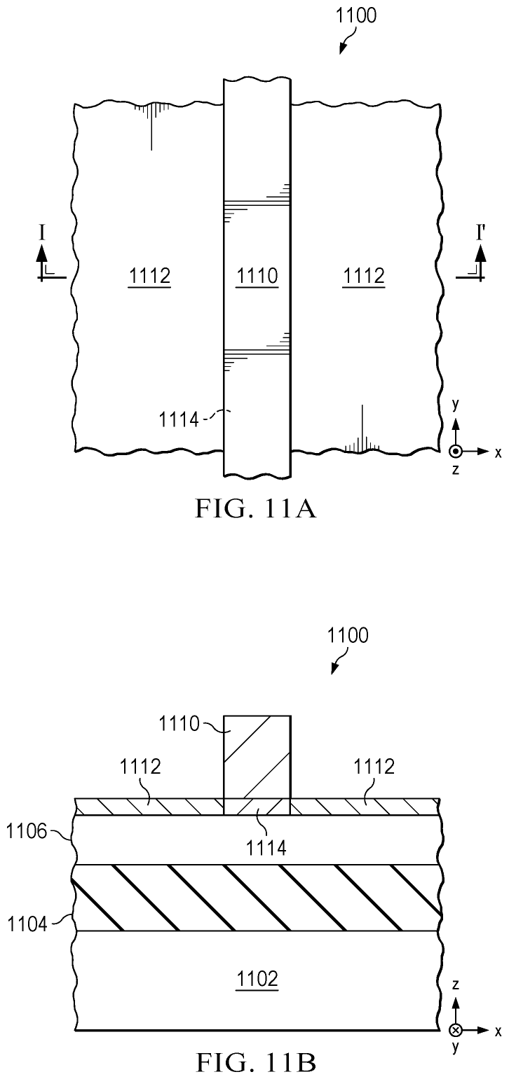

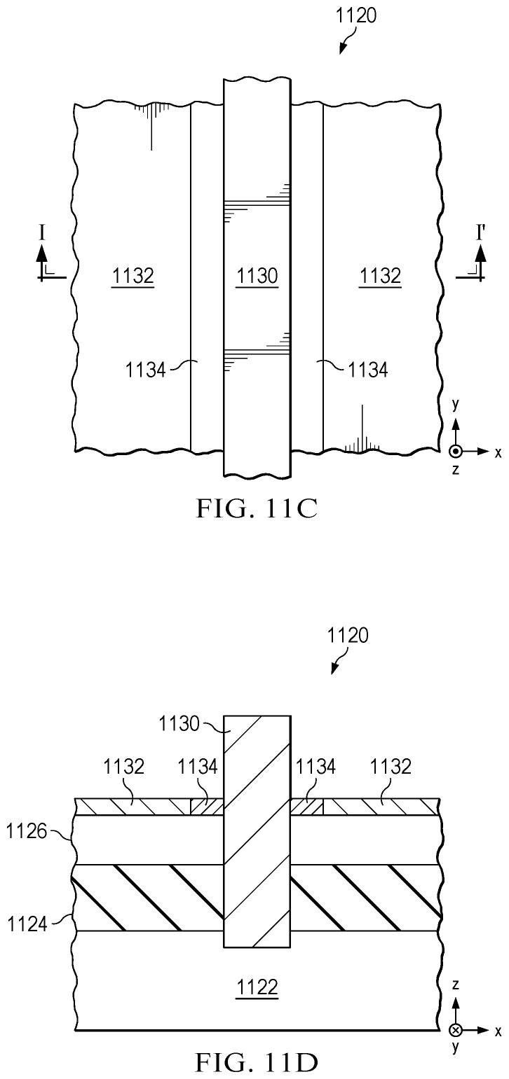

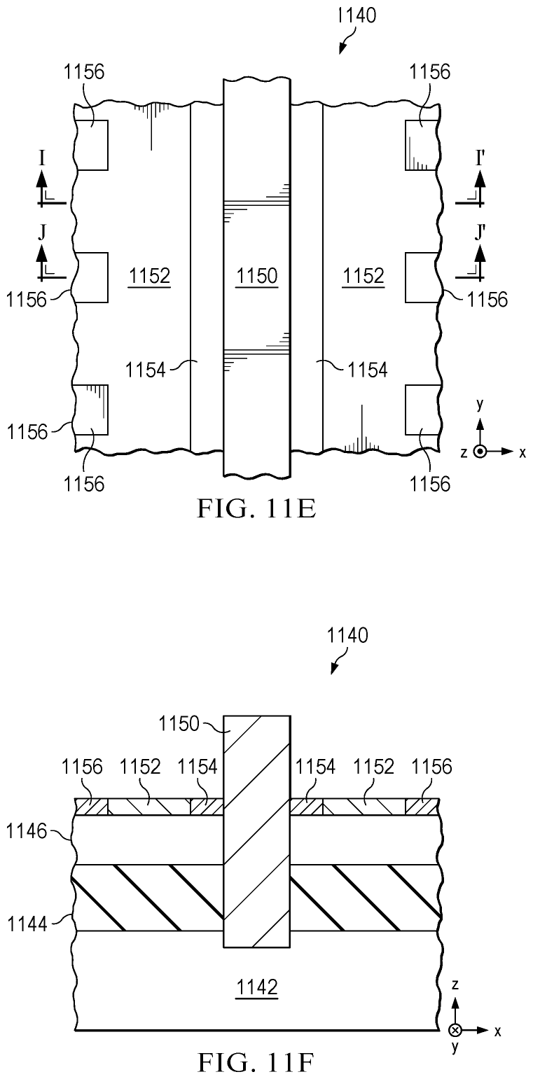

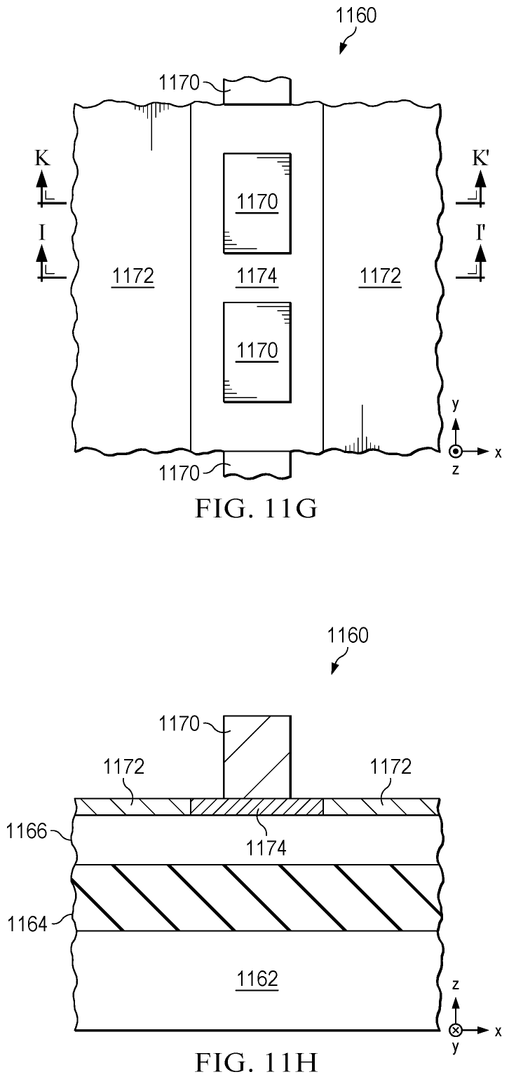

FIGS. 11A-11H illustrate examples of hybrid drain contact structures of HEMTs including a continuous semiconductor layer (e.g., a p-GaN layer) according to certain examples. FIG. 11A is a top view of an example of a hybrid drain contact structure at a drain region 1100 of an HEMT, and FIG. 11B is a cross-sectional view of an example of drain region 1100 of the HEMT along a line II′. The HEMT may be an enhancement mode HEMT or a depletion mode HEMT, and may be an example of HEMT 500, 600, or 602. In some examples, the hybrid drain contact structure shown in FIGS. 11A-11B may be a common hybrid drain contact structure shared by two half-pitches of an HEMT device.

As shown in FIGS. 11A and 11B, the hybrid drain contact structure may be formed on a semiconductor substrate. The semiconductor substrate may include a channel layer 1102 (e.g., including GaN) and a barrier layer 1104 (e.g., including AlGaN) grown on a growth substrate that may include one or more buffer layers. The hybrid drain contact structure may include a semiconductor layer 1106 (e.g., a p-GaN layer) over barrier layer 1104, and a first metal portion 1112 and a second metal portion 1114 on semiconductor layer 1106. Semiconductor layer 1106 may extend along the channel width direction (e.g., the y direction). As described above, semiconductor layer 1106 may deplete the 2DEG channel underneath. To prevent semiconductor layer 1106 from completely depleting the 2DEG channel underneath, semiconductor layer 1106 may need to be thin, and/or barrier layer 1104 may need to be thick. In this way, the 2DEG channel under semiconductor layer may be conductive when the HEMT is in the Off state. On the other hand, at the gate region, semiconductor layer 1106 may need to be thick and/or barrier layer 1104 may need to be thin, such that the 2DEG channel under semiconductor layer 1106 may be depleted to form an enhancement mode HEMT. The different thicknesses of barrier layer 1104 and/or the semiconductor layer 1106 may be achieved by multiple epitaxial growth and/or selective etching processes described above.

First metal portion 1112 and second metal portion 1114 may include metal or metal alloy materials described above. First metal portion 1112 and a first semiconductor portion of semiconductor layer 1106 form a first junction (e.g., a Schottky junction) having a first energy barrier height. First metal portion 1112 may extend along the channel width direction (e.g., y direction). Second metal portion 1114 and a second semiconductor portion of semiconductor layer 1106 form a second junction (e.g., an ohmic junction) having a second energy barrier height lower than the first energy barrier height. Second metal portion 1114 may extend along the channel width direction (e.g., the y direction). In some examples, semiconductor layer 1106 and barrier layer 1104 in some regions may be etched, and a drain electrical contact 1110 may be deposited to contact channel layer 1102 and form an ohmic contact with channel layer 1102. Drain electrical contact 1110 may extend in the channel width direction (e.g., y direction). In some examples, second metal portion 1114 is a part of drain electrical contact 1110 deposited on semiconductor layer 1106 and form the second junction with semiconductor layer 1106.

FIG. 11C is a top view of an example of a hybrid drain contact structure at a drain region 1120 of an HEMT, and FIG. 11D is a cross-sectional view of an example of drain region 1120 of the HEMT along line II′. The HEMT may be an enhancement mode HEMT or a depletion mode HEMT, and may be an example of HEMT 700 or 702. In some examples, the hybrid drain contact structure shown in FIGS. 11C-11D may be a common hybrid drain contact structure shared by two half-pitches of an HEMT device.

As shown in FIGS. 11C and 11D, the hybrid drain contact structure may be formed on a semiconductor substrate. The semiconductor substrate may include a channel layer 1122 (e.g., including GaN) and a barrier layer 1124 (e.g., including AlGaN) grown on a growth substrate that may include one or more buffer layers. The hybrid drain contact structure may include a semiconductor layer 1126 (e.g., a p-GaN layer) over barrier layer 1124, and a first metal portion 1132 and a second metal portion 1134 on semiconductor layer 1126. Semiconductor layer 1126 may extend along the channel width direction (e.g., the y direction). As described above, semiconductor layer 1126 may otherwise deplete the 2DEG channel underneath. To prevent semiconductor layer 1126 from completely depleting the 2DEG channel underneath, semiconductor layer 1126 may need to be thin, and/or barrier layer 1124 may need to be thick. In this way, the 2DEG channel under semiconductor layer 1126 may be conductive (on) when the HEMT is in the off state. On the other hand, at the gate region, semiconductor layer 1126 may need to be thick and/or barrier layer 1124 may need to be thin, such that the 2DEG channel under semiconductor layer 1126 may be depleted to form an enhancement mode HEMT. The different thicknesses of barrier layer 1124 and/or semiconductor layer 1126 at different regions may be achieved by multiple epitaxial growth and/or selective etching processes described above.

First metal portion 1132 and second metal portion 1134 may include metal or metal alloy materials described above, and may extend along the channel width direction (e.g., the y direction). First metal portion 1132 and a first semiconductor portion of semiconductor layer 1126 form a first junction (e.g., a Schottky junction) having a first energy barrier height. Second metal portion 1134 and a second semiconductor portion of semiconductor layer 1126 form a second junction (e.g., a low-barrier Schottky junction) having a second energy barrier height lower than the first energy barrier height. In the illustrated example, semiconductor layer 1126 and barrier layer 1124 in the middle region of the hybrid drain contact structure are etched, and a drain electrical contact 1130 is deposited to contact channel layer 1122 and form an ohmic contact with channel layer 1122. Drain electrical contact 1130 may extend in the channel width direction (e.g., y direction). In the illustrated example, second metal portion 1134 is between first metal portion 1132 and drain electrical contact 1130. In some examples, second metal portion 1134 may contact drain electrical contact 1130.

FIG. 11E is a top view of an example of a hybrid drain contact structure at a drain region 1140 of an HEMT, and FIG. 11F is a cross-sectional view of an example of drain region 1140 of the HEMT along line II′. A cross-sectional view of drain region 1140 of the HEMT along a line JJ′ may be similar to the cross-sectional view shown in FIG. 11D. The HEMT may be an enhancement mode HEMT or a depletion mode HEMT. In some examples, the hybrid drain contact structure shown in FIGS. 11E-11F may be a common hybrid drain contact structure shared by two half-pitches of an HEMT device.

As shown in FIGS. 11E and 11F, the hybrid drain contact structure may be formed on a semiconductor substrate. The semiconductor substrate may include a channel layer 1142 (e.g., including GaN) and a barrier layer 1144 (e.g., including AlGaN) grown on a growth substrate that may include one or more buffer layers. The hybrid drain contact structure may include a semiconductor layer 1146 (e.g., a p-GaN layer) over barrier layer 1144, and a first metal portion 1152 and a second metal portion 1154 on semiconductor layer 1146. Semiconductor layer 1146 may extend along the channel width direction (e.g., the y direction). To prevent semiconductor layer 1146 from completely depleting the 2DEG channel underneath, semiconductor layer 1146 may need to be thin, and/or barrier layer 1144 may need to be thick. In this way, the 2DEG channel under semiconductor layer 1126 may be conductive when the HEMT is in the off state. On the other hand, at the gate region, semiconductor layer 1146 may need to be thick and/or barrier layer 1144 may need to be thin, such that the 2DEG channel under semiconductor layer 1146 may be depleted to form an enhancement mode HEMT. The different thicknesses of barrier layer 1144 and/or the semiconductor layer 1146 at different regions may be achieved by multiple epitaxial growth and/or selective etching processes described above.

First metal portion 1152 and second metal portion 1154 may include metal or metal alloy materials described above and may also extend along the channel width direction (e.g., y direction). In the illustrated example, one or more regions 1156 of second metal portion 1154 are separated by first metal portion 1152. First metal portion 1152 and a first semiconductor portion of semiconductor layer 1146 form a first junction (e.g., a Schottky junction) having a first energy barrier height. Second metal portion 1154 and a second semiconductor portion of semiconductor layer 1146 form a second junction (e.g., a low-barrier Schottky junction) having a second energy barrier height lower than the first energy barrier height. In the illustrated example, semiconductor layer 1146 and barrier layer 1144 in the middle region of the hybrid drain contact structure are etched, and a drain electrical contact 1150 is deposited in the etch regions to contact channel layer 1142 and form an ohmic contact with channel layer 1142. Drain electrical contact 1150 may extend in the channel width direction (e.g., y direction). In some examples, second metal portion 1134 may contact drain electrical contact 1130.

FIG. 11G is a top view of an example of a hybrid drain contact structure at a drain region 1160 of an HEMT, and FIG. 11H is a cross-sectional view of an example of drain region 1160 of the HEMT along line II′. A cross-sectional view of drain region 1160 of the HEMT along a line KK′ may be similar to the cross-sectional view shown in FIG. 11D. The HEMT may be an enhancement mode HEMT or a depletion mode HEMT. In some examples, the hybrid drain contact structure shown in FIGS. 11G-11H may be a common hybrid drain contact structure shared by two half-pitches of an HEMT device.

As shown in FIGS. 11G and 11H, the hybrid drain contact structure may be formed on a semiconductor substrate. The semiconductor substrate may include a channel layer 1162 (e.g., including GaN) and a barrier layer 1164 (e.g., including AlGaN) grown on a growth substrate that may include one or more buffer layers. The hybrid drain contact structure may include a semiconductor layer 1166 (e.g., a p-GaN layer) over barrier layer 1164, and a first metal portion 1172 and a second metal portion 1174 on semiconductor layer 1166. Semiconductor layer 1166 may extend along the channel width direction (e.g., the y direction). To prevent semiconductor layer 1166 from completely depleting the 2DEG channel underneath, semiconductor layer 1166 may need to be thin, and/or barrier layer 1164 may need to be thick. In this way, the 2DEG channel under semiconductor layer 1166 may be conductive when the HEMT is in the off state. On the other hand, at the gate region, semiconductor layer 1166 may need to be thick and/or barrier layer 1164 may need to be thin, such that the 2DEG channel under semiconductor layer 1166 may be depleted to form an enhancement mode HEMT. The different thicknesses of barrier layer 1164 and/or the semiconductor layer 1166 at different regions may be achieved by multiple epitaxial growth and/or selective etching processes described above.

First metal portion 1172 and second metal portion 1174 may include metal or metal alloy materials described above, and may extend along the channel width direction (e.g., the y direction). First metal portion 1172 and a first semiconductor portion of semiconductor layer 1166 form a first junction (e.g., a Schottky junction) having a first energy barrier height. Second metal portion 1174 and a second semiconductor portion of semiconductor layer 1166 form a second junction (e.g., a low-barrier Schottky junction) having a second energy barrier height lower than the first energy barrier height. In the illustrated example, semiconductor layer 1166 and barrier layer 1164 in some regions of the hybrid drain contact structure are etched, and drain electrical contacts 1170 are deposited to contact channel layer 1162 and form ohmic contacts with channel layer 1162. In the illustrated example, drain electrical contacts 1170 are separated by second metal portion 1174. In some examples, second metal portion 1174 may contact drain electrical contacts 1170 and may form a continuous metal structure with drain electrical contacts 1170.

In some examples of the hybrid drain contact structure, the two or more junctions having different energy barrier heights may be formed using a same metal material and a same base semiconductor material (e.g., p-GaN) with different additional constituents (e.g., Al or In), different concentrations of an additional constituent (e.g., Al or In), different doping densities, and/or different levels of dopant activation in two or more different regions. In one example, the p-dopants (e.g., Mg) in the drain semiconductor layer (e.g., a p-GaN layer) may have different activation levels in different regions, for example, via selective hydrogen-based deactivation, such that the different regions may have different effective doping densities. In another example, the drain semiconductor layer may have different compositions in different regions, such as different concentrations of Al and/or In in a GaN layer. The drain semiconductor layer with the different doping densities, dopant activation levels, or material compositions at different regions may have different energy band structures, and thus may form junctions having different barrier heights with a same metal material or different metal materials. In some examples, a same metal material may be used in a hybrid drain contact structure to form an ohmic contact with the channel layer, form an ohmic or LBS junction with a first semiconductor region of the drain semiconductor layer, and form a Schottky junction with a second semiconductor region of the drain semiconductor layer.

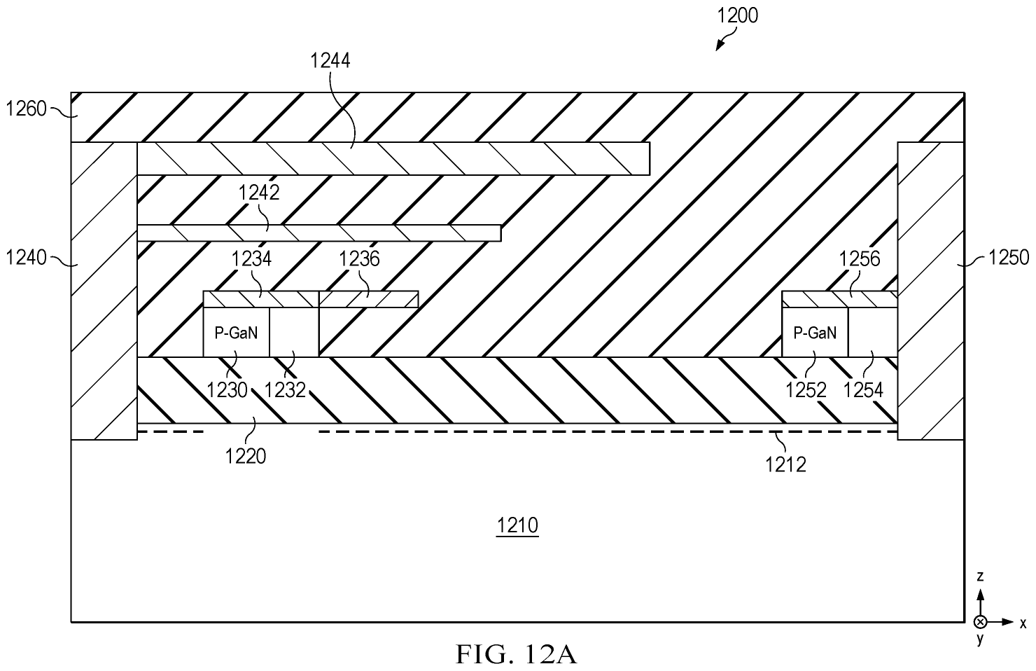

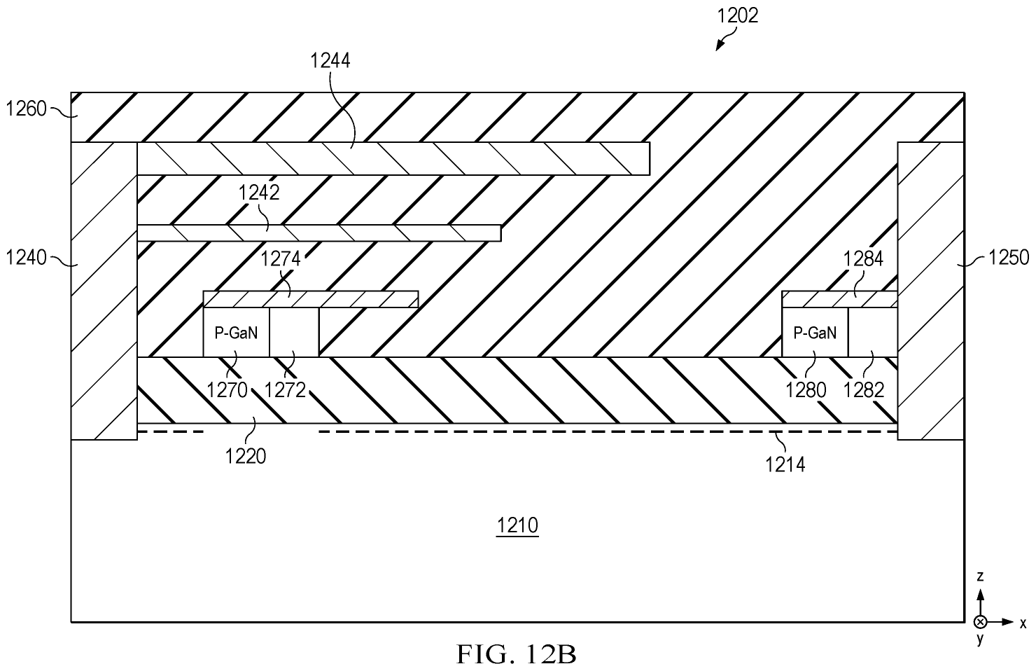

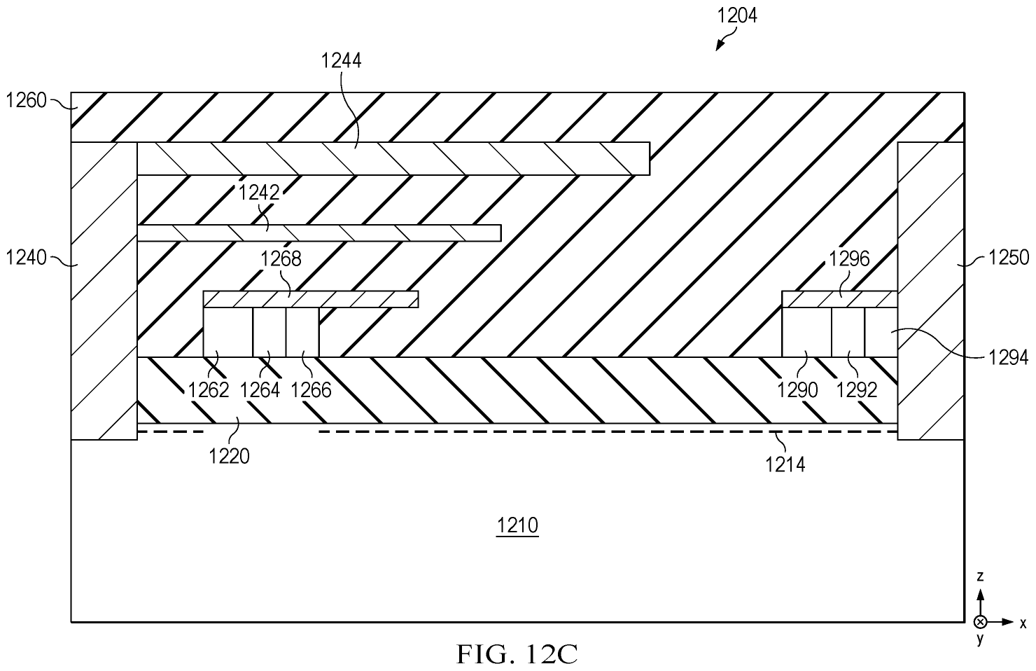

FIG. 12A illustrates an example of an enhancement mode HEMT 1200 including a hybrid drain contact structure having a Schottky metal and a semiconductor layer with different energy band structures at different regions according to certain examples. In the illustrated example, HEMT 1200 includes a substrate (not shown), a channel layer 1210 (e.g., including a GaN layer), a barrier layer 1220 (e.g., including an AlGaN layer), and drain, source, and gate structures. The drain, source, and gate structures are isolated by the dielectric material of a dielectric layer 1260. The gate structure is between the drain structure and the source structure, and may be closer to the source structure. In some examples, HEMT 1200 shown in FIG. 12A may be a half pitch of an HEMT device that includes HEMT 1200 and a mirrored version of HEMT 1200 that shares the drain structure with HEMT 1200.

The substrate of HEMT 1200 may be similar to substrate 505 described above, and thus is not described in detail with respect to FIG. 12A. Channel layer 1210 and barrier layer 1220 may be epitaxially grown on or in the substrate to form a heterostructure that may induce a 2DEG 1212 near the interface between channel layer 1210 and barrier layer 1220 due to the different energy band structures of channel layer 1210 and barrier layer 1220. Channel layer 1210, barrier layer 1220, and 2DEG 1212 may be similar to Channel layer 510, barrier layer 520, and 2DEG 512, respectively. In the illustrated example, channel layer 1210 includes a gallium nitride (GaN) layer, and barrier layer 1220 includes an aluminum gallium nitride (AlGaN) layer. Other materials may also be used for channel layer 1210 and barrier layer 1220 as described above with respect to FIG. 5A.

The gate structure of HEMT 1200 includes a gate semiconductor layer over an upper surface of barrier layer 1220. The gate semiconductor layer may be similar to gate semiconductor layer 530 and includes a p-doped semiconductor layer, such as a gallium nitride (GaN) layer doped with magnesium (Mg), carbon (C), zinc (Zn), and the like, or a combination thereof, as described above with respect to FIG. 5A. The gate semiconductor layer may include a first region 1230 and a second region 1232 that have different energy band structures. As discussed above, first region 1230 and second region 1232 of the gate semiconductor layer may include the same base material, such as GaN, but may have different additional constituents (e.g., Al or In), different doping densities, and/or different levels of dopant activation, and thus may have different energy band structures. The p-doping density and the thickness of each region of the gate semiconductor layer and the thickness of barrier layer 1220 under the gate semiconductor layer may be selected such that the gate semiconductor layer may deplete 2DEG 1212 under the gate semiconductor layer, such that HEMT 1200 is off without a positive gate voltage and may be turned on by applying a positive voltage to the gate structure.

A gate electrical contact 1234 is deposited on the gate semiconductor layer to function as a gate electrode for applying a gate voltage to the gate semiconductor layer. Gate electrical contact 1234 may include a Schottky metal. Gate electrical contact 1234 and first region 1230 of the gate semiconductor layer may form a Schottky contact, which may reduce gate leakage. Gate electrical contact 1234 and second region 1232 of the gate semiconductor layer may form an ohmic contact or a low-barrier Schottky contact, which may reduce the voltage drop between gate electrical contact 1234 and the gate semiconductor layer under DC conditions and in switching events, thereby reducing the effective gate overdrive voltage. In the illustrated example, the gate structure also includes a gate field plate 1236. Gate field plate 1236 may be used to, for example, reduce current collapse and dynamic on-state resistance, and increase the breakdown voltage of HEMT 1200.

At the source region of HEMT 1200, a source electrical contact 1240 extends through barrier layer 1220 and contacts a source region of channel layer 1210. Source electrical contact 1240 may include a metal or metal alloy and may form a low-barrier metal-to-semiconductor contact (e.g., an ohmic contact) with channel layer 1210. One or more source field plates 1242 and 1244 may be formed in dielectric layer 1260 and may be coupled to source electrical contact 1240. As described above, the field plates may be used to reduce current collapse and dynamic on-state resistance and/or increase the breakdown voltage of HEMT 1200.

At the drain region of HEMT 1200, a drain electrical contact 1250 extends through dielectric layer 1260 and barrier layer 1220 and contacts a drain region of channel layer 1210. Drain electrical contact 1250 may include a metal or metal alloy and may form a low-barrier metal-to-semiconductor contact (e.g., an ohmic contact) with channel layer 1210. In addition to drain electrical contact 1250, the drain structure of HEMT 1200 also includes a p-type drain contact structure that includes a drain semiconductor layer (e.g., a p-doped GaN layer) over the upper surface of barrier layer 1220. The drain semiconductor layer may include a first region 1252 and a second region 1254 that have different energy band structures. As discussed above, first region 1252 and second region 1254 of the drain semiconductor layer may include the same base material, such as GaN, but may have different additional constituents (e.g., Al or In), different doping densities, and/or different levels of dopant activation, and thus may have different energy band structures. In some examples, first region 1230 of the gate semiconductor layer and first region 1252 of the drain semiconductor layer include the same material and have the same energy band structure and the same thickness, and may be fabricated using the same processes. In some examples, second region 1232 of the gate semiconductor layer and second region 1254 of the drain semiconductor layer include the same material and have the same energy band structure and the same thickness, and may be fabricated using the same processes. The drain semiconductor layer may be separate from drain electrical contact 1250, or may contact drain electrical contact 1250.

In the illustrated example, a drain metal contact 1256 is deposited on the drain semiconductor layer. Drain metal contact 1256 may include the same metal material as gate electrical contact 1234. Drain metal contact 1256 may be electrically connected to drain electrical contact 1250, but may have a material having a metal work function different from the metal work function of drain electrical contact 1250. Drain metal contact 1256 and first region 1252 of the drain semiconductor layer may form a first junction that has a higher barrier height, such as a Schottky junction. The first junction with the higher barrier height may reduce the leakage current of the hybrid drain contact structure and may have some hole injection and current collapse mitigation capability at high drain voltages. Drain metal contact 1256 and second region 1254 of the drain semiconductor layer may form a second junction that has a lower barrier height, such as an ohmic contact or a low-barrier Schottky junction. The second junction with the lower barrier height can provide a Kelvin connection to the drain semiconductor layer of the hybrid drain contact structure to avoid the voltage dividing caused by the first junction that has a higher barrier height, thereby increasing the voltage level at the drain semiconductor layer and thus the hole injection efficiency of the p-type drain contact structure. Drain metal contact 1256 may include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), or an alloy thereof. In some examples, the alloy may include titanium tungsten aluminum (TiWAl) or titanium aluminum nitride (TiAlN).

FIG. 12B illustrates an example of an enhancement mode HEMT 1202 including a hybrid drain contact structure having an ohmic metal and a semiconductor layer with different energy band structures at different regions according to certain examples. HEMT 1202 shown in FIG. 12B may be similar to HEMT 1200 of FIG. 12A, except the gate structure and the drain structure. In HEMT 1202, the gate structure includes a gate semiconductor layer over an upper surface of barrier layer 1220. The gate semiconductor layer may include a p-doped semiconductor layer, such as a gallium nitride (GaN) layer doped with magnesium (Mg), carbon (C), zinc (Zn), and the like, or a combination thereof, as described above with respect to FIG. 5A. The gate semiconductor layer may include a first region 1270 and a second region 1272 that have different energy band structures. As discussed above, first region 1270 and second region 1272 of the gate semiconductor layer may include the same base material, such as GaN, but may have different additional constituents (e.g., Al or In), different doping densities, and/or different levels of dopant activation, and thus may have different energy band structures. The p-doping density and the thickness of each region of the gate semiconductor layer and the thickness of barrier layer 1220 under the gate semiconductor layer may be selected such that the gate semiconductor layer may deplete a 2DEG 1214 under the gate semiconductor layer, such that HEMT 1202 is off without a positive gate voltage and may be turned on by applying a positive voltage to the gate structure. In some examples, first region 1270 of the gate semiconductor layer of HEMT 1202 and first region 1230 of the gate semiconductor layer of HEMT 1200 may have different energy band structures, and second region 1272 of the gate semiconductor layer of HEMT 1202 and second region 1232 of the gate semiconductor layer of HEMT 1200 may have different energy band structures.

A gate electrical contact 1274 is deposited on the gate semiconductor layer to function as a gate electrode for applying a gate voltage to the gate semiconductor layer. Gate electrical contact 1274 may include an ohmic metal that may otherwise form an ohmic contact with a p-GaN material. Due to the different modifications to different regions of the gate semiconductor layer, gate electrical contact 1274 and first region 1270 of the gate semiconductor layer may form a Schottky contact, which may reduce gate leakage, whereas gate electrical contact 1274 and second region 1272 of the gate semiconductor layer may form an ohmic contact or a low-barrier Schottky contact, which may reduce the voltage drop between gate electrical contact 1274 and the gate semiconductor layer under DC conditions and in switching events, thereby reducing the effective gate overdrive voltage.

At the drain region of HEMT 1202, drain electrical contact 1250 extends through dielectric layer 1260 and barrier layer 1220 and contacts a drain region of channel layer 1210. Drain electrical contact 1250 may include a metal or metal alloy and may form a low-barrier metal-to-semiconductor contact (e.g., an ohmic contact) with channel layer 1210. In addition to drain electrical contact 1250, the drain structure of HEMT 1200 also includes a p-type drain contact structure that includes a drain semiconductor layer (e.g., a p-doped GaN layer) over the upper surface of barrier layer 1220. The drain semiconductor layer may include a first region 1280 and a second region 1282 that have different energy band structures as described above. In some examples, first region 1270 of the gate semiconductor layer and first region 1280 of the drain semiconductor layer include the same material and have the same energy band structure and the same thickness, and may be fabricated using the same processes. In some examples, second region 1232 of the gate semiconductor layer and second region 1282 of the drain semiconductor layer include the same material and have the same energy band structure and the same thickness, and may be fabricated using the same processes. The drain semiconductor layer may be separate from drain electrical contact 1250, or may contact drain electrical contact 1250.

In the illustrated example, a drain metal contact 1284 is deposited on the drain semiconductor layer. Drain metal contact 1284 may include the same metal material as gate electrical contact 1274. Drain metal contact 1284 may be electrically connected to drain electrical contact 1250, and may include the same material as drain electrical contact 1250. Drain metal contact 1284 and first region 1280 of the drain semiconductor layer may form a first junction that has a higher barrier height, such as a Schottky junction. The first junction with the higher barrier height may reduce the leakage current of the hybrid drain contact structure and may have some hole injection and current collapse mitigation capability at high drain voltages. Drain metal contact 1284 and second region 1282 of the drain semiconductor layer may form a second junction that has a lower barrier height, such as an ohmic contact or a low-barrier Schottky junction. The second junction with the lower barrier height can provide a Kelvin connection to the drain semiconductor layer of the hybrid drain contact structure to avoid the voltage dividing caused by the first junction that has a higher barrier height as described above, thereby increasing the voltage level at the drain semiconductor layer and thus the hole injection efficiency of the p-type drain contact structure. Drain metal contact 1284 may include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), or an alloy thereof. In some examples, the alloy may include titanium tungsten aluminum (TiWAl) or titanium aluminum nitride (TiAlN).

Even though FIGS. 12A and 12B describe examples of hybrid drain contact structures in enhancement mode HEMTs, the hybrid drain contact structures described with respect to FIGS. 12A and 12B can also be used in depletion mode HEMTs. In addition, the hybrid drain contact structures described with respect to FIGS. 12A and 12B can be used in HEMTs that have a plurality of p-GaN blocks (e.g., as described with respect to FIGS. 9A-10E) or one continuous p-GaN block (e.g., as described with respect to FIGS. 11A-11H) in the drain structure. Furthermore, the drain semiconductor layer can include two or more different regions having different energy band structures and thus can form two or more junctions having different barrier heights with a metal layer.

FIG. 12C illustrates another example of an enhancement mode HEMT 1204 including a hybrid drain contact structure. HEMT 1204 may be similar to HEMT 1202, but the gate semiconductor layer and the drain semiconductor layer in HEMT 1204 may each include three (or more) regions having different energy band structures. The three regions having different energy band structures may form three junctions having different barrier heights with a metal layer, such as a Schottky junction, a low-barrier Schottky junction, and an ohmic junction.

For example, the gate semiconductor layer in HEMT 1204 may include a first region 1262, a second region 1264, and a third region 1266 that have different energy band structures. As discussed above, in some examples, first region 1262, second region 1264, and third region 1266 of the gate semiconductor layer may include the same base material, such as GaN, but may have different additional constituents (e.g., Al or In), different doping densities, and/or different levels of dopant activation, and thus may have different energy band structures. First region 1262, second region 1264, and third region 1266 may form three junctions having different barrier heights with a gate electrical contact 1268, such as a Schottky junction, a low-barrier Schottky junction, and an ohmic junction.

Similarly, the drain semiconductor layer in HEMT 1204 may include a first region 1290, a second region 1292, and a third region 1294 that have different energy band structures. As discussed above, in some examples, first region 1290, second region 1292, and third region 1294 of the drain semiconductor layer may include the same base material, such as GaN, but may have different additional constituents (e.g., Al or In), different doping densities, and/or different levels of dopant activation, and thus may have different energy band structures. First region 1290, second region 1292, and third region 1294 may form three junctions having different barrier heights with a drain metal contact 1296, such as a Schottky junction, a low-barrier Schottky junction, and an ohmic junction.

Even though FIGS. 12A-12C show examples of HEMTs including the same number of regions having different energy band structures in the gate semiconductor layer and the drain semiconductor layer, the number of regions having different energy band structures in the gate semiconductor layer may be different from the number of regions having different energy band structures in the drain semiconductor layer in other examples.

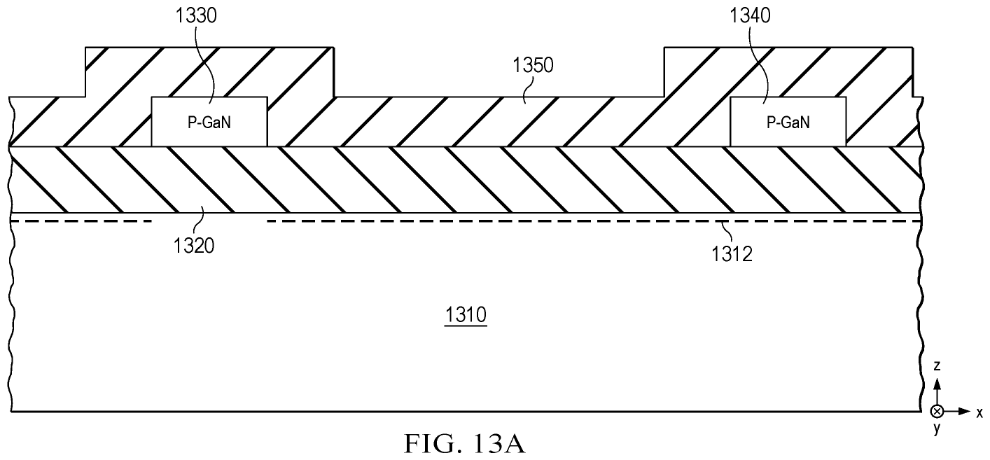

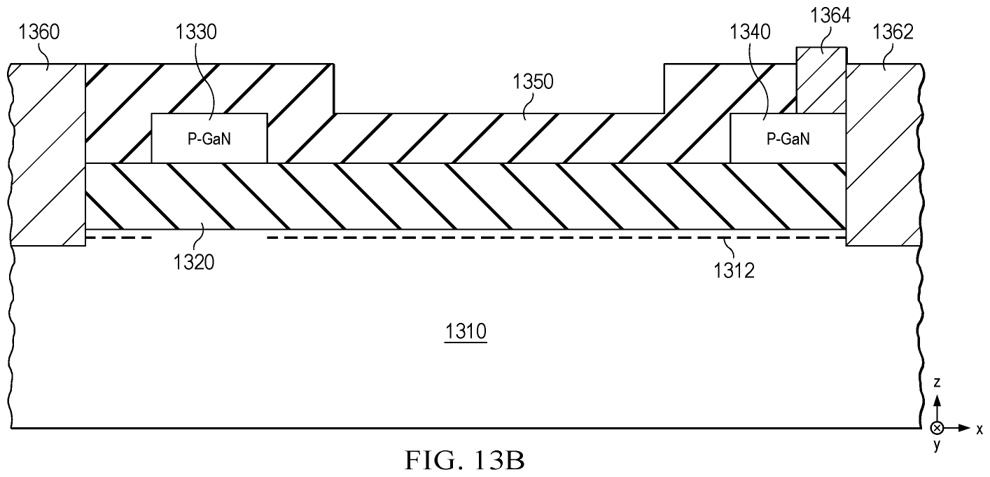

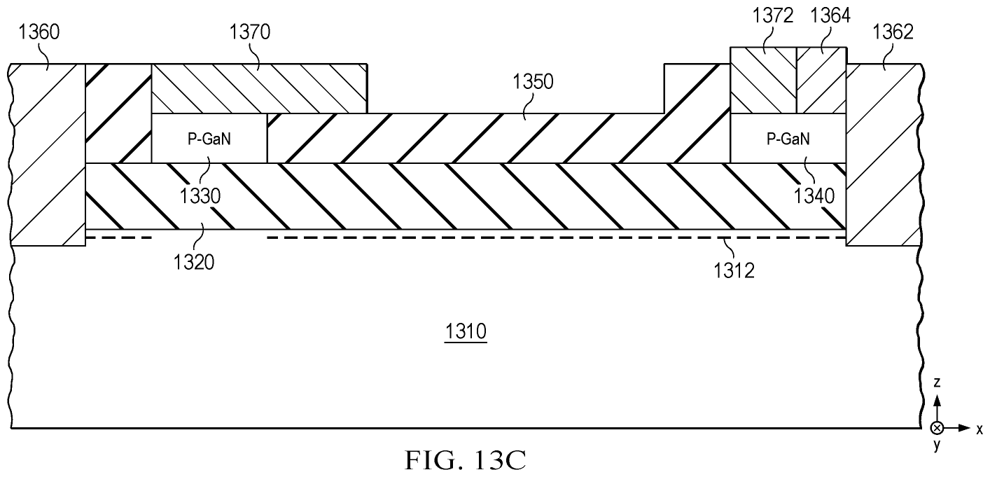

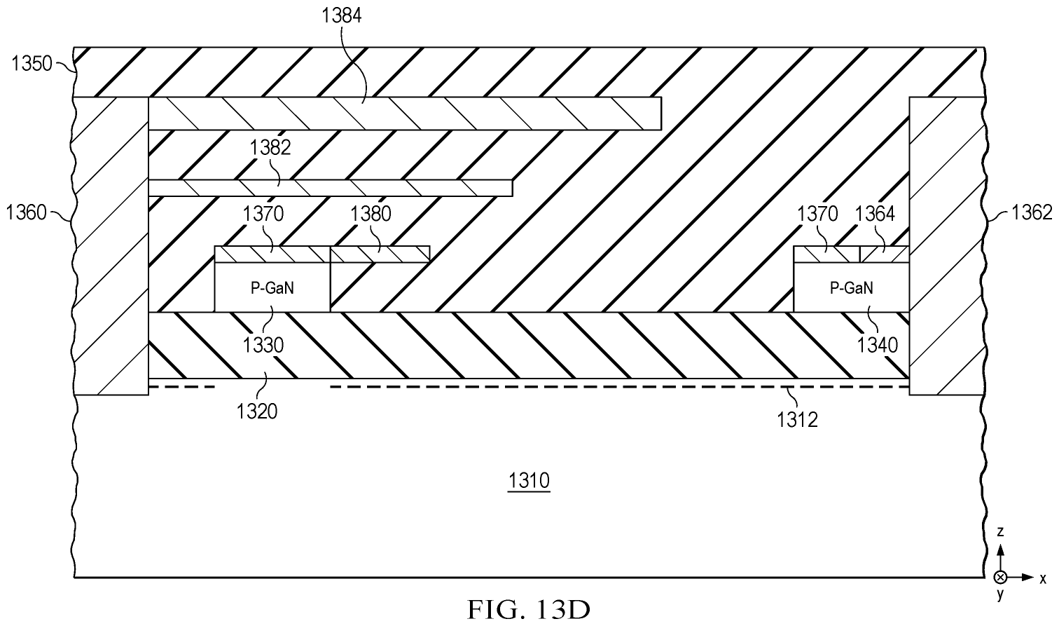

FIGS. 13A-13D illustrate an example of a process of fabricating an HEMT including a hybrid drain contact structure according to certain examples. FIG. 13A shows a semiconductor substrate that includes a channel layer 1310 (e.g., including a GaN layer) grown on a growth substrate, and a barrier layer 1320 (e.g., including an AlGaN) layer on channel layer 1310. The semiconductor substrate also include a semiconductor layer grown on barrier layer 1320 and patterned to form a gate semiconductor layer 1330 and a drain semiconductor layer 1340. A passivation layer 1350 (e.g., including an oxide or nitride based dielectric material) is deposited over barrier layer 1320, gate semiconductor layer 1330, and drain semiconductor layer 1340, to encapsulate these semiconductor layers. As described above with respect to, for example, FIG. 5A, the growth substrate may be a bulk semiconductor substrate, a semiconductor-on-insulator (SOI) substrate, or any other appropriate substrate. In one example, the growth substrate may include a bulk silicon wafer, and may include one or more transition layers or buffer layers of suitable materials for accommodating the lattice mismatch between the growth substrate and channel layer 1310 (e.g., to reduce or minimize lattice defect generation and/or propagation in channel layer 1310). For example, the transition layers or buffer layers may have a gradient concentration of one or more elements in a surface normal direction (e.g., z direction) of the semiconductor substrate.

Channel layer 1310 and barrier layer 1320 may be epitaxially grown on the growth substrate to form a heterostructure that may induce a 2DEG 1312 near the interface between channel layer 1310 and barrier layer 1320 due to the different energy band structures of channel layer 1310 and barrier layer 1320. 2DEG 1312 may conduct current in a two-dimensional plane (e.g., an x-y plane). In the illustrated example, channel layer 1310 includes a GaN layer. In some examples, the material of channel layer 1310 includes an unintentionally doped material, such as a material doped by diffusion of dopants from another layer, or includes an intrinsic material. In the illustrated example, barrier layer 1320 includes an aluminum gallium nitride (AlGaN) layer. Other materials may be used for channel layer 1310 and barrier layer 1320. For example, channel layer 1310 may include indium aluminum gallium nitride (InᵢAlⱼGa₁₋ᵢ₋ⱼN) (where 0≤i≤1, 0≤j≤1, and 0≤i+j≤1), and barrier layer 1320 may include indium aluminum gallium nitride (InₖAlₗGa₁₋ₖ₋ₗN) (where 0≤k≤1, 0≤l≤1, and 0≤k+l≤1).

Gate semiconductor layer 1330 and drain semiconductor layer 1340 are fabricated in a p-doped semiconductor layer. The p-doped semiconductor layer may have the same base material as channel layer 1310. For example, the p-doped semiconductor layer may include a gallium nitride (GaN) layer, or more generally, indium aluminum gallium nitride (InₘAlₙGa₁₋ₘ₋ₙN) (where 0≤m<1, 0≤n<1, and 0≤m+n≤1). The p-type dopant of the p-doped semiconductor layer may include magnesium (Mg), carbon (C), zinc (Zn), and the like, or a combination thereof. In some examples, a concentration of the p-type dopant that is electrically activated in the p-doped semiconductor layer may be equal to or greater than 1×10¹⁷ cm⁻³, or equal to or greater than 1×10¹⁸ cm⁻³. Other materials, dopants, and/or concentrations may be used in other examples. Gate semiconductor layer 1330 and drain semiconductor layer 1340 may be formed by epitaxial growth and selective etching using an etch mask, or may be formed by selective area growth using a growth mask. The etch mask or growth mask may define the shape and size of gate semiconductor layer 1330 and drain semiconductor layer 1340. For example, as described above, drain semiconductor layer 1340 may have a hexagonal shape and may taper towards the gate structure. The doping density and thickness of p-doped gate semiconductor layer 1330 and the thickness of barrier layer 1320 under gate semiconductor layer 1330 may be selected such that the p-doped gate semiconductor layer 1330 may deplete 2DEG 1312 under gate semiconductor layer 1330, and thus the HEMT is off without a positive gate voltage and may be turned on by applying a positive voltage to the gate structure.

As described above with respect to, for example, FIGS. 12A and 12B, in some examples, each of gate semiconductor layer 1330 and drain semiconductor layer 1340 may include a same base semiconductor material (e.g., p-GaN) with different additional constituents (e.g., Al or In), different concentrations of an additional constituent (e.g., Al or In), different doping densities, and/or different levels of dopant activation in two or more different regions. In one example, the p-dopants (e.g., Mg) in gate semiconductor layer 1330 and drain semiconductor layer 1340 may have different activation levels in different regions, for example, via selective hydrogen-based deactivation, such that the different regions may have different effective doping densities and different energy band structures. In another example, each of gate semiconductor layer 1330 and drain semiconductor layer 1340 may have different compositions in different regions, such as different concentrations of Al and/or In in a GaN layer. The drain semiconductor layer with the different doping densities, dopant activation levels, or material compositions at different regions may have different energy band structures, and thus may form two or more junctions having different barrier heights with a same metal material or different metal materials.

Passivation layer 1350 may include one or more dielectric layers of a same dielectric material or different dielectric materials deposited in one or more deposition processes. For example, passivation layer 1350 may include an oxide-based dielectric material or a nitride-based dielectric material, such as silicon oxide (e.g., a phosphosilicate glass (PSG)), aluminum oxide, silicon nitride, and the like.

FIG. 13B shows that passivation layer 1350 and barrier layer 1320 may be selectively etched to expose channel layer 1310 at the source and drain regions and a first region of drain semiconductor layer 1340, and then a first metal material may be deposited on the exposed channel layer 1310 and drain semiconductor layer 1340. The first metal material deposited on the exposed channel layer at the source region is a source electrical contact 1360, which may form an ohmic contact with channel layer 1310. The first metal material deposited on the exposed channel layer at the drain region is a drain electrical contact 1362, which may form an ohmic contact with channel layer 1310. The first metal material deposited on the first region of drain semiconductor layer 1340 is a first drain metal contact 1364, which may form an ohmic contact with the first region of drain semiconductor layer 1340. In some examples, the first metal material includes titanium (Ti), titanium tungsten (TiW), titanium nitride (TiN), nickel (Ni), platinum (Pt), tantalum nitride (TaN), copper (Cu), tungsten (W), gold (Au), aluminum (Al), or an alloy thereof.

FIG. 13C shows that passivation layer 1350 at the drain region and the gate region may be selectively etched to expose gate semiconductor layer 1330 and a second region of drain semiconductor layer 1340, and then a second metal material is deposited on the exposed gate semiconductor layer 1330 and the second region of drain semiconductor layer 1340. The second metal material deposited on the second region of drain semiconductor layer 1340 is a second drain metal contact 1372, which may form a Schottky contact with the second region of drain semiconductor layer 1340. Therefore, there may be three types of metal-to-semiconductor contact at the drain region, including an ohmic contact between drain electrical contact 1362 and channel layer 1310, an ohmic contact between first drain metal contact 1364 and the first region of drain semiconductor layer 1340, and a Schottky contact between second drain metal contact 1372 and the second region of drain semiconductor layer 1340. The second metal material deposited on the exposed gate semiconductor layer 1330 is a gate metal contact 1370, which may form a Schottky contact with gate semiconductor layer 1330. In some examples, the second metal material includes titanium (Ti), titanium tungsten (TiW), titanium nitride (TiN), nickel (Ni), platinum (Pt), tantalum nitride (TaN), copper (Cu), tungsten (W), gold (Au), aluminum (Al), or an alloy thereof.

FIG. 13D shows additional structures fabricated using backend-of-line (BEOL) processes. For example, the deposited second metal material may be planarized, where the remaining second metal material on passivation layer 1350 and adjacent to gate metal contact 1370 may be a gate field plate 1380. Additional dielectric material layers may be deposited, and metal layers may be deposited on the dielectric material layers and patterned to form, for example, a first source field plate 1382 and a second source field plate 1384. As described above, the field plates may be used to, for example, mitigate the current collapse and the increase breakdown voltage of the HEMT. Even though not shown in FIG. 13D, electrical interconnects, such as metal traces and vias, may be formed to connect the drain structure, gate structure, and source structure to drive circuits or load circuits.

FIGS. 13A-13D show an example of processes for fabricating an example of an HEMT including an example of a hybrid drain contact structure disclosed herein according to certain examples. Other hybrid drain contact structures disclosed herein may be fabricated using similar processes, including various combinations of epitaxial growth, deposition, etching, planarization, and the like.

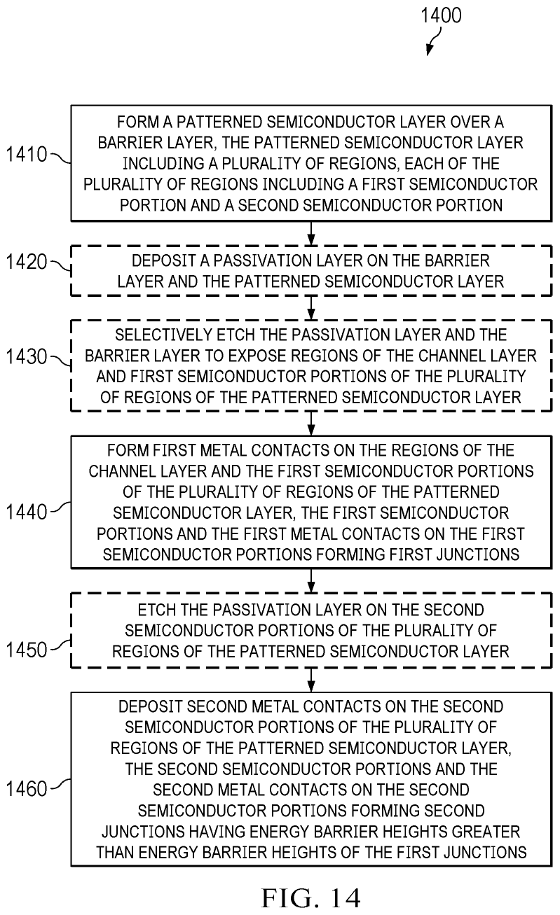

FIG. 14 includes a flowchart 1400 illustrating an example of a process of fabricating an HEMT including a hybrid drain contact structure according to certain examples. It is noted that the operations illustrated in FIG. 14 provide particular processes for fabricating examples of HEMTs disclosed herein according to certain examples. Other sequences of operations can also be performed to fabricate HEMTs according to alternative examples. For example, alternative examples may perform the operations in a different order. Moreover, the individual operations illustrated in FIG. 14 can include multiple sub-operations that can be performed in various sequences as appropriate for the individual operation. Furthermore, some operations can be added or removed depending on the particular example. In some examples, two or more operations may be performed in parallel. One of ordinary skill in the art would recognize many variations, modifications, and alternatives.

Operations at block 1410 of flowchart 1400 include forming a patterned semiconductor layer over a barrier layer on a semiconductor substrate. The barrier layer may be over a channel layer on the semiconductor substrate and may form a heterostructure with the channel layer such that 2DEG may be induced near the interface between the channel layer and the barrier layer. In one example, the channel layer includes a GaN layer, and the barrier layer includes an AlGaN layer. The patterned semiconductor layer may include a plurality of semiconductor regions. In some examples, each of the plurality of semiconductor regions includes at least a first semiconductor portion and a second semiconductor portion. The patterned semiconductor layer may be a p-doped semiconductor layer (e.g., a p-GaN layer) etched using an etch mask to selectively remove some regions of the p-doped semiconductor layer. The etch mask may define the shape and size of each of the plurality of semiconductor regions. Examples of the shape of each of the plurality of semiconductor regions are shown in, for example, FIGS. 5B, 9A, 9D, 10A, 10D, 11A, 11C, 11E, and 11G. For example, each of the plurality of semiconductor regions may have a hexagonal shape or another shape, and may taper in a direction from a drain region to a gate region. The patterned semiconductor layer may include semiconductor regions at both the gate region and the drain region for fabricating an enhancement mode HEMT, or may only include semiconductor regions at the drain region for fabricating a depletion model HEMT.

In some examples, the semiconductor regions at the gate regions and the drain regions have different thicknesses, different dopants, different doping densities, different dopant activation levels, or different additional constituents. For example, the different thicknesses may be attained by a uniform epitaxial growth process and a selected area epitaxial growth process. The different activation levels in different regions can be attained by, for example, selective hydrogen-based deactivation. In some examples, there may be one semiconductor block at the drain region as described above with respect to, for example, FIGS. 11A-11H. In some examples, the barrier layer may have different thicknesses at the gate region and the drain region, which may be achieved by, for example, a uniform epitaxial growth process and a selected area epitaxial growth process.

At block 1420, the operations include depositing a passivation layer over the barrier layer and the patterned semiconductor layer. The passivation layer may include, for example, an oxide-based dielectric layer or a nitride-based dielectric layer. The passivation layer may be used to protect and isolate the source structure, gate structure, and drain structure. A semiconductor wafer formed after the operations of block 1420 is shown in FIG. 13A.

Operations at block 1430 include selectively etching the passivation layer and the barrier layer to expose regions of the channel layer and first semiconductor portions of the plurality of semiconductor regions of the patterned semiconductor layer. For example, as described above with respect to FIG. 13B, passivation layer 1350 and barrier layer 1320 may be selectively etched using one or more masks and one or more etching processes to expose channel layer 1310 at the source and drain regions and a first region of drain semiconductor layer 1340 at each p-type drain contact structure.

At block 1440, first metal contacts are formed in the etched regions by depositing a first metal material on the exposed regions of the channel layer and the exposed first semiconductor portions of the plurality of semiconductor regions of the patterned semiconductor layer, as shown in, for example, FIG. 13B. The first semiconductor portions and the first metal contacts on the first semiconductor portions form first junctions that may have low barrier heights, such as ohmic junctions or low-barrier Schottky junctions. The first metal contacts deposited on the exposed regions of the channel layer include one or more drain electrical contacts that contact the channel layer at the drain region and form low barrier junctions (e.g., ohmic junctions) with the channel layer. The first metal contacts deposited on the exposed regions of the channel layer also include one or more source electrical contacts that contact the channel layer at the source region and form low barrier junctions (e.g., ohmic junctions) with the channel layer.

Operations at block 1450 include removing the passivation layer on the second semiconductor portions of the plurality of semiconductor regions of the patterned semiconductor layer by etching to expose the second semiconductor portions of the plurality of semiconductor regions of the patterned semiconductor layer. In examples where enhancement mode HEMTs are fabricated, the passivation layer on the patterned semiconductor layer at the gate region may be etched to expose a semiconductor region of the patterned semiconductor layer at the gate region.

At block 1460, second metal contacts may be formed by depositing a second metal material on the second semiconductor portions of the plurality of semiconductor regions of the patterned semiconductor layer as shown in, for example, FIG. 13C. The second semiconductor portions and the second metal contacts on the second semiconductor portions form second junctions having energy barrier heights greater than the energy barrier heights of the first junctions. In examples where enhancement mode HEMTs are fabricated, the second metal contacts deposited on the patterned semiconductor layer at the gate region form third junctions with the patterned semiconductor layer at the gate region. The third junctions may have energy barrier heights greater than energy barrier heights of the first junctions, and may have energy barrier heights similar to the energy barrier heights of the second junctions.

Even though not shown in flowchart 1400, BEOL processes may be performed to fabricate additional structures, such as field plates, electrical interconnects, and the like. FIG. 14 shows an example of a process for fabricating an example of an HEMT including an example of a hybrid drain contact structure disclosed herein according to certain examples. Other hybrid drain contact structures disclosed herein may be fabricated using similar processes, including various combinations of epitaxial growth, deposition, etching, planarization, and the like. For example, even thought a method of fabricating a hybrid drain contact structure with a plurality of p-type drain contact structures is described with respect to FIG. 14, the method can be modified to include two or more epitaxial growth processes for growing the barrier layer or the p-type semiconductor layer, to fabricate a hybrid drain contact structure with one continuous p-type drain contact structure as described with respect to, for example, FIGS. 11A-11H. In various examples, the HEMTs disclosed herein may be fabricated using, for example, a gate-first process flow, a gate-last process flow, or a hybrid process flow, and the gate and drain structures may be fabricated using a self-aligned process flow, a non-self-aligned process flow, or a hybrid alignment process flow.

As used herein, the term “contiguous” is used to describe adjacent structures that are connected without a break. As used herein, the term “semiconductor substrate” may refer to a semiconductor wafer without other layers or circuits formed therein, or a semiconductor wafer that includes various layers and circuits formed therein. As used herein, the term “layer” may refer to a continuous layer, or a region or portion of a layer. As used herein, terms “Schottky junction” and “Schottky contact” are used interchangeably. As used herein, terms “ohmic junction” and “ohmic contact” are used interchangeably. As used herein, terms “low-barrier Schottky junction” and “low-barrier Schottky contact” are used interchangeably.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A semiconductor device comprising:
a substrate including a channel layer and a barrier layer over the channel layer;
a source contact electrically coupled to the channel layer;
a gate structure over the barrier layer; and
a drain contact structure including:
a first drain contact electrically coupled to the channel layer;
a semiconductor layer over the barrier layer and including a first semiconductor portion and a second semiconductor portion; and
a second drain contact on the semiconductor layer and electrically coupled to the first drain contact, the second drain contact including a first metal portion and a second metal portion, the first metal portion and the first semiconductor portion forming a first junction having a first energy barrier height, and the second metal portion and the second semiconductor portion forming a second junction having a second energy barrier height lower than the first energy barrier height.

2. The semiconductor device of claim 1, wherein:
the first junction includes a first Schottky junction; and
the second junction includes an ohmic junction, a second Schottky junction having an energy barrier height lower than the first energy barrier height, or a combination thereof.

3. The semiconductor device of claim 1, wherein:
the first metal portion includes a first metal material having a first metal work function; and
the second metal portion includes a second metal material having a second metal work function different from the first metal work function.

4. The semiconductor device of claim 1, wherein:
the first metal portion and the second metal portion include a same metal material; and
the first semiconductor portion and the second semiconductor portion have different energy band structures.

5. The semiconductor device of claim 4, wherein the first semiconductor portion and the second semiconductor portion include a same base semiconductor material and have different levels of doping or dopant activation.

6. The semiconductor device of claim 1, wherein the first metal portion and the second metal portion include titanium (Ti), titanium tungsten (TiW), titanium nitride (TiN), nickel (Ni), platinum (Pt), tantalum nitride (TaN), copper (Cu), tungsten (W), gold (Au), aluminum (Al), titanium tungsten aluminum (TiWAl), titanium aluminum nitride (TiAlN), or a combination thereof.

7. The semiconductor device of claim 1, wherein:
the semiconductor layer further includes a third semiconductor portion;
the second drain contact further includes a third metal portion; and
the third semiconductor portion and the third metal portion form a third junction having a third energy barrier height different from the first energy barrier height and the second energy barrier height.

8. The semiconductor device of claim 7, wherein the third metal portion has a metal work function different from metal work functions of the first metal portion and the second metal portion.

9. The semiconductor device of claim 7, wherein the third semiconductor portion has an energy band structure different from energy band structures of the first semiconductor portion and the second semiconductor portion.

10. The semiconductor device of claim 1, wherein:
the drain contact structure is a first drain contact structure;
the semiconductor device includes a plurality of drain contact structures including the first drain contact structure, each of the plurality of drain contact structures having the same structure as the first drain contact structure; and
the first drain contacts and the second metal portions of the second drain contacts of the plurality of drain contact structures are contiguous.

11. The semiconductor device of claim 10, wherein the semiconductor layer of the first drain contact structure is separate from the semiconductor layers of other drain contact structures of the plurality of drain contact structures.

12. The semiconductor device of claim 10, wherein the first semiconductor portion of the semiconductor layer and the first metal portion of the second drain contact of each drain contact structure of the plurality of drain contact structures are tapered in a direction towards the gate structure.

13. The semiconductor device of claim 10, wherein the first drain contacts of the plurality of drain contact structures are interleaved with the second metal portions of the second drain contacts and the semiconductor layers of the plurality of drain contact structures in a width direction of the semiconductor device.

14. The semiconductor device of claim 13, wherein the first drain contact and the second metal portion of the second drain contact of each of the plurality of drain contact structures have a same length in a length direction of the semiconductor device.

15. The semiconductor device of claim 13, wherein:
the second drain contact of each of the plurality of drain contact structures further includes a third metal portion between the first metal portion and the second metal portion;
the semiconductor layer of each of the plurality of drain contact structures further includes a third semiconductor portion;
the third metal portion and the third semiconductor portion forms a third junction; and
the third junction has a third energy barrier height different from the first energy barrier height and the second energy barrier height.

16. The semiconductor device of claim 13, wherein the first drain contact and the second metal portion of the second drain contact of each of the plurality of drain contact structures have different lengths in a length direction of the semiconductor device.

17. The semiconductor device of claim 10, wherein:
the first drain contacts of the plurality of drain contact structures are contiguous; and
the second metal portion of the second drain contact is between the first drain contact and the first metal portion of the second drain contact in each of the plurality of drain contact structures.

18. The semiconductor device of claim 1, wherein:
the semiconductor layer includes a semiconductor region that extends continuously along a width direction of the semiconductor device;
the first metal portion of the second drain contact extends along the width direction of the semiconductor device; and
a first region of the barrier layer under the gate structure has a lower thickness than a second region of the barrier layer under the drain contact structure.

19. The semiconductor device of claim 18, wherein the first drain contact and the second metal portion of the second drain contact are parts of a contiguous metal contact that extends along the width direction of the semiconductor device.

20. The semiconductor device of claim 18,
the first drain contact extends along the width direction of the semiconductor device; and
the second metal portion of the second drain contact extends along the width direction of the semiconductor device and is between the first drain contact and the first metal portion of the second drain contact.

21. The semiconductor device of claim 18, wherein:
the first drain contact extends along the width direction of the semiconductor device;
a first region of the second metal portion of the second drain contact extends along the width direction of the semiconductor device and is between the first drain contact and the first metal portion of the second drain contact; and
one or more second regions of the second metal portion of the second drain contact are separated by the first metal portion of the second drain contact.

22. The semiconductor device of claim 18, wherein:
the second metal portion of the second drain contact extends along the width direction of the semiconductor device; and
the first drain contact includes a plurality of regions interspersed in and surrounded by the second metal portion of the second drain contact.

23. The semiconductor device of claim 1, wherein the semiconductor layer is a first semiconductor layer, and the gate structure comprises:
a second semiconductor layer over the barrier layer; and
a gate contact layer over the second semiconductor layer.

24. The semiconductor device of claim 23, wherein:
the second semiconductor layer includes a third semiconductor portion and a fourth semiconductor portion; and
the gate contact layer includes a third metal portion and a fourth metal portion, the third metal portion and the third semiconductor portion forming a third junction having a third energy barrier height, and the fourth metal portion and the fourth semiconductor portion forming a fourth junction having a fourth energy barrier height lower than the third energy barrier height.

25. The semiconductor device of claim 23, wherein the second semiconductor layer is thicker than the first semiconductor layer.

26. The semiconductor device of claim 1, wherein the gate structure comprises:
a dielectric layer over the barrier layer; and
a conductive layer over the dielectric layer.

27. A method comprising:
forming a patterned semiconductor layer over a barrier layer, the barrier layer being over a channel layer formed on a semiconductor substrate, the patterned semiconductor layer including a plurality of regions, each of the plurality of regions including a first semiconductor portion and a second semiconductor portion;
forming first metal contacts on regions of the channel layer and the first semiconductor portions of the plurality of regions of the patterned semiconductor layer, in which the first semiconductor portions and the first metal contacts on the first semiconductor portions form first junctions; and
depositing second metal contacts on the second semiconductor portions of the plurality of regions of the patterned semiconductor layer, in which the second semiconductor portions and the second metal contacts on the second semiconductor portions form second junctions having greater energy barrier heights than the first junctions.

28. The method of claim 27, wherein:
the second junctions include first Schottky junctions; and
the first junctions include ohmic junctions, second Schottky junctions having energy barrier heights lower than the energy barrier heights of the second junctions, or a combination thereof.

29. The method of claim 27, further comprising, before forming the first metal contacts:
depositing a passivation layer on the barrier layer and the patterned semiconductor layer; and
selectively etching the passivation layer and the barrier layer to expose the regions of the channel layer and the first semiconductor portions of the plurality of regions of the patterned semiconductor layer.
